(19) United States
(12) Patent Application Publication
(10) Pub. No.: US 2002/0115293 A1
(43) Pub. Date: Aug. 22, 2002

(54) Device to rapidly and accurately sequence long DNA fragments

(76) Inventor: Bahram Ghodsian, La Jolla, CA (US)

Correspondence Address: DAVID R PRESTON & ASSOCIATES, 12625 HIGH BLUFF DRIVE, SUITE 205, SAN DIEGO, CA, 92130, US

(21) Appl. No.: 09/964,819

(22) Filed: Sep. 25, 2001

Related U.S. Application Data
(60) Provisional application No. 60/259,620, filed on Jan. 3, 2001.

(51) Int. Cl. H01L 21/302; H01L 21/461

(52) U.S. Cl. 438/689

(57) ABSTRACT

The present invention relates to a chip device capable of rapidly and accurately sequencing long DNA fragments. There is disclosed methods of fabricating several novel near field optical detectors useful in detecting and sequencing DNA nucleotides and other small molecules. A variety of material deposition, layering, etching and cleaning techniques are used to micromachine this lab-on-chip device.

This application claims benefit of priority to U.S. provisional patent application Serial No. 60/259,620 filed on Jan. 3, 2001 to Bahram Ghodsian which patent application is incorporated herein by reference.

### TECHNICAL FIELD

The present invention relates to a micromachined opto-electronic waveguide and a method of fabricating the same by using selective growth, masking and etching processes. More particularly, the present invention relates to a method of fabricating an near-infrared detector which operates at room temperature and which has the qualities of excellent sensitivity, low noise, high thermal stability and minimum electromagnetic and noise interference. The present invention also relates to a method of fabricating this near-infrared detector in integrated fashion with lab-on-a-chip capillary electrophoresis systems. Such improved capillary electrophoresis systems have utility in sequencing molecules, particularly DNA molecules, extremely accurately and rapidly.

### BACKGROUND

The completion of the first working draft of the DNA sequence of the human genome was announced on Jun. 26, 2000. This feat represents an achievement as significant for mankind equal to that of landing man on the moon and the technological advances needed to reach this goal were certainly equally impressive especially when one considers that the DNA sequence of humans is approximately 3.2 gigabases in length.

This accomplishment was made possible by advances in DNA sequencing technology over the last few years which permitted the relatively rapid of determination of the order of the four individual chemical bases which constitute the code in a DNA molecule.

The polymerase chain reaction, various DNA labeling and sequencing techniques, and banks of automated DNA sequencers have made this accomplishment possible due mostly to the streamlining and automation of a number of time consuming DNA sequencing procedures. The running of parallel capillary sequencers, which can process 96 samples at a time, has greatly shortened the time it took to prepare the working draft sequence. Some experts calculate that by utilizing parallel capillary sequencers sequencing capacity and output jumped about eightfold in less than a year to where the labs were generating sequence data at a rate of over 1000 nucleotides per second on a continuous basis.

Sequencing and analyzing DNA involves several steps that includes the preparation of DNA, its fragmentation, labeling and base sequence analysis. To sequence large genomes, two competing techniques are employed. One technique used exclusively by Celera Genomics is called the whole-genome “shotgun” method. The other technique, called the tiered “shotgun” sequencing strategy or “clone-by-clone” method, is used by the International Human Genome Sequencing Consortium.

In the whole-genome shotgun method small clones are prepared directly from genomic DNA rather than from mapped BACs. This method offers a potentially faster sequencing than the clone-by-clone method but involves a much more involved base sequence reassembly process after sequencing is completed. The whole-genome shotgun method takes a genome which has been segmented into fragments about 150,000 bases long and replicated using bacterial artificial chromosomes (BACs). Complex computerized mapping techniques calculate the exact placement of each clone in the genome. The clones are then ultimately fragmented into smaller pieces of about 500 to 1000 bases for sequencing and further computerized sequence analysis.

Gel electrophoresis is used in both of these methodologies. A series of DNA fragments which differ in length by just one base are end labeled with a fluorescent dye specific for each of the four bases. The labeled DNA fragments are loaded onto an electrophoresis column containing acrylamide gel. A voltage across the column causes the DNA fragments to migrate through the gel and to separate according to fragment length. At the bottom of the column, the fluorescent dye molecule is excited by laser light and the distinctive emission is picked up and detected by a detector.

Gel electrophoresis technology is currently used in the Applied biosystems PRISM 3700 and the Molecular Dynamics MegaBACE 100 capillary sequencers which were used in the sequencing of the human genome. Both instruments incorporate capillary tubes to hold the sequence gel, automate sample loading, separation matrix loading and removal, data collection and analysis. While these instruments provide significant improvement over manual gel preparation and lane tracking required in slab-gel sequencers, there is still a great need for even faster sequencers. Sequencing time per sample is about 3 hours in machines which use capillaries. These sequencers combine high efficiency with high-throughput capability, automated sample preparation and automated tracking of samples which avoids mistakes in sample sequencing and also provides a high level of quality control over the process.

While sequencing costs have dropped 100-fold over the last decade further reductions in sequencing sample volumes, times, and costs are needed. Some experts in the field are calling for a new generation of sequencers capable of the rapid and accurate determination of sequences 700 to 1000 nucleotides long.

One recognized method of increasing sequencing efficiency and processing speeds while reducing costs is to reduce fluid volumes of the sequencing and separation steps.

Electrophoresis-based sequencers built on microchannel plates or “microchips” are just now becoming commercially available. Such microchip sequencers offer more efficient sample injection; higher speeds, greater resolution, higher throughput, and greater detection sensitivity; lower costs and much lower sample and reagent consumption. These microchip sequencers also have the ability to be integrated seamlessly into the sample acquisition and processing steps. Such microchip electrophoresis sequencers can be inexpensively manufactured and are attractive as disposable, one-use devices.

Caliper Technologies Corporation recently released their AMS 90 or “LabChip” that takes up 96 separate DNA samples at a time and separates the DNA fragments on a electrophoresis microchip. A sample can be processed on the LabChip in about 5 to 30 seconds. Laser-induced fluorescence is used to detect the separate DNA fragments and the sequence recorded and analyzed by an Agilent Technologies Bioanalyzer 2100. In operation, Caliper's LabChip runs the DNA sample from one sample well through a microchannel which is crossed at a right angle by a separation microchannel. Once the DNA sample reaches the intersection with the separation microchannel, the sample is injected into the separation channel by the application of an electric charge along the length of the separation microchannel. As the DNA fragments pass down the length of the separation microchannel they are separated according to their size by means of molecular sieving. As mentioned above, the individual labeled DNA fragments are then excited by laser light and simultaneously the fluorescence detected at a suitable point along the separation channel. The results are recorded and analyzed with the Agilent 2100 Bioanalyzer. Once detected, the sample passes into a waste/buffer well.

These present art sequencers will benefit greatly from increased speed and thus reduced throughput times by the incorporation of the near field optical detector of the present invention since it offers greater resolving power than present day light gathering and focusing methods.

DNA sequencing by size fractionation is generally a relatively slow and indirect method of obtaining sequence data. The present invention presents one of the next generation of sequencers will allow direct analysis of individual DNA molecules at rates of up to and possibly exceeding 1000 bases per second.

As stated above, the next step in the genomic science is to understand the function of the DNA sequences. But first the genes must be located, separating them from the 95 percent and more of the genome that appears uninvolved in the workings of human cells. There are an estimated couple of thousands of genes spread throughout the billions of bases that make up the genome, and little is known about the majority of them. An important advancement in the genomic science has been the annotation process of the sequencing of the genomes of other species.

The present invention provides an inexpensive, high throughput and accurate MEMS device capable of performing DNA sequencing on 5 cm×5 cm glass/silicon chip. The sequencing is carried out by electrophoresis action in channels etched on a glass substrate. There is one channel for each of the four DNA bases, run in parallel. Channel width and depth is 30 mm, and the length of the channel is 3 cm. In one embodiment of the present invention, there are 17 of these sets (a set consists of four channels) on a 5 cm×5 cm chip. Each chip is able to rapidly sequence DNA fragment up to 85,000 bases in length.

The development of DNA analysis systems and methods with enhanced speed, sensitivity, and throughput are important for the continuation of the Human Genome Project and for the subsequent utilization of this sequence information. Some improved technologies developed thus far include (1) capillary electrophoresis (CE) (See, Landers, J. P., Ed. Handbook of Capillary Electrophoresis; CRC: Boca Raton, Fla., 1994; Drossman, H.; Luckey, J. A.; Kostichka, A. J.; D'Cunha, J.; Smith, L. M. Anal. Chem. 1990, 62, 900-903; Swerdlow, H.; Gesteland, R. Nucleic Acids Res. 1990, 18, 1415-1419; Cohen, A. S.; Najarian, D. R.; Karger, B. L. J. Chromatogr. 1990, 516, 49-60; Swerdlow, H.; Wu, S.; Harke, H.; Dovichi, N. J. J. Chromatogr. 1990, 516, 61-67); (2) thin slab gels, (See, Kostichka, A. J.; Marchbanks, M. L.; Brumley, R. L., Jr.; Drossman, H.; Smith, L. M., Bio/Technology 1992, 10, 78-81); (3) multiplex labeling, (See, Church, G. M.; Kieffer-Higgens, S. Science 1988, 240, 185-188 and Cherry, J. L.; Young, H.; Di Sera, L. J.; Ferguson, F. M.; Kimball, A. W.; Dunn, D. M.; Gesteland, R. F.; Weiss, R. B. Genomics 1994, 20, 68-74); and (4) energy-transfer fluorescent labels (See, Ju, J.; Ruan, C.; Fuller, C. W.; Glazer, A. N.; Mathies, R. A. Proc. Natl. Acad. Sci. U.S.A.1995, 92, 4347-4351 and Ju, J.; Glazer, A. N.; Mathies, R. A. Nat. Med. 1996, 2, 246-249) to increase the performance of gel electrophoresis.

Many groups have demonstrated that capillary array electrophoresis (CAE) further enhances the throughput of capillary electrophoretic separations. See, for example, Huang, X. C.; Quesada, M. A.; Mathies, R. A. Anal. Chem. 1992, 64,967-972; Mathies, R. A.; Huang, X. C. Nature 1992, 359, 167-169; Clark, S. M.; Mathies, R. A. Anal. Biochem. 1993, 215, 163-170; Wang, Y.; Ju, J.; Carpenter, B. A.; Atherton, J. M.; Sensabaugh, G. F.; Mathies, R. A. Anal. Chem. 1995, 67, 1197-1203; Wang, Y.; Wallin, J. M.; Ju, J.; Sensabaugh, G. F.; Mathies, R. A. Electrophoresis 1996, 17, 1485-1490; Kheterpal, I.; Scherer, J. R.; Clark, S. M.; Radhakrishnan, A.; Ju, J.; Ginther, C. L.; Sensabaugh, G. F.; Mathies, R. A. Electrophoresis 1996, 17, 1852-1859; Takahashi, S.; Murakami, K.; Anazawa, T.; Kambara, H. Anal. Chem. 1994, 66, 1021-1026; Ueno, K.; Yeung, E. S. Anal. Chem. 1994, 66, 1424-1431; Bashkin, J.; Bartosiewicz, M.; Roach, D.; Leong, J.; Barker, D.; Johnston, R. J. Capillary Electrophor. 1996, 3, 61-68; and Anazawa, T.; Takahashi, S.; Kambara, H. Anal. Chem. 1996, 68, 2699-2704.

However, preparation and manipulation of large numbers of capillaries can be difficult, the capillary outside diameter limits the number of capillaries that can be bundled in an array, and even faster separations are desirable.

Microfabricated CE chips were introduced in 1992, and separations of fluorescent dyes, fluorescently labeled amino acids, and metal ion complexes have shown that these devices can increase the speed of CE separations by an order of magnitude. See, respectively, [21] Manz, A.; Harrison, D. J.; Verpoorte, E. M. J.; Fettinger, J. C.; Paulus, A.; Ludi, H.; Widmer, H. M. J. Chromatogr. 1992, 593, 253-258; Harrison, D. J.; Manz, A.; Fan, Z.; Ludi, H.; Widmer, H. M. Anal. Chem. 1992, 64, 1926-1932; Jacobson, S. C.; Hergenroeder, R.; Koutny, L. B.; Warmack, R. J.; Ramsey, J. M. Anal. Chem. 1994, 66, 1107-1113; Harrison, D. J.; Fluri, K.; Seiler, K.; Fan, Z.; Effenhauser, C. S.; Manz, A. Science 1993, 261, 895-897; Effenhauser, C. S.; Manz, A.; Widmer, H. M. Anal. Chem. 1993, 65, 2637-2642; Jacobson, S. C.; Hergenroeder, R.; Moore, A. W., Jr.; Ramsey, J. M. Anal. Chem. 1994, 66, 4127-4132 and Jacobson, S. C.; Moore, A. W.; Ramsey, J. M. Anal. Chem. 1995, 67, 2059-2063.

Microfabricated CE chips have now been used for rapid analysis of biologically relevant samples, such as DNA restriction fragments, PCR products, DNA sequencing fragments, short oligonucleotides, and blood serum cortisol. See, respectively, Woolley, A. T.; Mathies, R. A. Proc. Natl. Acad. Sci. U.S.A. 1994, 91, 11348-11352; Jacobson, S. C.; Ramsey, J. M. Anal. Chem. 1996, 68, 720-723; Woolley, A. T.; Mathies, R. A. Anal. Chem. 1995, 67, 3676-3680; Effenhauser, C. S.; Paulus, A.; Manz, A.; Widmer, H. M. Anal. Chem. 1994, 66, 2949-2953 and Koutny, L. B.; Schmalzing, D.; Taylor, T. A.; Fuchs, M. Anal. Chem. 1996, 68, 18-22.

Indeed, it has been recently shown that PCR can also be functionally integrated onto CE chips to form DNA analysis microdevices. See, Woolley, A. T.; Hadley, D.; Landre, P.; deMello, A. J.; Mathies, R. A.; Northrup, M. A., Anal. Chem. 1996, 68, 4081-4086.

A microfabricated electrochemical array detector for electrophoretic analysis has also recently been demonstrated. See, P. F. Gavin, A. G. Ewing, J. Am. Chem. Soc, 118, 8932-8936, 1996. However, the utility of these high-speed miniaturized separation devices is limited because only small DNA fragments can be analyzed in parallel in a relatively low throughput manner.

Recently others report reading 500 and 565 bases in 20 and 27 min, respectively, in short electrophoretic microchannels filled with linear polyacrylamide (“LPA”) as the sieving matrix. See, Liu, S.; Shi, Y.; Ja, W. W.; Mathies, R. A. Anal. Chem. 1999, 71, 566-573 and Schmalzing, D.; Tsao, N.; Koutny, L.; Chisholm, D.; Srivastava, A.; Adourian, A.; McEwan, P.; Matsudaira, P.; Ehrlich, D. Genome Res. 1999, 9, 853-858.

This is far superior to the performance of capillaries for comparable read length. While these results are adequate for many sequencing and screening applications, whole genome sequencing requires significantly longer reads to minimize sequence assembly and effectively reduce costs. See, Dovichi, N. J. Electrophoresis 1997, 18, 2393-2399; Schmalzing, D.; Belenky, A.; Novotny, M. A.; Koutny, L.; Salas-Solano, O.; El-Difrawy, S.; Adourian, A.; Matsudaira, P.; Ehrlich, D. Nucleic Acids Res. 2000, 28, e43; Koonin, S. E. Science (Washington, D.C.) 1998, 279, 36 and Mullikin, J. C.; McMurray, A. A. Science (Washington, D.C.) 1999, 283, 1867-1868. See FIG. 6 which shows a comparison of long and short microfabricated capillary electrophoresis channels illustrating the need to have longer channels.

Finishing costs and logistics are also known to be essential factors in genome center productivity. Based on electrophoretic performance of the best sieving materials, many researchers in the field conclude that longer reads demand longer channels. See, Schmalzing, D.; Adourian, A.; Koutny, L.; Ziaugra, L.; Matsudaira, P.; Ehrlich, D. Anal. Chem. 1998, 70, 2303-2310.

Thus, only by separating bands further apart can a low-resolution detector detect the individual DNA fragments. To address this issue, Ehrlich's group constructed long straight separation channels in 25 cm×50 cm glass plates to extend the read length to over come the resolution limitation of detectors used in microfabricated channels devices and evaluated the device performance. They report sequencing 800 base pairs. See, Koutny, L. Schmalzing, D. Salas-Solano, O. El-Difrawy, S. Adourian, A. Buonocore, S. Abbey, K. McEwan, P. Matsudaira, P. Ehrlich D. Anal. Chem., 2000, 72 (14), 3388 -3391.

Although Schmalzing's statement “longer reads demand longer channels” is true, however, this is not the only way to increase the read length. See, Schmalzing, 1998.

The other approach to achieve longer reads length, which has not been explored extensively so far, is to have detectors with a superior resolving power. This approach is explained by our finding that resolution on shorter channel devices can be achieved with a single base accuracy with molecular separations as little as 10-30 nm. This increased resolution offers a means of tremendously improving the read length for genomic applications.

The invention disclosed herein, an optical DNA sequence detection and determination system, integrated with microfluidic channels for separating DNA molecule fragments with electrophoresis action and for detecting the DNA sequence with single base molecule accuracy, addresses the aforementioned needs. Disclosed herein is the means to manufacture this single base accurate detector; integrated with an array of glass microfluidic channels to create a disposable DNA sequence determination microsystems. This invention has a number of important advantages over present DNA sequencing systems which are important for genomic drug discovery market. These advantages are high throughput, longer reads (1000-5000 bases) per sequencing run, low manufacturing cost (few dollars per chip), small size (chips on the order of 2 inches square) and a single base accuracy.

Over a century ago Ernst Abbe in Archive. F. Mikroskop. Anat. 9, 413, 1873 originally answered the question why sub-wavelength resolution cannot be achieved by conventional far field microscopy. Later, A. B. Porter in Phil. Mag. (6), 11, 1906, p. 154 gave a concise English language description of the solution in 1906:

If a lens is to produce a truthful image of an illuminated object, it must have an aperture sufficient to transmit the whole of the diffraction pattern produced by the object, if but part of this diffraction pattern is transmitted, the image will not truthfully represent the object, but will correspond to another (virtual) object whose whole diffraction pattern is identical with that portion which passes through the lens; if the structure of the object is so fine, or if the aperture of the lens is so narrow, that no part of the diffraction pattern due to the structure is transmitted by the lens, then the structure will be invisible no matter what magnification is used.

Porter considered as his microscopical object a grating with spacing a and defined the resolution as the smallest value of a for which the grating pattern could be detected by the microscope. As shown in the following EQUATION 1, the direction of the diffracted wave is given by:

α(sin θₘ−sin θᵢ)=mλ

where θⱼ, is the angle the incident plane wave makes with the normal to the grating, θₘ, is the angle the diffracted wave makes with the normal, λ is the wavelength and m is a positive integer indicating the order of the diffraction. This equation is called the grating equation. If the size of the lens is such that it can capture this diffracted wave then the microscope can detect the pattern of the grating. Otherwise, the pattern is not visible.

Of interest is the minimum value of a that can satisfy this grating equation. Suppose the objective and the condenser of the microscope each completely cover one of the half spaces separated by the grating: that is, the numerical aperture of each is both one. In that case, θⱼ and θₘ can both range from −π/2 to π/2 and the minimum value of a is given in the following EQUATION 2 by:

α=λ/2

This is the theoretical limit in which the most marginal condenser ray is diffracted by the grating in first order into the most marginal ray going to the objective. FIG. 7 provides an illustration of the grating equation. One can extend this model easily into ordinary microscopical objects by considering that any planar optically transmitting pattern can be Fourier decomposed into sinusoidal gratings like the one above. EQUATION 2 then can be interpreted as the period of the highest spatial frequency component of the object that can be seen by the conventional microscope.

The terms near field and far field possess a number of different explicit meanings. See, M. A. Paesler and P. J. Moyer, Near-field optics: Theory, Instrumentation, and Applications, John Wiley & Sons, New York, 1996.

However, for our present purposes, one can classify far-field microscopes as those microscopes whose optical elements (that is, radiation sources and radiation collectors) are far away from the viewed object in comparison to the wavelength, whereas near-field microscopes possess optical elements whose distance from the object is on the scale of the wavelength or smaller. The results of the previous section show that information about the high spatial frequency components of a viewed object is simply not present in the electromagnetic far field, and therefore no far-field microscope, regardless of its construction, can resolve these high spatial frequency features. The basis for near-field microscopy is the principle that the high spatial frequency information about the object that is not carried into the far field is still present in the near field. Consequently, if one were to extend a microscope optical element into this near field and if the element itself possesses sub-wavelength features that can interact with the high spatial frequency electromagnetic field in a meaningful way, then one can capture this very useful information. FIG. 8 shows a frequently reproduced illustration of the operation of the near-field microscope. See, E. Betzig and J. K. Trautman, Science 257, 1992, p. 189. The near-field optical element is portrayed as an opaque screen with a sub-wavelength aperture in it.

As shown in FIG. 8, the aperture confines the incident radiation and allows it to illuminate only a small area on the sample surface. Incident radiation passes through the aperture, which is positioned immediately over the surface to be imaged. Because of the confinement of the radiation by the aperture, only a small area of the surface is illuminated at any one time. This radiation will diffract into a large spatial distribution in the far field, but will still contain information about the transmission properties of only the small illuminated region in the surface.

By scanning the aperture over the sample, it is possible to reconstruct an image with resolution determined by the aperture size and not solely by the wavelength. FIG. 8 is an illustration of an illumination mode near-field microscope; the corresponding collection mode near-field microscope illuminates the sample from the far field and collects radiation in the near field with the aperture. See, Paesler, 1996.

A demonstration of the basic theoretical notion of NFOD operation can be made through consideration of simple conceptual configuration introduced by Vigoureux et al. See, Vigoureux J. M. and Girard, C., Appl. Opt. 1992, 31, 3170-3177 and Vigoureux, J. M. Depasse, F. and Girard, C., Appl. Opt. 1992, 31, 3036-3045.

The classical microscope is considered in terms of the lens structure as shown in FIG. 9 that is assumed to gather illumination emitted by DNA bands that are excited by laser beam underneath the lens, to give a planer monochromatic radiation of wavelength λ. The objects are simply photo-excited DNA bands that are traveling in capillary tube by application of electrophoresis.

In FIG. 9 the conventional microscope is modeled in terms of a detector located at a screen placed a distance z away from DNA bands. The emitted light contains both far field as well as near-field information about the image. The near-field information is evanescent as shown by Wolf and Nieto-Vesperinas. See, Wolf, E. and Nieto-Vesperinas, M. Appl. Opt., 1979, 18, p. 2679.

Since the amplitude of these evanescent components (or near-field information) decrease rapidly with z, this information does not survive the journey to the macroscopically remote detector, and no near-field information about objects' image exist in the image captured by the detector. DNA fragments, for example, can be modeled by the classical double-slit configuration, with two identical bands of width L separated by a distance d. The emitted light from excited DNA fragments has wavelength λ.

Using an analysis quite similar to that employed to determine the effect of a nearby aperture on the frequency spectrum of the single slit, one can calculate the image on the screen at Z in the far-field device (a) and the image that can be reconstructed from the light that propagates from near-field instrument (b) to far field detector located in at the screen. The former image (a) is gathered in a conventional parallel format with real image in real space transduced at z=Z. As shown in the following EQUATION 3, the field at the aperture is:

$$f ( x , z = 0 ) = {E}_{x} ( x , z = 0 ) rect ( \frac{d + L}{x} ) rect ( \frac{- d + L}{x} )$$

which has a Fourier transform as shown in the following EQUATION 4:

$$F ( {α}_{x} , z = 0 ) = 4 {E}_{0} cos 2 {πα}_{x} d \frac{sin 2 {πα}_{x} L}{2 {πα}_{x}}$$

This, in turn allows one to express the field at a distance z=Z as shown in the following EQUATION 5:

f(x,z=Z)=∫_{-∞}^{∞}dαₓexp(−2πiαₓx)F(αₓ,z=0)exp(−2πi(α²−αₓ²)^{½}Z)

As noted above, one need only consider the propagating components; thus, one can limit the range of integration to |αₓ|≦ω/2πc, and, as shown in the following EQUATION 6, the conventional far field microscope detects the following field at z=Z:

f(x,z=Z)=∫_{-ω/2πc}^{+ω/2πc}dαₓexp(−2πiαₓx)F(αₓ,z=0)exp(−2πi(α²−αₓ²)^{½}Z)

As one can see above, the information content at z=Z is not sufficient to resolve the high-frequency information. In this analysis, the two DNA light sources are not resolved in the far field. As shown in the following EQUATION 7, this equation can be solved for the far field at a sub-wavelength distance ε

f₂(x,z=ε)=∫_{-ω/2πc}^{+ω/2πc}dαₓexp(−2πiαₓx)F(αₓ,z=0)exp(−2πi(α²−αₓ²)^{½ε)}

Now, one can replace a sub-wavelength aperture of width w in the near field of the object at z=ε and x=X. At this sub-wavelength distance, the field can be expressed as shown in the following EQUATION 8:

$${f}_{3} ( x , z = ϵ ) = {f}_{2} ( x , z = ϵ ) rect ( \frac{x}{X + w} )$$

Again taking the Fourier transform and expressing field at a remote distance in terms of this transform, one is left with the following expression as shown in the following EQUATION 9 for the solution in the far field for near field device of FIG. 9:

f(x,z=Z)=∫_{-ω/2πc}^{+ω/2πc}dαₓexp(−2πiαₓx)F(αₓ,z=0)exp(−2πi(α²−αₓ²)^{½}(Z−ε))

$$f ( x , z = Z ) = {\int }_{- ω / 2 π c}^{+ ω / 2 π c} ⅆ {α}_{x} exp ( - 2 π i {α}_{x} x ) F ( {α}_{x} , z = 0 ) exp ( - 2 π {i ( {α}^{2} - {α}_{x}^{2} )}^{1 / 2} ( Z - ϵ ) ) \times {\int }_{- ∞}^{∞} ⅆ {α}_{x} 4 {E}_{0} cos {α}_{x} ⅆ \frac{sin ( {α}_{x} - {α}_{x} ) L}{{α}_{x} - {α}_{x}} exp ( - 2 π {i ( {α}_{x}^{2} - {α}_{x}^{′2} )}^{1 / 2} ϵ ) \times \frac{sin 2 πα {w}_{x}}{2 {πα}_{x}} exp ( 2 π {i ( {α}_{x}^{2} - {α}_{x}^{′2} )}^{1 / 2} X )$$

One can see, through the presence of a nearby aperture, the expression for the far field contains high frequency components. That is, high spatial frequencies that do not propagate in the conventional instrument are present in the far field for near field device.

In examining the graph in FIG. 10, one can see the effect of increasing the tip-sample separation. For this analysis, the aperture width w was taken to be 80 nm, and the distance between the DNA bands and the NFOD tip ranged from 10 to 70 nm as shown. The DNA bands separation is clearly resolved as the aperture is located at a distance of 10 nm from the DNA bands. The images blurs with increasing tip-sample separation e until at z=70 nm, a single feature is seen and the two bands are not resolved. Similarly, the effect of increasing DNA bands separation can be seen in FIG. 11 in which z was maintained at 30 nm and FIG. 12 in which case z was maintained at 300 nm. The two bands are quite evident for d=20 nm, but definition decreases with d until at d=50 nm, and beyond. The two images are no longer distinguishable when z=300 nm from sample.

The field near the aperture is confined in the transverse direction to approximately the size of the aperture. This confinement holds for one or two aperture lengths from the screen, after which the field pattern diverges rapidly. To this extent, FIG. 10 is an accurate representation of radiation passing through a sub-wavelength aperture, and one can expect a near-field microscope based on this design to image a localized sample region as shown in the graph.

The total energy, integrated over the transverse direction decreases with separation from the screen indicating that some of the energy is trapped in the vicinity of the aperture. One can conclude that the trapped energy is contained in the evanescent waves, while the energy that travels far away from the aperture corresponds to the propagating waves.

One important conclusion is the detector tip has to be almost in contact with sample to capture the near-field information. Hence, no matter how sensitive the photo-detectors are, if they do not have high-resolution power they are pretty useless for DNA sequencing on a 2 inch×2-inch chip. The only way to increase the resolution is to capture near-field information of the image.

The near field exists in close proximity to the specimen, less than one optical wavelength. Using a tiny aperture and placing that aperture in the near field of the specimen, optical microscopy can achieve significantly greater resolving power. According to Synge's suggestion, the specimen is placed in the near field of the aperture, and light is delivered through the aperture so that it impinges upon and is reflected from or transmitted through the specimen. The reflected or transmitted light is then collected and viewed with a conventional optical microscope. In this way, only a tiny portion of the specimen is illuminated, hence all of the light entering the optical microscope corresponds to a single microscopic feature. This technique is thus capable of producing higher resolution than conventional optical microscopes.

A number of different implementations of Synge's idea have been experimented with. Pohl suggested that optical implementations could be achieved by coating the tip of a prism-like crystal. The first successful optical near-field demonstration was by a group at Cornell, which “taffy-pulled” glass micropipettes down to sub-wavelength diameters and defined the aperture by metallic overcoats. The taffy-pulled micropipette was highly inefficient, because the sub-wavelength diameter of the pipette choked off virtually all of the light, so that very little light would exit through the aperture to impinge upon the specimen.

Betzig and coworkers at AT&T Bell labs improved upon the Cornell taffy-pulled micropipette by replacing the glass micropipette with a fiber optic cable. See, Betzig, 1992. Using the fiber optic cable Betzig and coworkers increased efficiency by three or four orders of magnitude. The Betzig device is manufactured by heating the fiber optic cable and then taffy-pulling it to sub-wavelength diameter, followed by a metallic overcoat.

While the Betzig technique improves efficiency, a fundamental problem still remains. Although light will propagate efficiently down a fiber optic cable of standard diameter, the light becomes choked off when the diameter is reduced beyond a certain dimension. This is because light propagates in a waveguide-like fashion in the fiber optic cable of standard diameter. Specifically, light is confined to the inner core of the fiber optic cable by total internal reflection at the inner core-outer cladding boundary. When confined to the inner core in this fashion, light is said to be in the propagating mode.

However, when the diameter of the inner core is reduced by his technique, the propagating mode gives way to an evanescent mode. In the evanescent mode the optical energy is no longer truly propagating and is no longer confined to the fiber optic core, but rather a portion of the energy dissipates or escapes. Longer the distance light must travel in the evanescent mode; the more energy escapes from the core. The solution for this problem would be to reduce the distance light has to travel in an evanescent mode to in order to benefit from the technique. The degradation in both resolution as well as efficiency has significant consequences. Although taffy-pulling can produce extremely small apertures, the resulting efficiency is not high enough that virtually no usable light can travel beyond the aperture and the near field information is not captured efficiently. The present invention overcomes the limitation of the above described present day technology; additionally the proposed invention is not based on fiber optic. The present invention provides a robust approach to manufacture an NFOD with an aperture size in order of 10-20 nm that tapers non-linearly to a couple microns at the top. The sharpness of the optical wave-guide created by the small aperture size, combined with the short distance that light has to travel to be detected, greatly benefits the near-field optical imaging capability of the present invention.

The NFOD of the present invention has a tapered tip that protrudes vertically downward from the surface of the top substrate and that comprises a portion of the outer core made out of metal for light confinement in the optical waveguide. The NFOD can be integrated with or without a lens. The tapered tip defines an optical waveguide with an aperture of 10-20 nm at its tapered extremity. As will be more fully explained below, the tip is tapered nonlinearly with respect to the vertical axis of the substrate. An optically opaque coating such as sputtered metal is applied to the tapered tip to reduce the evanescent propagation along the tip length.

The NFOD design of the present invention seeks to minimize the distance over which light travels through the evanescent mode region, as well as the distance it travels to detector for much enhancement in signal-to-noise ratio, and magnifying the light signal by 10-50 times to maintain the desired high resolution. The efficiency of the detector is dramatically improved by eliminating the non-guiding dielectric mode region, which typically spans more than a hundred wavelengths in a probe of conventional taffy-pulled construction.

Thus, whereas the conventional taffy-pulled probe has an elongated adiabatic taper (i.e., a taper over many optical wavelengths), the NFOD of this proposal avoids an elongated adiabatic taper. This means that light propagating down the tip spend very little time traversing the lossy adiabatic region. It is in this lossy adiabatic region that much of the optical energy is lost in the conventional taffy-pulled probe. The NFOD achieves the desired light-collecting aperture size with a significantly shorter probe length, thereby allowing the probe to deliver optical energy at between two to three orders of magnitude brighter than competitor's fiber optical probe. To appreciate the significance of this, consider that in photographic terms, one order of magnitude yields improved sensitivity of between 3 to 4 f-stops and two orders of magnitude yields improved sensitivity of between 6 to 7 f-stops. The NFOD is then integrated into a glass lid that is then assembled on the top of an already etched glass channel. This approach allows one to manufacture the NFOD and the glass lids separately and to attach them to different channel designs (glass, plastic, quartz, etc) so long as one has access to the layout design of the channel that one plans on using.

The present invention is an uncooled NIR detector and is based in part on pyroelectric polymer sputtered thin film. This film offers good sensitivity, low noise, thermal stability, and minimum electromagnetic and noise interference. The technical approach to the NIR detector configuration is relatively simple. The sensing structure consists of thin film pyroelectric polymer sandwiched between two conductive layers one a heat seeking or absorbing layer and the second a pyroelectric or piezoelectric layer on a optically translucent oxide layer, which is the optical waveguiding layer. To increase the energy conversion efficiency, a near-infrared (“NIR”) absorbing layer can be applied to underneath of the PVDF pyroelectric layer. The heat absorbing layer can be designed to absorb with nearly 100% efficiency over a broad range of wavelength or alternatively a narrow range of wavelength as desired. However, in order that a heat absorbing layer does not increase the thermal time constant of the NIR absorbing layer, slowing the detecting response down and decrease the sensitivity, the heat absorbing layer is required to have a small thermal mass and high thermal conductivity. As this design approach is aimed at a very low-cost detector, it is also desirable that a reliable non-critical process can manufacture the heat absorbing layer. A number of methods of depositing NIR heat absorbing layers for pyroelectric NIR detectors have been reported. See, Parsons, A. D. and Pedder, D. J., J. Vac. Sci. Technology, 1988, A6, pp. 1686-1689; Turnbull, A. A., Proc. SPIE, 1985, 588, pp.38-43; Lang, W. Kühl, K. and II Sandmaier, Sensors and Actuators A, 1992, 34, pp. 343-348; Bauer, S. Bauer-Gogonea, S. Becker, W. Fettig, R. Ploss, B. Ruppel, W. Von Münch, W., Sensors and Actuators A, 1993, 37-38, pp. 497-501; Liddiard, K. C., Infrared Phys. Techno, 1993, 34, pp. 379-387.

Homogeneous thin metal films are eminently suitable as heat seeker layers, which also serve as the first electrode and form a n 4/λ resonant cavity absorber. Very thin metal layers are suitable for deposition as electrode/heat seeker layers on ceramic PVDF surface primarily due to the flatness of the surface, but it is difficult to deposit a homogenous thin metallic layer on thin soft film PVDF or copolymer (“PVDF/TrFE”). This is due to the fact that metal films do not grow homogeneously, but form in islands. See, Lienhard, D. Heepman, F. Ploss, B., Microelectron. Eng., 1995, 29, pp.101-104; Namba, Y., Jpn, J. Appl. Phys., 1970, 9, pp. 1326-1329.

The resistivity of the metal films increases with the decrease in film thickness. The application of conductive polymer, PEDT/PSS (Poly3,4-etylenedioxythiophene polystyrenesulphonate) offers a potential solution to the electrode/heat seeker layer problem for pyroelectric polymers. It has been shown that the conductive polymer, PEDT/PSS is far easier to deposit on either PVDF or VDF/TrFE copolymer than a metal layer thin enough to achieve the same degree of absorption. Moreover, the manufacturing of the conductive polymer film is a noncritical process with a high reproducibility. The current responsivity of 28 μm thick free standing PVDF pyroelectric detector with self-absorbing PEDT/PSS structure is 10 times higher than that of the commercial PVDF film using a nickel-aluminum metal film as surface electrode layer. Since the NIR absorption layer is integrated with the NFOD, the requirement of sensitivity is relaxed.

The next step differs for different NFOD configurations. The configuration shown in FIG. 1 requires a thin layer of dielectric material such as oxide or nitride whereas the configurations shown in FIGS. 2 and 3 require a very thick dielectric layer. This layer is the optical waveguide layer. Having deposited the optical waveguiding material as in case of the configuration shown in FIG. 1, then the heat-seeking layer (typically PEDT/PSS) is spun-on or sputtered on the optical guiding layer.

The heat absorbing layer has two purposes, one to absorb light in the 700-1000 nm wavelength (NIR), and the other to act as the first electrode of a pyroelectric IR-detector. In the case of other two configurations, the optical waveguide layer is polished flat. See FIGS. 2 and 3. In FIG. 2 a photoresist re-flow technique is used to crate an integrated lens on the optical waveguide layer. Deposition of the heat-absorbing layer follows this step. After that the light guiding and heat-absorbing layers are patterned together. After that, the pyroelectric layer, which can be PVDF, ZnO or lead zinc titanium (“PZT”) is sputtered on the heat-absorbing layer and patterned. Among these pyroelectric materials, PVDF has shown higher pyroelectric coefficient than the other two. However, in general any piezoelectric material can be used, as all piezoelectric material have to some extend pyroelectric characteristics.

Next the second electrode is sputtered and patterned. This layer is a metallic reflective layer. The theoretical analysis shows that to achieve the maximum absorbency for three-layer resonant cavity structure with a 9 μm PVDF layer, the first electrode (heat-absorber) must have a sheet resistance of 300-450 Ω/□ and second electrode (reflector) a sheet resistance of 0-4 Ω/□ or less. See, Setiadi, D. He, Z. Hajto, J. and Binnie, T. D., Infrared Phys. Techno, 1999, 40, pp. 267-278. Finally, the backside of the wafer is patterned and etched by deep reactive ion etching to expose the tip of the oxide mold. The tip of the oxide mold and the tip of the metal confining layer are etched away to expose the 10-12 nm radius of the optical waveguiding layer.

The present invention as generally described above, provides an integrated system for substantially lowering the cost and time for sequencing nucleic acids, which system is readily automatable and integratable with upstream or downstream processes.

### BRIEF DESCRIPTION OF THE FIGURES

FIG. 1A depicts the first structure after the wafer providing step.

FIG. 1B depicts the first structure after the first passivation step.

FIG. 1C depicts the first structure after the first photoresist layering step.

FIG. 1D depicts the first structure after the first mask creation step.

FIG. 1E depicts the first structure after the first etching and photoresist removal step.

FIG. 1F depicts the first structure after the first anisotropic etching step.

FIG. 1G depicts the first structure after the second passivation step.

FIG. 1H depicts the first structure after the light confining layer deposition step.

FIG. 1I depicts the first structure after the second photoresist layering step.

FIG. 1J depicts the first structure after the second mask creation step.

FIG. 1K depicts the first structure after the second etching step.

FIG. 1L depicts the first structure after the second etching, photoresist removal and wafer cleaning step.

FIG. 1M depicts the first structure after the light guiding layer deposition step.

FIG. 1N depicts the first structure after the third photoresist layering step.

FIG. 1O depicts the first structure after the third mask creation step.

FIG. 1P depicts the first structure after the third etching and cleaning step.

FIG. 1Q depicts the first structure after the heat absorbent layer deposition step.

FIG. 1R depicts the first structure after the fourth photoresist layering step.

FIG. 1S depicts fourth mask creation step.

FIG. 1T depicts fourth etching, photoresist removal and cleaning step.

FIG. 1U depicts the first structure after the IR sensitive material deposition step.

FIG. 1V depicts the first structure after the fifth photoresist layering step.

FIG. 1W depicts the first structure after the fifth masking step.

FIG. 1X depicts the first structure after the fifth etching, photoresist removal and cleaning step.

FIG. 1Y depicts the first structure after the electrically conductive material deposition step.

FIG. 1Z depicts the first structure after the sixth photoresist layering step.

FIG. 1AA depicts the first structure after the sixth masking step.

FIG. 1BB depicts the first structure after the sixth etching, photoresist removal and cleaning step.

FIG. 1CC depicts the first structure after the seventh photoresist layering step.

FIG. 1DD depicts the first structure after the seventh masking step.

FIG. 1EE depicts the first structure after the seventh etching and photoresist removal step.

FIG. 1FF depicts the first structure after the second anisotropic etching step.

FIG. 1GG depicts the first structure after the eighth etching step.

FIG. 1HH depicts the first structure after the ninth and final etching step.

FIG. 1H′ depicts the second alternative photoresist layering step.

FIG. 1I′ depicts the second alternative mask creation step.

FIG. 1J′ depicts the alternative light confining layer deposition step.

FIG. 1K′ depicts the structure after the alternative lift-off, photoresist removal and wafer cleaning step.

FIG. 2M depicts the second structure after the light guiding layer deposition step.

FIG. 2N depicts the second structure after the polishing step.

FIG. 2O depicts the second structure after the third photoresist layering step.

FIG. 2P depicts the second structure after the third mask creation step.

FIG. 2Q depicts the second structure after the first photoresist heating and reflowing step.

FIG. 2R depicts the second structure after the third etching step.

FIG. 2S depicts the second structure after the fourth photoresist layering step.

FIG. 2T depicts the second structure after the fourth mask creation step.

FIG. 2U depicts the second structure after the fourth etching, photoresist removal and cleaning step.

FIG. 2V depicts the second structure after the heat absorbent layer deposition step.

FIG. 2W depicts the second structure after the fifth photoresist layering step.

FIG. 2X depicts the second structure after the fifth mask creation step.

FIG. 2Y depicts the second structure after the fourth etching, photoresist removal and cleaning step.

FIG. 2Z depicts the second structure after the IR sensitive material deposition step.

FIG. 2AA depicts the second structure after the fifth photoresist layering step.

FIG. 2BB depicts the second structure after the fifth masking step.

FIG. 2CC depicts the second structure after the fifth etching, photoresist removal and cleaning step.

FIG. 2DD depicts the second structure after the electrically conductive material deposition step.

FIG. 2EE depicts the second structure after the sixth photoresist layering step.

FIG. 2FF depicts the second structure after the sixth masking step.

FIG. 2GG depicts the second structure after the sixth etching, photoresist removal and cleaning step.

FIG. 2HH depicts the second structure after the seventh photoresist layering step.

FIG. 2II depicts the second structure after the seventh masking step.

FIG. 2JJ depicts the second structure after the seventh etching and photoresist removal step.

FIG. 2KK depicts the second structure after the second anisotropic etching step.

FIG. 2LL depicts the second structure after the eighth etching step.

FIG. 2MM depicts the second structure after the ninth and final etching step.

FIG. 3M depicts the third structure after the light guiding layer deposition step.

FIG. 3N depicts the third structure after the polishing step.

FIG. 3O depicts the third structure after the third photoresist layering step.

FIG. 3P depicts the third structure after the third mask creation step.

FIG. 3Q depicts the third structure after the third etching, photoresist removal and cleaning step.

FIG. 3R depicts the third structure after the heat absorbent layer deposition step.

FIG. 3S depicts the third structure after the fifth photoresist layering step.

FIG. 3T depicts the third structure after the fifth mask creation step.

FIG. 3U depicts the third structure after the fourth etching, photoresist removal and cleaning step.

FIG. 3V depicts the third structure after the IR sensitive material deposition step.

FIG. 3W depicts the third structure after the fifth photoresist layering step.

FIG. 3X depicts the third structure after the fifth masking step.

FIG. 3Y depicts the third structure after the fifth etching, photoresist removal and cleaning step.

FIG. 3Z depicts the third structure after the electrically conductive material deposition step.

FIG. 3AA depicts the third structure after the sixth photoresist layering step.

FIG. 3BB depicts the third structure after the sixth masking step.

FIG. 3CC depicts the third structure after the sixth etching, photoresist removal and cleaning step.

FIG. 3DD depicts the third structure after the seventh photoresist layering step.

FIG. 3EE depicts the third structure after the seventh masking step.

FIG. 3FF depicts the third structure after the seventh etching and photoresist removal step.

FIG. 3GG depicts the third structure after the second anisotropic etching step.

FIG. 3HH depicts the third structure after the eighth etching step.

FIG. 3II depicts the third structure after the ninth and final etching step.

FIG. 4 depicts in plan view the integrated NFOD/CE chip.

FIG. 5 Depicts the NFOD/CE chip in plan and cross sectional views.

FIG. 5 B-B′ Depicts the NFOD/CE in an enlarged, cross sectional view

FIG. 6 depicts comparison of long and short microfabricated CE illustrating need to have longer channels.

FIG. 7 depicts an illustration of the grating equation.

FIG. 8 depicts the operation of a transmission illumination mode near-field microscope.

FIG. 9 depicts the classical DNA band detection system.

FIG. 10 depicts the relationship between NFOD's tip to sample separation.

FIG. 11 depicts DNA band intensity distribution at tip to sample separation of 30 nm.

FIG. 12 depicts DNA band intensity distribution at tip to sample separation of 300 nm.

### SUMMARY

The present invention recognizes that there is a great demand in the field of medical research and diagnosis for therapid nucleotide sequencing of large DNA fragments and for therapid detection of single biomolecules which needs are met in part by lab-on-a-chip capillary electrophoresis technology. However, sequencing of large DNA fragments and other biomolecules by electrophoretic technology is limited by the poor resolution of such devices which reduces throughput. There is a need for an improved optical detection device which has the power to resolve individual nucleotide bases and single biomolecules and thus provide enhanced speed, sensitivity and throughput. The present invention provides such a device and methods of use.

The present invention includes but is not limited to a near field optical detector device that includes a near field optical detector that is capable of detecting and resolving individual molecules such as nucleotides. The present invention also includes a means for integrating the near field optical detector in a lab-on-a-chip capillary electrophoresis device capable of rapidly and accurately sequencing long stretches of polynucleotides.

The present invention includes a variety of other aspects. These aspects are detailed herein.

A first aspect of the present invention is a method of manufacturing a near field optical detector with a pyramidal detecting layer.

A second aspect of the present invention is a method of manufacturing a near field optical detector wherein the detecting layer is arrayed on a convex lens.

A third aspect of the present invention is a method of manufacturing a near field optical detector with a planar detecting layer.

A fourth aspect of the present invention is a method of manufacturing a chip resident capillary electrophoresis device with integrated near field optical detector capable of rapidly and accurately sequencing long DNA fragments.

### DETAILED DESCRIPTION OF THE INVENTION

### GENERAL DEFINITIONS

Unless defined otherwise, all technical and scientific terms used herein have the same meaning as commonly understood by one of ordinary skill in the art to which this invention belongs. Generally, the nomenclature used herein and the microfabrication technologies and procedures described below are well known and commonly employed in the art. Conventional methods are used for these procedures, such as those provided in the art and various general references such as Gregory T. A. Kovacs' textbook entitled “Micromachined Transducers Sourcebook” which is published by McGraw-Hill or W. Scot Ruska's textbook entitled Microelectronic Processing by the same publisher. Where a term is provided in the singular, the inventors also contemplate the plural of that term. The nomenclature used herein and the laboratory procedures described below are those well known and commonly employed in the art. As employed throughout the disclosure, the following terms, unless otherwise indicated, shall be understood to have the following meanings:

“Directly” refers to direct causation of a process that does not require intermediate steps.

“Indirectly” refers to indirect causation that requires intermediate steps. Conventional methods are used for these procedures, such as those provided in the art and various general references. Terms of orientation such as “up” and “down” or “upper” or “lower” and the like refer to orientation of the parts during use of the device. Where a term is provided in the singular, the inventors also contemplate the plural of that term. The nomenclature used herein and the laboratory procedures described below are those well known and commonly employed in the art. As employed throughout the disclosure, the following terms, unless otherwise indicated, shall be understood to have the following meanings:

An element of the present invention is “integral to” another element of the present invention when the two elements are manufactured as a single piece.

An element of the present invention is “separate from” another element of the present invention when the two elements are manufactured as separate pieces.

A “reagent” can be any chemical, including organic compounds and inorganic compounds and combinations thereof. A reagent can be provided in gaseous, solid, or liquid form, or any combination thereof, and can be a component of a solution or a suspension. A reagent preferably includes fluids, such as buffers useful in methods of detecting analytes in a sample or specimen, such as anticoagulants, diluents, buffers, test reagents, specific binding members, detectable labels, enzymes and the like. A reagent can also include an extractant, such as a buffer or chemical, to extract an analyte from a sample or specimen or a sample collection device. For example, a buffer can be used to free biological components such as cells or etiological agents on or within a sample collection device, such as a swab. Alternatively, an extractant, such as an acid, can be use to extract analytes from the sample or specimen, such as LPS from bacteria.

“Sample” is any material to be tested for the presence and/or concentration of an analyte in a sample or specimen, or to determine the presence and/or numbers of one or more components of a sample or specimen, or to make a qualitative assessment of a sample or specimen. A sample can be the same as a specimen. Preferably, a sample is a fluid sample, preferably a liquid sample. Examples of liquid samples that may be tested using a test device of the present invention include eukaryotic and prokaryotic cellular contents, DNA samples, bodily fluids including blood, serum, plasma, saliva, urine, ocular fluid, semen, and spinal fluid; water samples, such as samples of water from oceans, seas, lakes, rivers, and the like, or samples from home, municipal, or industrial water sources, runoff water or sewage samples; and food samples, such as milk or wine. Viscous liquid, semi-solid, or solid specimens may be used to create liquid solutions, eluates, suspensions, or extracts that can be samples. For example, throat or genital swabs may be suspended in a liquid solution to make a sample. Samples can include a combination of liquids, solids, gasses, or any combination thereof, as, for example a suspension of cells in a buffer or solution. Samples can comprise biological materials, such as cells, microbes, organelles, and biochemical complexes. Liquid samples can be made from solid, semisolid or highly viscous materials, such as soils, fecal matter, tissues, organs, biological fluids or other samples that are not fluid in nature. For example, these solid or semi-solid samples can be mixed with an appropriate solution, such as a buffer, such as a diluent or extraction buffer. The sample can be macerated, frozen and thawed, or otherwise extracted to form a fluid sample. Residual particulates can be removed or reduced using conventional methods, such as filtration or centrifugation. Other technical terms used herein have their ordinary meaning in the art that they are used, as exemplified by a variety of technical dictionaries.

### MICROMACHINING DEFINITIONS

“Anisotropic etching” means the methods of forming voids or cavities including suitable wet chemical etchants and dry processing procedures as known in the art. These include any etch which etches significantly faster in one crystal direction than in other crystal directions. For example, an etchant such as tetramethylammonium hydroxide (TMAH) or ethylenediamine pyrocatechol solution (EDP) and water may be used to preferentially attack the <100> planes of substrate material consisting of n-type silicon or low or moderately doped p-type silicon. Other wet etchants are potassium hydroxide and hydrazine solutions. Dry etchants include the use of silicon fluoride gas to anistropically etch various glasses or else induced current plasma techniques (“ICP”). Etching of most of these substrate by either a wet chemical etching or dry etching proceeds until the crystal planes at the bottom of the void etched in the substrate meet to create an inverted pyramidal shape. Glasses etched by silicon fluoride, on the other hand, form bullet shaped voids which are similarly useful in the manufacture of the present invention.

“Anisotropy” refers to sidewalls of an etched void or structure which are in sharp definition in the vertical direction with respect to the substrate surface into which the void or structure is micromachined. Anisotropic micromachining processes typically progress in a preferred direction rather than with equal rates in all directions as is the case with isotropic micromachining processes.

“Cleaning process” refers to any of a number of common wafer cleaning procedures such as those described in Micromachined Transducers Sourcebook authored by Gregory T. A. Kovacs and published by McGraw-Hill (copyright 1998). RCA and piranha are examples of some specific cleaning processes useful in the micromanufacture of the present invention.

“Dry etching” refers to the use of induced current plasma (“ICP”) to etch a silicon substrate.

“Etching processes” refers to any method used to etch and remove different materials. For example, to etch and remove silicon oxide one could use either a plasma etching process, reactive ion exchange etching (“RIE”) or chemical wet etching process. Other suitable etching processes for silicon oxide and other materials are described in Micromachined Transducers Sourcebook authored by Gregory T. A. Kovacs and published by McGraw-Hill (copyright 1998).

“Heat absorbent materials” refers to materials such as gold, carbon and PEDT/PSS polymer.

“Heat absorbent material deposition method” refers to metalization procedures such as sputtering, polymer sputtering and spin-on.

“IR or infra-red sensitive material” refers generally to pyroelectric and piezoelectric materials and specifically to polyvinylidene fluoride (“PVDF”), polyvinylidene fluoride/trifluoroethylene copolymer (“PVDF/TrFE”), lanthanum-doped lead zirconate tantalate (“PZT”), ZnO, TiW, lithium tantalate, barium titanate, triglycine sulfate, polyvinyl fluoride and quartz.

“IR or infra-red sensitive material deposition method” refers to sputtering, evaporation, spin-on, bonding and electroplating methods among others.

“Light guiding material” refers to either silicon, silicon dioxide, silicon nitride or polymers.

“Light guiding material deposition methods” refers to any of a number of suitable deposition methods including the following: low-pressure chemical vapor deposition (“LPCVD”), chemical vapor deposition (“CVD”), plasma-enhanced chemical vapor deposition (“PECVD”), oxidation furnaces, sputtering, spin-on.

“Masking step” means depositing a layer of masking material from a couple of angstroms to a couple of microns thickness on an underlying layer or substrate.

“Masking technique or procedure” means any known technique for providing a mask to an underlying layer. One of the preferred masking techniques is the photolithographic patterning process which involves a series of micromachining steps starting first with depositing a layer of photoresist on one or more underlying layers or substrate layers by spinning. Second, baking the spun-on photoresist layer. Third, exposing the baked photoresist layer to ultraviolet (“UV”) light passing through a mask formed by a quartz plate brought in close physical proximity to the surface f the baked photoresist layer which quartz plate is covered with a thin film of chromium a portion of which chromium film has been selectively removed to allow light through. Fourth, the portions of the photoresist which were exposed to the UV light are removed by plasma etch or wet chemical etch such as a developer solution, leaving only the non-exposed regions behind to act as barrier for further etching of the underlying layer or layers. Fifth, the wafer or deposited layers are cleaned either by RCA's commercially available photoresist removal products or the sulfuric acid/hydrogen peroxide cleaning process known as the “piranha” cleaning process.

“Passavation layer” means material such as thermal silicon oxide (“Oxide”) created on a silicon substrate in an atmospheric furnace by either dry or wet oxidation processes; low temperature oxide (“LTO”), phosphorous doped silicon oxide (“PSG”), or silicon nitride (“SiN”) each of which can be created by low pressure chemical vapor deposition; spun-on glass and spun-on polymers created by spinning processes; or metals such as gold, wolfram and tungsten created by sputtering processes, electron beam evaporative processes or resistant heating evaporation process.

“Passavation procedure” can refer to the grow of a layer of oxide, for example silicon dioxide on a silicon wafer, on the surface of a wafer by means such as thermal oxidation. Alternatively, passivation procedure can refer to the deposition of the other previously mentioned passivation materials by one of the described creation methods.

“Substrate” generally means a wafer shaped material for micromachining. In particular, substrates useful in the present invention include wafers of single crystal semiconductors such as single crystal <100> oriented silicon (“Si”), Germanium (“Ge”) and Galium Arsenide (“GaAs”) which have useful crystal plane anisotropy for micromachining and potential for integration of active circuits. Other materials such as glasses, particularly borosilicate and soda glass can be used as the substrate. A suitable etchant for glass is SiF₆. For the present invention, the substrate referenced in the examples is single crystal <100> oriented silicon.

“Wet chemical etching” refers to the use of potassium hyroxide (“KOH”), ethylene diamine pyrochatechol (“EDP”), tetramethylammonium hydroxide (“TMAH”) or hydrazine to etch silicon and other suitable substrates and deposited layers. Other wet chemical etchants are known to those familiar with the art and can be used in appropriate instances.

### ELECTROPHORESIS DEFINITIONS

Electrophoresis gets its name from the process whereby the movement of ions is produced under the influence of an applied voltage across a field that the ions exist. It is well known that opposites attract and in electrophoresis, ions of opposite charge to electrodes on either end of the voltage, will migrate toward that electrode. Simply stated, ions that are negatively charged will move or migrate toward the positively charged electrode and vice versa for the positively charged ions. This is the basis for which CE and CEC operate.

Rate of Migration: What makes CE a powerful tool in separation science is the phenomena whereby every ion will migrate at different rates. This difference is based on its quantity of charge compared to its relative hydrodynamic size. Hydrodynamic size very closely relates to the mass of the molecule. It is commonly called the “Charge to Mass Ratio”. A simpler term that is used to describe the molecules affinity for its opposite electrode is commonly called “Electrophoretic Mobility”. These mobilities can be exploited for incredible separations of very closely structured molecules.

Ionic Mobility: The actual mobility of an ion takes into account the environment that the ion exists in during the separation process. For example, electrophoretic mobility will differ from actual mobility when viscosity changes and of course the amount of voltage that is applied. In simpler terms, this makes the attraction much greater or weaker to the opposite charged electrode. The more voltage, the more attraction and greater the speed.

Electro-Osmotic Flow (“EOF”) CE has incredible efficiency or ability to separate similarly structured compounds. This is due to EOF. When a voltage is applied across a tube filled with an electrolyte solution (a solution that conducts electricity), the solution begins to move toward the cathode. This is not similar to the chromatographic pump, but it does provide the flow of materials past a detector like the pump in HPLC. This should not be confused with electrophoretic mobility described above. It is a separate phenomenon and is exploited in CE for maximum flexibility in separation power. Both EOF and Electrophoretic mobility can occur at the same time working in opposite directions to provide greater resolution.

Plug Flow in CE: In a capillary, the charge from electrode to electrode is conducted by the buffer system (ions in a water solution) or what is better described as the Back Ground Electrolyte (BGE). Ions of the BGE conducts electricity and provide the current needed in CE. This current is evenly distributed over the entire capillary diameter and the phenomenon of EOF occurs (evenly). The water molecules in the BGE also naturally move toward the cathode in a very even manner. The electro osmotic flow that occurs is called a “plug flow” because of its plug like shape. Due to this very even flow and flat front, extremely high Theoretical Plate Counts are observed in CE.

“CE Instrument Schematic” A typical CE instrument uses the following components to achieve both EOF and Electrophoretic Mobility and therefore separations: (1) Cathode (Negatively Charged Electrode); (2) Anode (Positively Charged Electrode); (3) Power Supply to generate Voltage/Current; (4) Catholyte (Buffer Solution at the Cathode End); (5)Anolyte (Buffer Solution at the Anodic End); (6) Capillary (25 mm to 100 mm ID); (7) A Detection Method; (8) Data Acquisition Method; (9) Injection means. Samples are introduced into the capillary for separation by two different methods. Both having advantages and disadvantages; Electrokinetic injection and Hydrodynamic (Vacuum or Pressure) Injection. Electrokinetic injection works when the capillary is placed into the catholyte on one end and into the anolyte (containing the sample to be analyzed) on the other end. When a voltage is applied, the EOF moves from the tip of the capillary to the end of the capillary. A siphoning effect occurs, dragging a representative sample into the capillary. Also, ions begin moving into the capillary from the buffer solution due to electrophoretic mobility as part of the sample loading. This can be an advantage when trying to analyze small concentrations of these ions. These injections usually last for 1-5 seconds. Hydrodynamic injection works when a pressure is applied at one end of the capillary or a vacuum is applied. The pressure differential between the two opposite sides of the capillary will make liquid move into the capillary. Temperature and therefore viscosity plays a major role in reproducibility in both injections so it is important to control both.

Water Plug: After injection the capillary injection end is moved into a sample vial containing CE grade water. A “water plug” is injected in the same manner that the sample was injected. Then the capillary is moved into a different anolyte solution that does not contain the sample. Voltage is applied across the capillary and the separation takes place as the separated samples move (electrophoretically and with EOF) past the detector.

Capillary electrophoresis (“CE”), is a technique where an electrophoretic separation takes place in a very small capillary tube. The capillaries typically used for CE are inexpensive and commercially available. Typically capillaries range about 30 to 50 centimeters in length, 0.150 to 0.375 millimeters in outer diameter, and a 0.010 to 0.075 millimeter diameter channel down the center. In a CE separation the capillary is filled with buffer and each end is immersed in a vial of the same buffer. A sample of analyte is injected at one end, either by electrophoresis or by pressure, and a electric field of 100 to 700 volts/centimeter is applied across the capillary. The analyte migrates down the capillary due to the electric field (electrophoresis) separating into components as it goes. At the other end of the capillary each of the separated analytes is detected and quantified. CE separates molecules based on differences in their electrophoretic mobility in the buffer. Electrophoretic mobility is proportional to the charge of the molecule divided by its frictional coefficient. This is approximately equal to the charge to mass ratio of the molecule. So in general any molecules with differing charge to mass ratios can be separated by CE. Detection of these analytes is not a trivial task. Because the capillaries are so tiny only a very small amount of sample may be injected onto them. Typically a 1 nanoliter sample is injected into the capillary. Some detection systems presently used are UV absorbance, mass spectrometry, and laser induced fluorescence. Laser induced fluorescence (“LIF”) is by far the most sensitive of these. A simple LIF detector requires only a laser beam passing through the capillary to excite the analyte, a microscope objective at 90 degrees to the laser to collect the fluorescence emission, and a optical filter and photomultiplier tube (“PMT”) to measure the emitted light. Shining the laser through a round capillary creates a lot of scattered laser light. Some of this scattered light is detected along with the fluorescent emission and increases the background. Increases in the background mean more noise and thus a poorer detection limit.

With the advent of the human genome project there has become a large effort to develop faster, higher throughput, and less expensive technologies for things like DNA sequencing and DNA mapping. The traditional separation technology for DNA analysis is slab gel electrophoresis. CE separation has many advantages over slab gel separations. CE separations are faster then slab gels and are capable of producing greater resolution. While a slab gel can analyze several samples at once and a simple CE instrument only one sample at a time a number of commercial concerns have developed CE instruments that use tens and even hundreds of capillaries simultaneously.

It is not easy to analyze DNA in capillaries filled only with buffer. That is because DNA fragments of different lengths have the same charge to mass ratio. To separate DNA fragments of a different sizes the capillary needs to be filled with sieving matrix of some sort. One excellent sieving matrix is linear polyacrylamide (acrylamide polymerized without bis-acrylamide) for DNA sequencing separations. This material is not rigid like a crosslinked gel but looks much like glycerol. With a little bit of effort it can be pumped in and out of the capillaries. To simulate the separation characteristics of an agarose gel one can also use hydroxyethylcellulose. It is not much more viscous then water and can easily be pumped into the capillaries.

Performing electrophoresis in small-diameter capillaries allows the use of very high electric fields because the small capillaries efficiently dissipate the heat that is produced. Increasing the electric fields produces very efficient separations and reduces separation times. Capillaries are typically of 50 μm inner diameter and 0.5 to 1 m in length. The applied potential is 20 to 30 kV. Due to electroosmotic flow, all sample components migrate towards the negative electrode. A small volume of sample (10 nL) is injected at the positive end of the capillary and the separated components are detected near the negative end of the capillary. CE detection is similar to detectors in HPLC, and include absorbance, fluorescence, electrochemical, and mass spectrometry. The capillary can also be filled with a gel, which eliminates the electroosmotic flow. Separation is accomplished as in conventional gel electrophoresis but the capillary allows higher resolution, greater sensitivity, and on-line detection.

Electroosmotic flow: The surface of the silicate glass capillary contains negatively-charged functional groups that attract positively-charged ions. The positively-charged ions migrate towards the negative electrode and carry solvent molecules in the same direction. This overall solvent movement is called electroosmotic flow. During a separation, uncharged molecules move at the same velocity as the electroosmotic flow (with very little separation). Positively-charged ions move faster and negatively-charged ions move slower.

Capillary Electrophoresis is a family of related techniques that employ narrow-bore (10-200 μm i.d.) capillaries to perform high efficiency separations of both large and small molecules. Various CE techniques perform separations based on several mechanisms, such as molecular size (sieving), isoelectric focusing and hydrophobicity (MECC). High voltages are used to separate molecules based on differences in charge and size. In free-zone CE, separation results from the combination of electrophoretic migration (the movement of charged molecules towards an electrode of opposite polarity) and electroosmotic flow (the bulk of electrolyte flow caused by a charged inner capillary wall and an applied potential). Positive, neutral and negatively charged molecules migrate toward the negative electrode in the capillaries. The magnitude of the electroosmotic flow carries negatively charged molecules as well as neutrals, towards the negative electrode. The electroosmotic flow is dependent upon field strength, electrolyte pH, buffer composition and ionic strength, viscosity and capillary surface characteristics; all of which can be used singly or in combination to enhance separations. Detection is achieved by monitoring UV absorbance directly on-line through a window in the capillary. Other detection options include Laser-Induced Fluorescence, Diode Array and Mass Spectrometry. Sample injection into the capillary is accomplished either by applying pressure or voltage to the sample vial.

### INTRODUCTION

The present invention recognizes that available technologies used in genomic sequencing can only sequence short DNA fragments, are costly to run, are slow, and are, due to their complexity, susceptible to errors caused by the humans running the sequencing machines. There is also recognized a general need in the sciences and industry for the ability to rapidly identify individual atoms and molecules both organic and inorganic in samples.

As a non-limiting introduction to the breath of the present invention, the present invention includes several general and useful aspects, including:

1) a method of manufacturing a near field optical detector with a pyramidal detecting layer;

2) a method of manufacturing a near field optical detector wherein the detecting layer is arrayed on a convex lens;

3) a method of manufacturing a near field optical detector with a planar detecting layer; and

4) a method of manufacturing a chip resident capillary electrophoresis device with integrated near field optical detector capable of rapidly and accurately sequencing long DNA fragments.

These aspects of the invention, as well as others described herein, can be achieved by using the methods, articles of manufacture and compositions of matter described herein. To gain a full appreciation of the scope of the present invention, it will be further recognized that various aspects of the present invention can be combined to make desirable embodiments of the invention.

### I THE FIRST STRUCTURE—A NEAR FIELD OPTICAL DETECTOR WITH PYRAMIDAL DETECTING LAYER

The present invention includes the following embodiment in which the detecting layer is in close proximity with the detector tip. This and the following embodiments of the Near Field Optical Detector (“NFOD”) can be incorporated into a number of devices useful for the detection of extremely small molecules. In particular this and the following embodiments of the NFOD can be incorporated into a device useful for the rapid and accurate sequencing of long fragments of DNA.

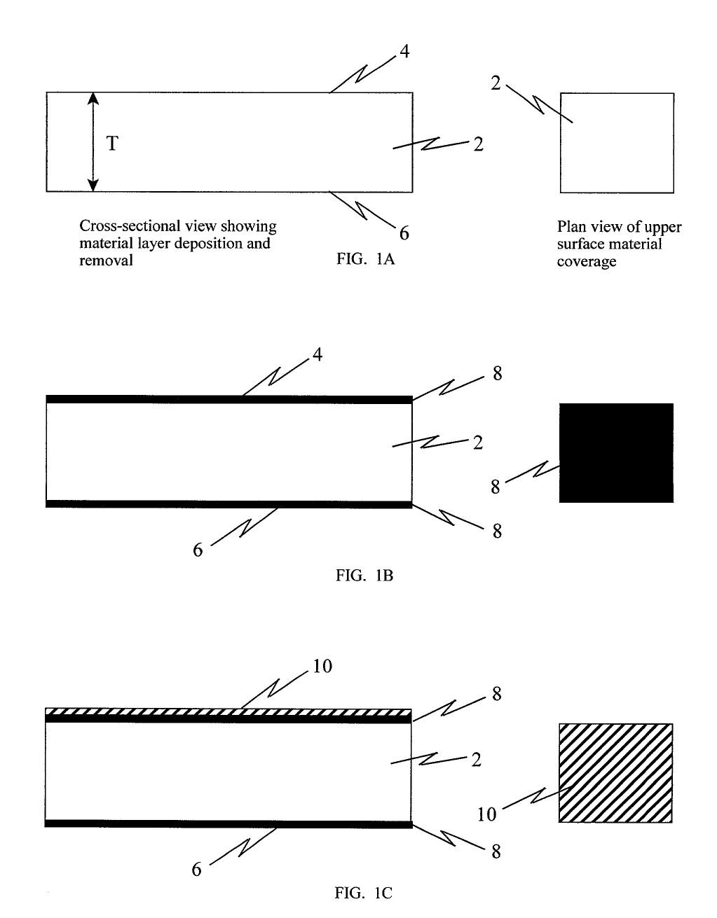

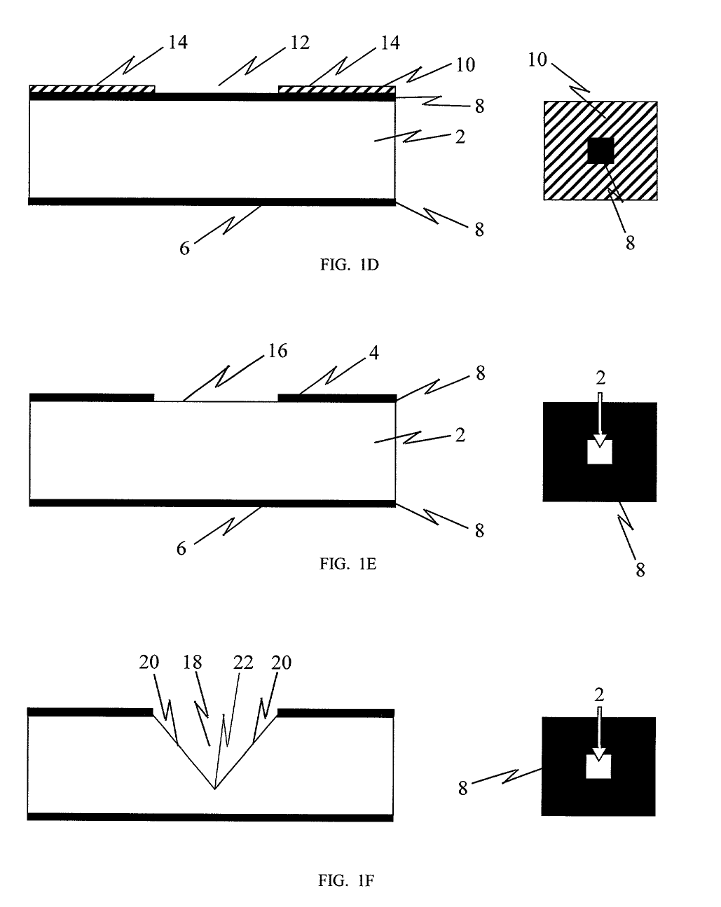

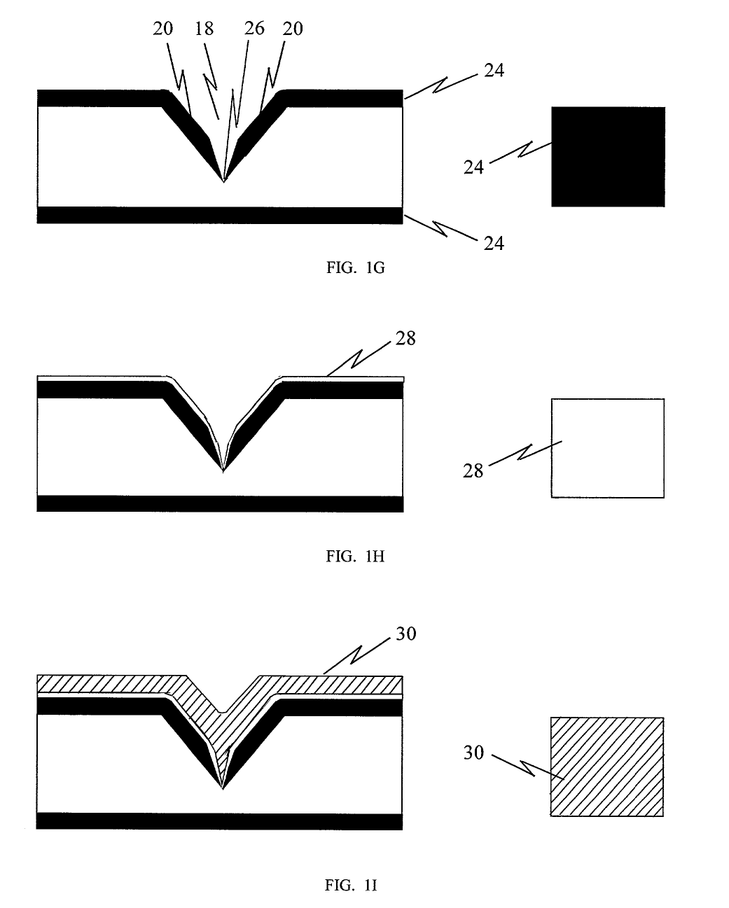

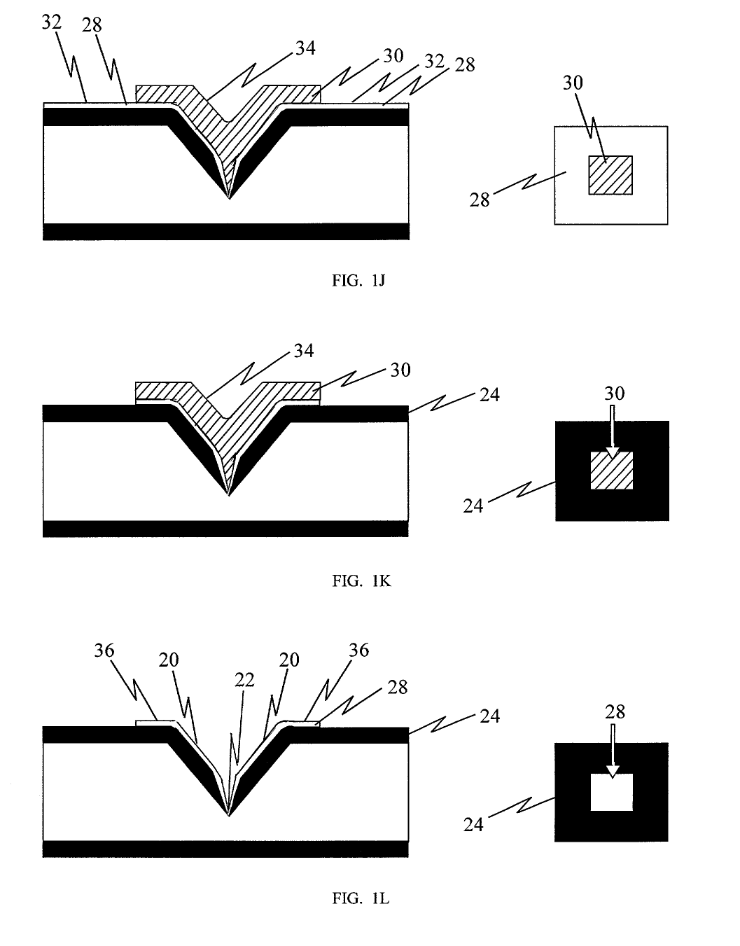

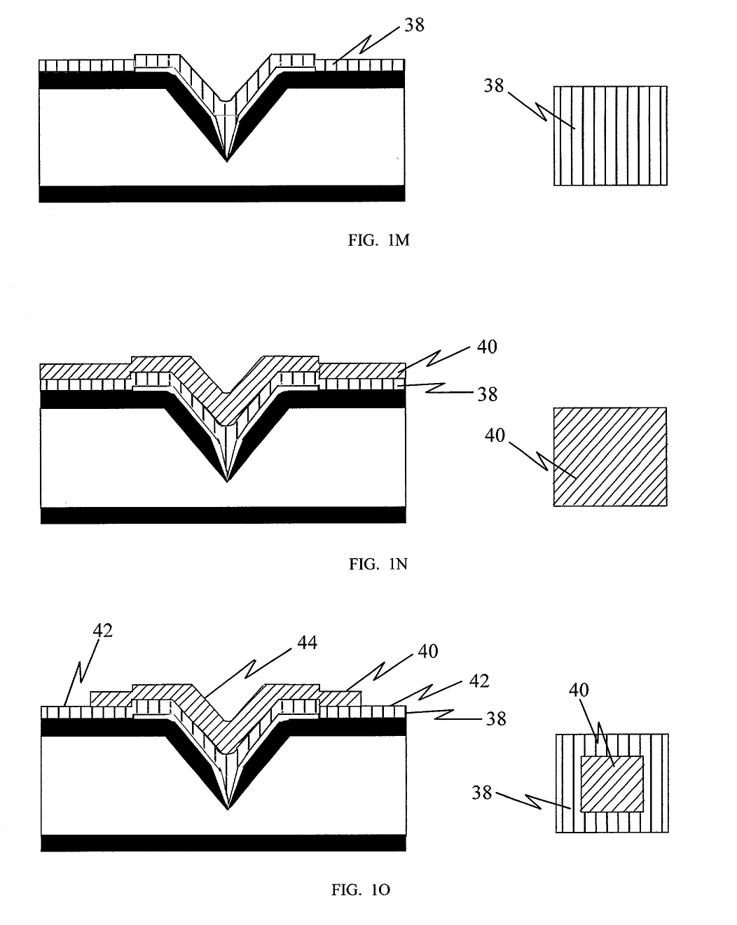

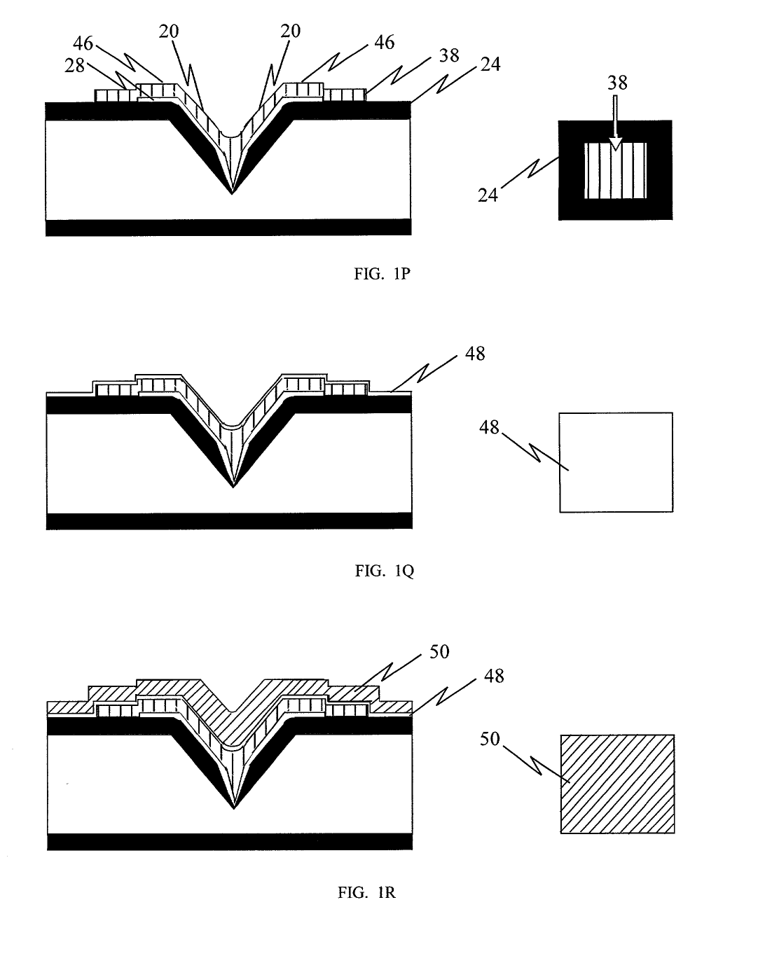

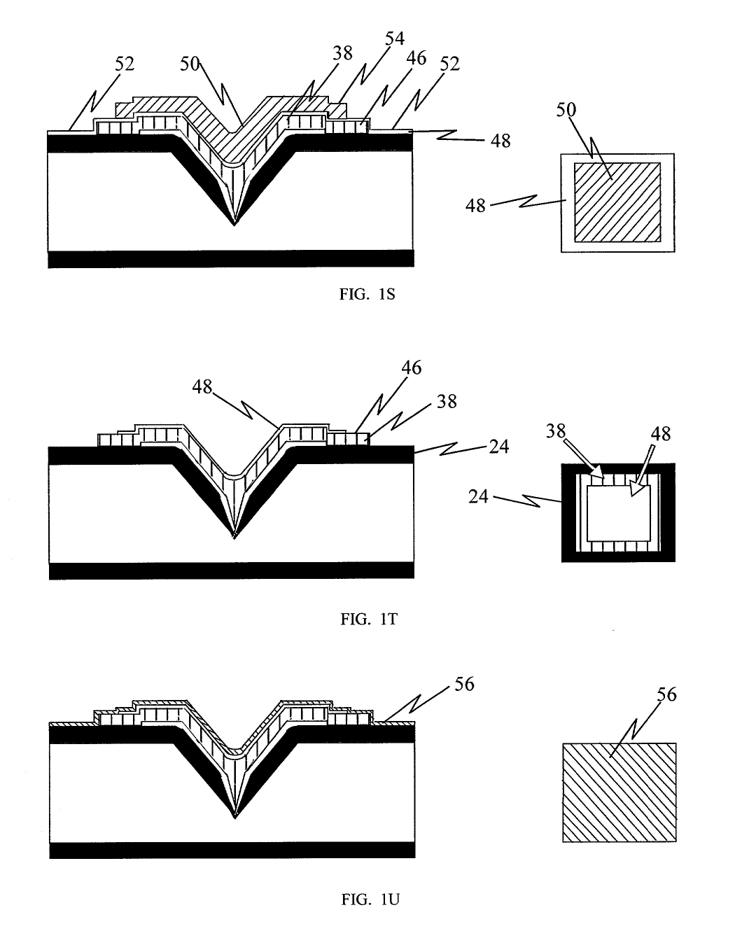

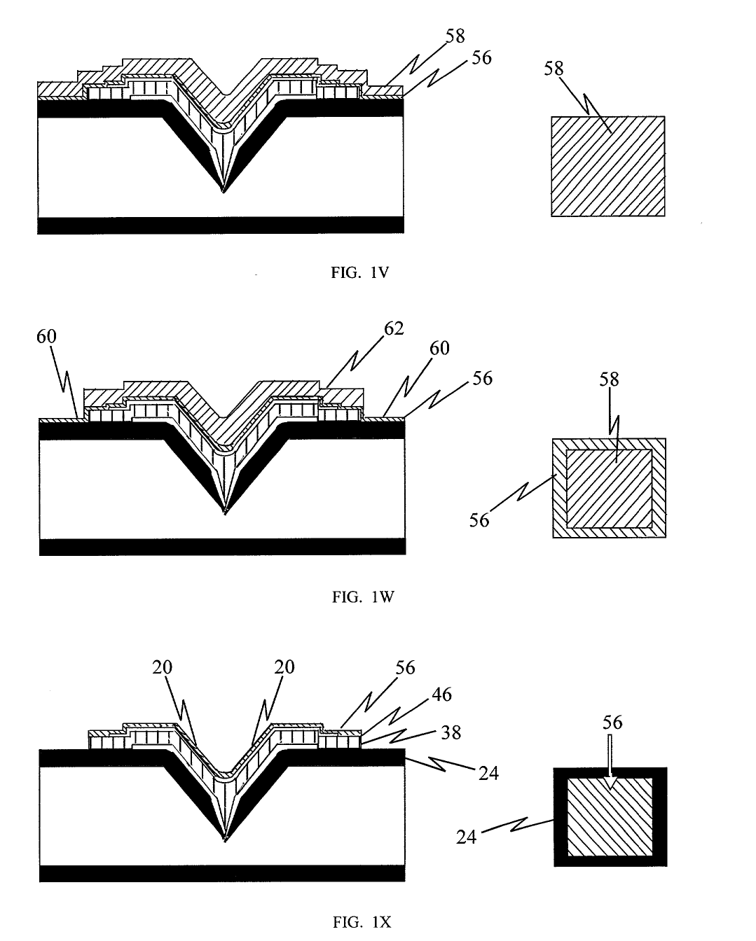

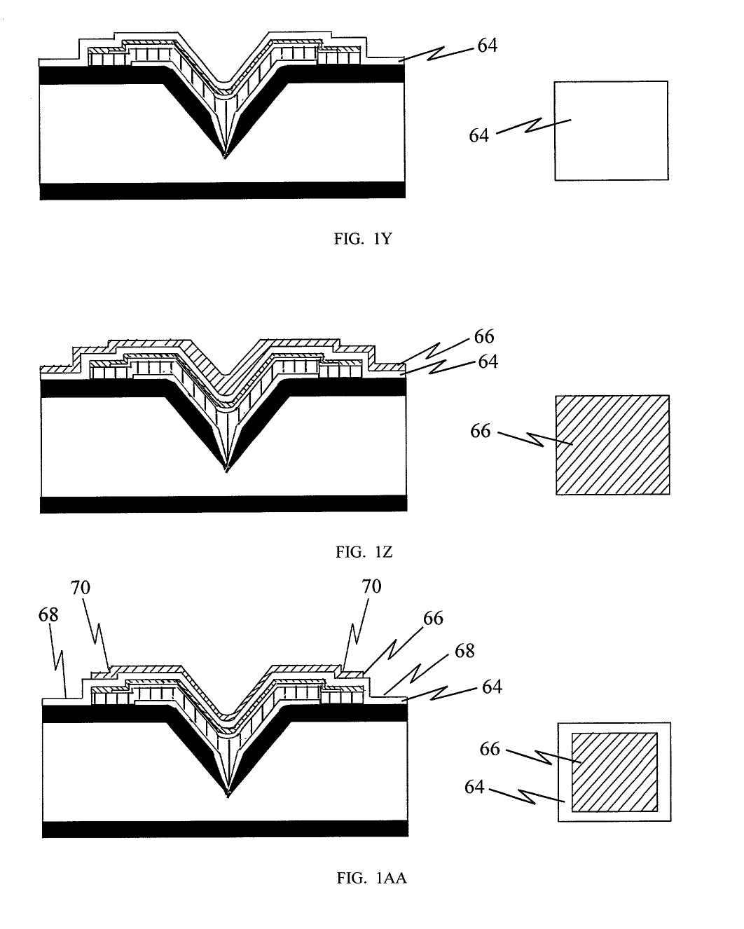

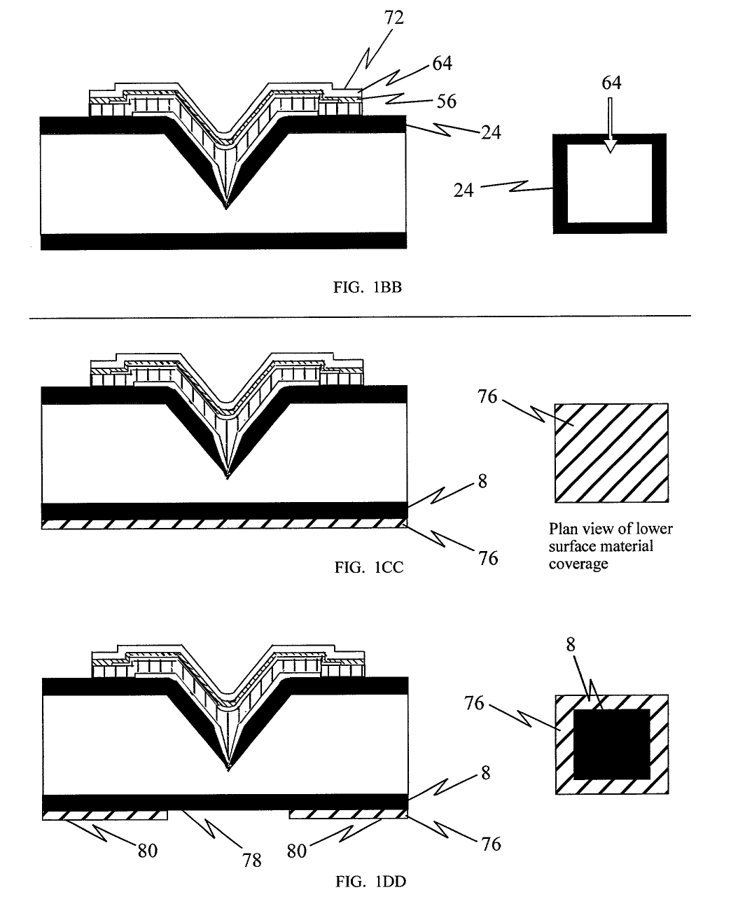

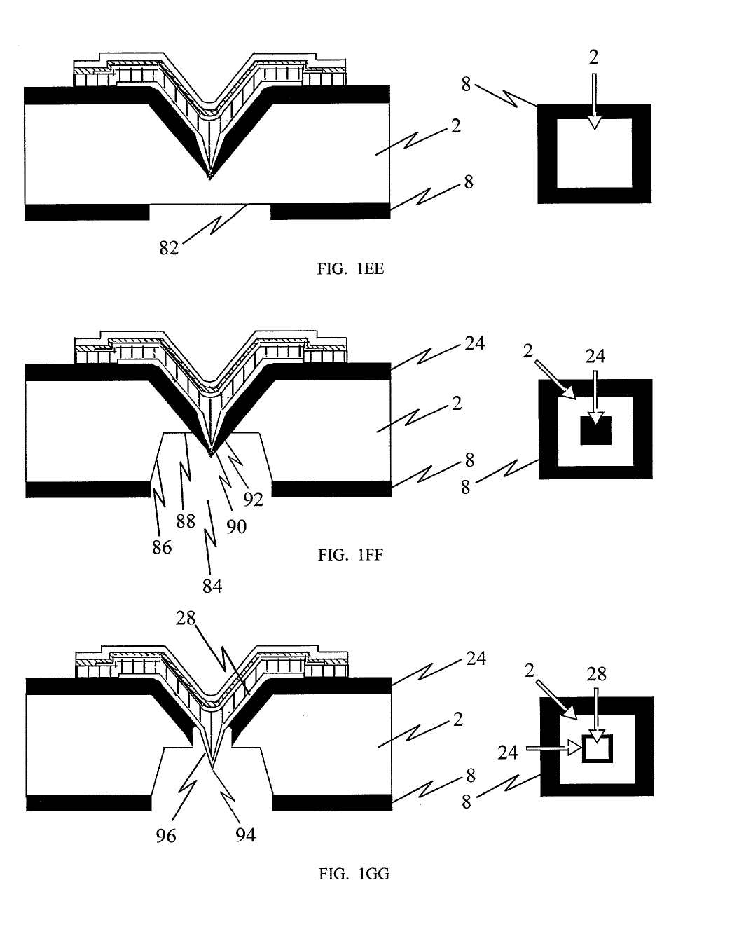

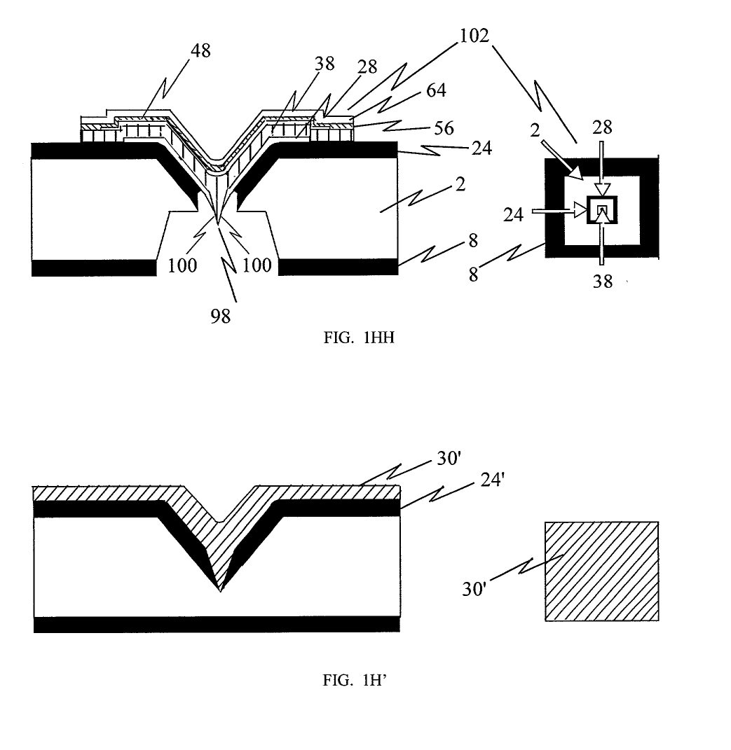

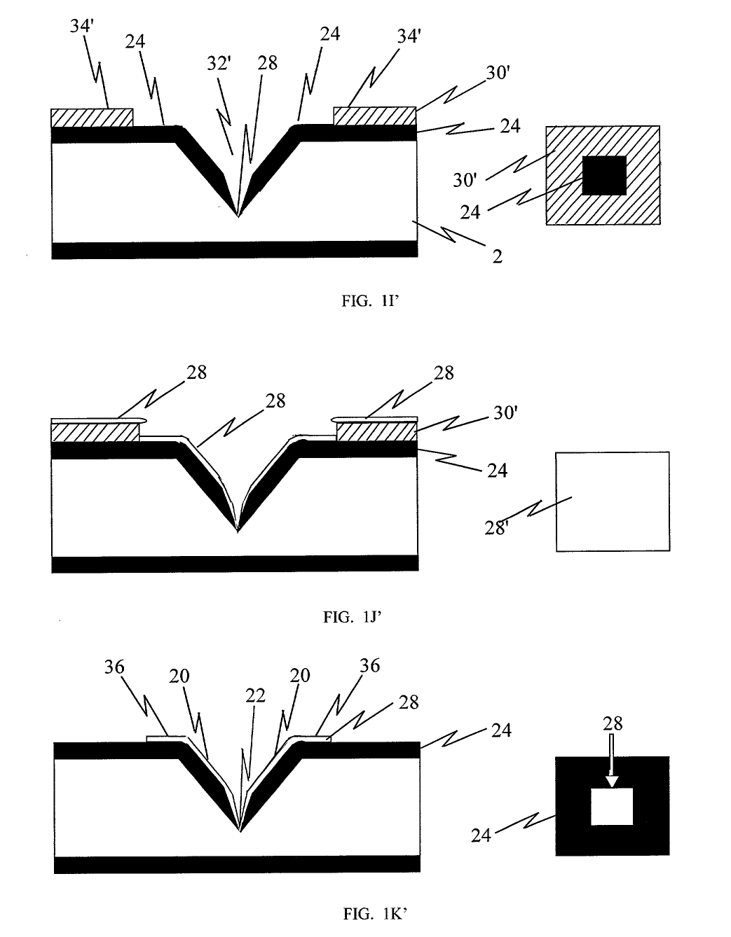

FIGS. 1A to 1HH illustrate a method for micromachining the near field optical detector 100 with a pyramidal detecting layer of FIG. 1HH. These series of figures show cross-sectional views of a substrate wafer at various stages during the fabrication of the near-field optical detector with a pyramidal detecting layer. The process first begins by providing a substrate wafer 2 as shown in FIG. 1A. The substrate material is preferably single crystal <100> oriented silicon. Substrate wafer 2 has a first face 4 and a second face 6 and a thickness T. The substrate wafer may have any convenient diameter and thickness.

Next, as shown in FIG. 1B, a first passivation step provides a first passivation layer 8 on each of both the first face 4 and the second face 6 of substrate wafer 2.

Next, a first photoresist layer 10 is formed on the first face 4 by a spin-on procedure leaving the structure as shown in FIG. 1C.

Next, a first masking layer masking pattern is formed in the first photoresist layer 10 by a masking procedure and, as shown in FIG. 1D, a first unmasked area 12 on the first face 4 of substrate wafer 2 with a square area is exposed at the completion of this first masking step. This first unmasked area 12 can be between about 1, 3, 5, 7, 9, 10, 30, 50, 70, 90, 100, 300 or 500 μm and about 2, 4, 6, 8, 20, 40, 60, 80, 200 or 400 μm on each side and in fact does not have to be exactly square in area. The remaining first masking layer 14 is resistant to etching solutions, and protects the underlying first passivation layer 8.

Next, the first unmasked area 12 is subjected to a suitable etching process and the first masking layer 14 removed. As shown in FIG. 1E there is created at this stage a first area of exposed substrate 16.

After the above masking, etching and photoresist removal procedures are complete, the first area of exposed substrate 16 is next subjected to an anisotropic etching process which etching process continues until the <111> crystal planes of the substrate meet at the bottom of the first void 18 created in the substrate 2 as shown in FIG. 1F. This first void has the shape of an inverted pyramidal first void which is defined by sides 20 which intersect at a sharp point 22.

Next, the is subjected to a first cleaning process, preferably by the RCA or Piranha methods.

Next, the wafer is subjected to a second passivation procedure using a low temperature thermal oxidation of the wafer. This procedure is preferentially carried out at a temperature of between 800° to 950° C. to introduce a curved surface in the newly formed passivation layers which now form the sides 20 of the first void 18 as shown in FIG. 1G. The thickness of the second passivation layer 24 formed on the first 4 and second faces 6 of the wafer 2 upon completion of this step can taper between about 1, 3, 5, 7, 9, 10, 30, 50, 70, 90, 100, 300, 500, 700 or 900 Å and about 2, 4, 6, 8, 20, 40, 60, 80, 200, 400, 600, 800 or 1000 Å at the narrowest point and between about 1, 3, 5, 7, 9, 10, 30, 50, 70, 90, 100, 300, 500, 700 or 900 Å and about 2, 4, 6, 8, 20, 40, 60, 80, 200, 400, 600, 800 or 1000 Å at the thickest point. Upon completion of this second passivation process the sides 20 of the first void 18 define a cusp-shaped tapered void 26.

Next, a thin layer of light confining material 28 is deposited onto the first face 4 of the wafer 2 as shown in FIG. 1H. This light confining material layer 28 can be between about 1, 3, 5, 7, 9, 10, 30, 50, 70, 90, 100, 300 or 500 Å and about 2, 4, 6, 8, 20, 40, 60, 80, 200 or 400 Å.

Next, a second photoresist layer 30 is formed thereupon the layer of light confining material 28 by a spin-on procedure resulting in the structure shown in FIG. 1I.

Next, a second masking layer masking pattern is formed in the second photoresist layer 30 by a masking procedure and, as shown in FIG. 1J, a second unmasked area 32 on the first face 4 of substrate wafer 2 starting between about 0.1, 0.3, 0.5, 0.7, 0.9, 1, 3, 5, 7, 9 or 10 μm and about 0.2, 0.4, 0.6, 0.8, 2, 4, 6 or 8 μm beyond the first void 18 is exposed at the completion of this second masking step. The remaining second photoresist layer 34 is resistant to etching solutions, and protects the underlying light confining layer 28.

After the second masking procedure is complete, the exposed light confining layer 28 is next subjected to a second suitable etching process which etching process continues until the exposed light confining layer 28 is removed leaving the structure as shown in FIG. 1K.

Next, the wafer is subjected to a second cleaning process to remove the remaining second masking layer 34. This process leaves an area of light confining material 28 on the first void sides 20 and extending between about 0.1, 0.3, 0.5, 0.7, 0.9, 1, 3, 5, 7, 9 or 10 μm and about 0.2, 0.4, 0.6, 0.8, 2, 4, 6 or 8 μm beyond the first void 18 to form a lip 36 of light confining material as shown in FIG. 1L.

Next, a thin layer 38 of light guiding material is deposited on the first face 4 of the substrate wafer 2 by an appropriate light guiding material deposition method leaving the structure as shown in FIG. 1M. An important quality for the light guiding material is the ability to guide light within the resultant near field optical detector with minimum optical losses or attenuation. The thickness of this light guiding material layer 38 can be between about 1, 3, 5, 7, 9, 10, 30, 50, 70, 90, 100, 300, 500, 700 or 900 Å and about 2, 4, 6, 8, 20, 40, 60, 80, 200, 400, 600, 800 or 1000 Å.

Next, a third photoresist layer 40 is formed thereupon the first face 4 of the substrate wafer 2 by a spin-on procedure leaving the structure shown in FIG. 1N.

Next, a third masking layer masking pattern is formed in the third photoresist layer 40 by a masking procedure and, as shown in FIG. 1O, a third unmasked area 42 on the first face 4 of substrate wafer 2 starting between about 0.1, 0.3, 0.5, 0.7, 0.9, 1, 3, 5, 7, 9 or 10 μm and about 0.2, 0.4, 0.6, 0.8, 2, 4, 6 or 8 μm beyond the lip of the light confining material 36 is exposed at the completion of this third masking step. The remaining third masking layer 44 is resistant to etching solutions, and protects the underlying light guiding layer 38.

After the third masking procedure is complete, the third unmasked area 42 is next subjected to a plasma etching process which etching process continues until the exposed light guiding layer 38 is removed.

Next, the wafer is subjected to a third cleaning process to remove the remaining third masking layer 44 leaving an area of light guiding material 38 on the first void sides 20 and extending between about 0.1, 0.3, 0.5, 0.7, 0.9, 1, 3, 5, 7, 9 or 10 μm and about 0.2, 0.4, 0.6, 0.8, 2, 4, 6 or 8 μm beyond the lip 36 of the light confining material to form a lip 46 of light guiding material as shown in FIG. 1P.

Next, a thin layer 48 of heat absorbent material is deposited on the first face 4 by an appropriate heat absorbent material deposition method leaving the structure as shown in FIG. 1Q. This heat absorbent material layer 48 can be between about 0.001, 0.003, 0.005, 0.007, 0.009, 0.01, 0.03, 0.05, 0.07, 0.09 or 0.1 μm and about 0.002, 0.004, 0.006 0.008, 0.02, 0.04, 0.06 or 0.08,μm.

Next, a fourth photoresist layer 50 is formed thereupon the first face 4 of the substrate wafer 2 by a spin-on procedure leaving the structure shown in FIG. 1R.

Next, a fourth masking layer masking pattern is formed in the fourth photoresist layer 50 by a masking procedure, as shown in FIG. 1S, in a fourth unmasked area 52 on the first face 4 of substrate wafer 2 which exposes an area of the heat absorbent layer 48 at the completion of this fourth masking step. This step also leaves behind a fourth masking layer 54 which extends to within between about 1, 3, 5, 7, 9 or 10 μm and about 2, 4, 6 or 8 μm from the edge of the underlying lip 46 of the light guiding layer. The remaining fourth masking layer 54 is resistant to etching solutions, and protects the underlying heat absorbent layer 48.

After the fourth masking procedure is complete, the fourth unmasked area 52 is next subjected to a acid etching process which etching process continues until the exposed heat absorbent layer 48 is removed.

Next, the wafer is subjected to a fourth cleaning process to remove the remaining fourth masking layer 54 leaving an area of heat absorbing material 48 on the first void sides 20 and extending outward between about 1, 3, 5, 7, 9 or 10 μm and about 2, 4, 6 or 8 μm on the first face 4 until just before reaching the lip 46 of the light guiding material 38 to form the structure as shown in FIG. 1T.

Next, a thin layer 56 of IR sensitive material is deposited on the first face 4 by sputtering an appropriate IR sensitive material deposition method leaving the structure as shown in FIG. 1U. This IR sensitive material layer 46 can be between about 1, 3, 5, 7, 9, 10 or 30 μm and about 2, 4, 6, 8 or 20 μm thick.

Next, a fifth photoresist layer 58 is formed thereupon the first face 4 of the substrate wafer 2 by a spin-on procedure leaving the structure shown in FIG. 1V.

Next, a fifth masking layer masking pattern is formed in the fifth photoresist layer 58 by a masking procedure leaving, as shown in FIG. 1W, a fifth unmasked area 60 on the first face 4 which exposes an area of the IR sensitive layer 56 at the completion of this fifth masking step. This step also leaves behind a fifth masking layer 62 which extends to the edge of the underlying lip 46 of the light guiding layer. The remaining fifth masking layer 62 is resistant to etching solutions, and protects the underlying IR sensitive layer 56.

After the fifth masking procedure is complete, the fifth unmasked area 60 is next subjected to an appropriate IR sensitive material etching process which etching process continues until the exposed IR sensitive layer 56 is removed.

Next, the wafer is subjected to a fifth cleaning process to remove the remaining fifth masking layer 62 leaving an area of IR sensitive material 56 on the first void sides 20 and extending between about 1, 3, 5, 7, 9, 10 or 30 μm and about 2, 4, 6, 8 or 20 μm on the first face 4 until stopping just above the lip 46 of the light guiding material 38 to form the structure as shown in FIG. 1X.

Next, a thin layer 64 of electrically conductive material is deposited on the first face 4 by an appropriate electrically conductive material deposition method leaving the structure as shown in FIG. 1Y. This electrically conductive material layer can be between about 1, 3, 5, 7, 9, 10, 30, 50, 70, 90, 100, 300 or 500 Å and about 2, 4, 6, 8, 20, 40, 60, 80, 200 or 400 Å.

Next, a sixth photoresist layer 66 is formed thereupon the first face 4 of the substrate wafer 2 by a spin-on procedure leaving the structure shown in FIG. 1Z.

Next, a sixth masking layer masking pattern is formed in the sixth photoresist layer 66 by a masking procedure leaving, as shown in FIG. 1AA, a sixth unmasked area 68 on the first face 4 which exposes an area of the electrically conductive material 64 at the completion of this sixth masking step. This step also leaves behind a sixth masking layer 70 which covers an area of the electrically conductive layer 64 which lies directly above the IR sensitive material layer 56. The remaining sixth masking layer 70 is resistant to etching solutions, and protects the underlying electrically conductive layer 64.

After the sixth masking procedure is complete, the sixth unmasked area 68 is next subjected to an acid etching process which etching process continues until the exposed electrically conductive layer 64 is removed.

Next, the wafer is subjected to a sixth cleaning process to remove the remaining sixth masking layer 70 leaving an area of electrically conductive material on the first face 4 above the IR sensitive material layer 56 to form an electrode 72 as shown in FIG. 1BB.

Next, a seventh photoresist layer 76 is formed on the second face 6 by a spin-on procedure leaving the structure as shown in FIG. 1CC.

Next, a seventh masking layer masking pattern is formed in the seventh photoresist layer 76 by a masking procedure and, as shown in FIG. 1DD, a seventh unmasked area 78 on the second face of substrate wafer 2 with about a 3 micron by 3 micron square area centered directly below the first void 18 is exposed at the completion of this seventh masking step. The remaining seventh masking layer 80 is resistant to etching solutions, and protects the underlying first passivation layer 8 found on the second face 6.

Next, the seventh unmasked area 78 is subjected to an etching process and the seventh masking layer 80 removed. As shown in FIG. 1EE there is created at this stage a second area of exposed substrate 82.

After the above masking, etching and photoresist removal procedures are complete, the second area of exposed substrate 82 is next subjected to a silicon anisotropic etching process which etching process continues until the <111> crystal planes of the substrate expose the pyramidally shaped first passivation layer 8 formed on the first face 4 to a height of between about 500, 600, 700, 800, 900 or 1000 Å and about 550, 650, 750, 850 or 950 Å. The structure of the second void 84 created in the substrate 2 by this anisotropic etching process is shown in FIG. 1FF. This second void 84 has the shape of a truncated pyramidal void which is defined by sloping sides 86 which intersect with a flat roof plane 88 through which an inverted pyramidally shaped point 90 centrally projects.

Next, the exposed passivation layer 92 on the centrally projecting inverted pyramidally shaped point 90 is subjected to an eighth etching process and the exposed first passivation layer removed. At this stage there is exposed a thin tapered point 94 clad with a light confining layer 96 as shown in FIG. 1GG.

Lastly, the light confining layer 96 on the thin tapered point 94 is subjected to a ninth etching process and the exposed light confining layer removed. This series of micromachining steps creates a near field optical detector with a pyramidal detecting layer 102 shown in FIG. 1HH wherein there is exposed an exceedingly slender detector tip 98 comprising in part an area of exposed light guiding material 100. The detector tip 98 has a diameter of approximately 10 to 20 nm at its apex.

It must be noted that the processing steps shown in FIGS. 1H through 1L can alternatively be replaced by the lift-off process shown in FIGS. 1H′ through 1K′ as described in the following steps.

First, for this alternative series of lift-off process steps a second photoresist layer 30′ is formed thereupon the first face 4 of the substrate wafer by a spin-on procedure resulting in the structure shown in FIG. 1H′.

Next, a second masking layer masking pattern is formed in the second photoresist layer 30′ by a masking procedure and, as shown in FIG. 1I′, a second unmasked area 32′ on the first face 4 of substrate wafer 2 exposes the cusp-shaped void 28′ and a surrounding lip of second passivation layer 24 between about 0.1, 0.3, 0.5, 0.7, 0.9, 1, 3, 5, 7, 9 or 10 μm and about 0.2, 0.4, 0.6, 0.8, 2, 4, 6 or 8 μm wide. The remaining second photoresist layer 34′ protects the underlying second passivation layer 24.

Next, a thin layer of light confining material 28′ is deposited onto the first face 4′ of the wafer 2′ as shown in FIG. 1J′. This light confining material layer 28′ can be between about 1, 3, 5, 7, 9, 10, 30, 50, 70, 90, 100, 300 or 500 Å and about 2, 4, 6, 8, 20, 40, 60, 80, 200 or 400 Å.

Next, the wafer is subjected to a second cleaning process to lift-off and remove the light confining layer seated on top of the second masking layer 34′. This process leaves an area of light confining material 28 on the first void sides 20 and extending between about 0.1, 0.3, 0.5, 0.7, 0.9, 1, 3, 5, 7, 9 or 10 μm and about 0.2, 0.4, 0.6, 0.8, 2, 4, 6 or 8 μm beyond the first void 18 to form a lip 36 of light confining material as shown in FIG. 1K′. This completes the description of the alternative lift-off process steps which can replace the steps shown in FIGS. 1H through 1K.

### II THE SECOND STRUCTURE—A NEAR FIELD OPTICAL DETECTOR WITH DETECTING LAYER ARRAYED ON A CONVEX LENS

The present invention also includes an alternative embodiment of the NFOD in which the detecting layer lies on top of a convex lens.

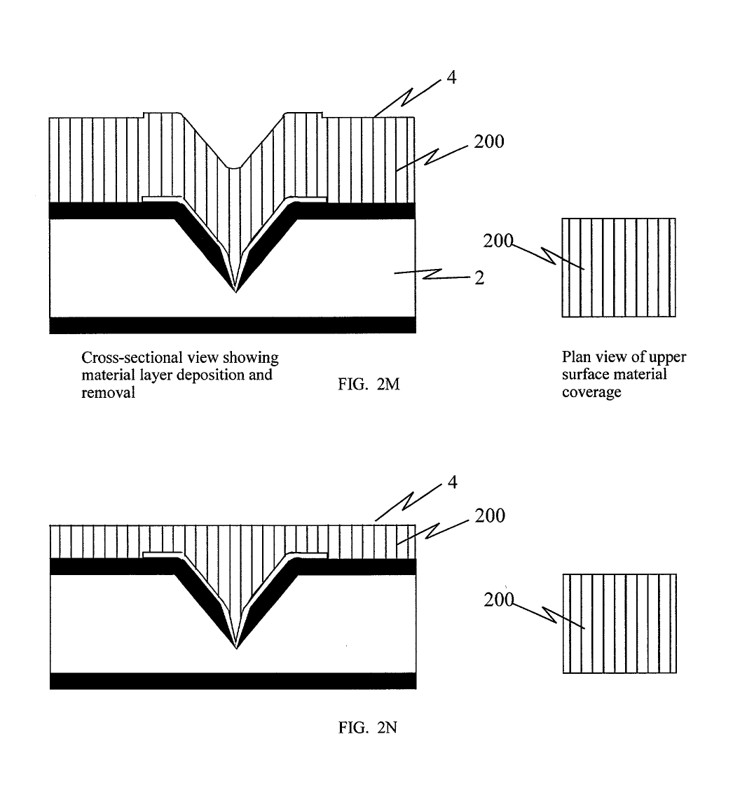

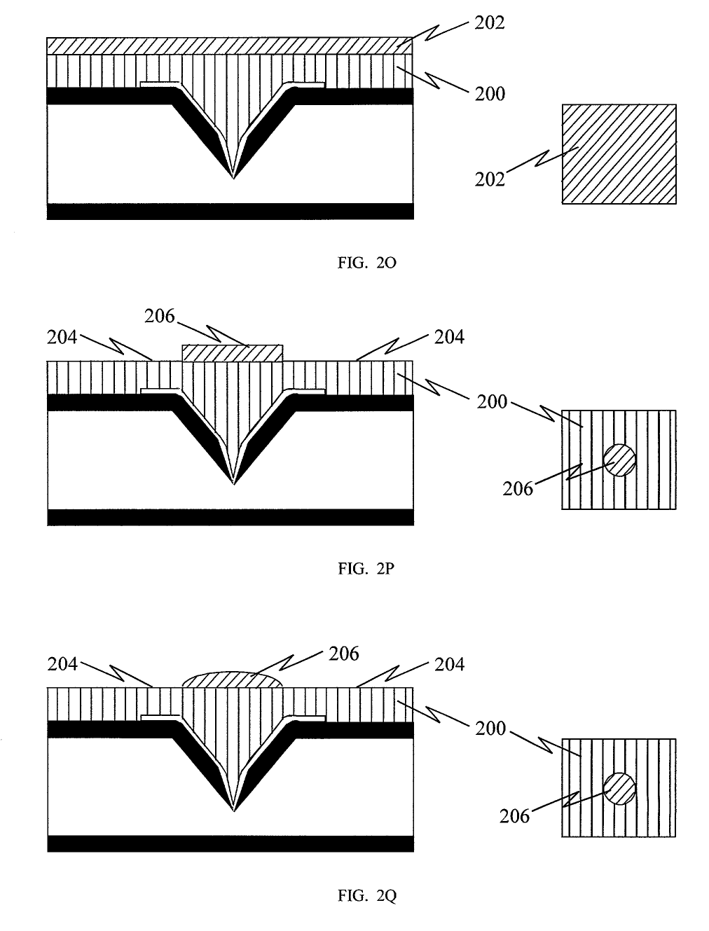

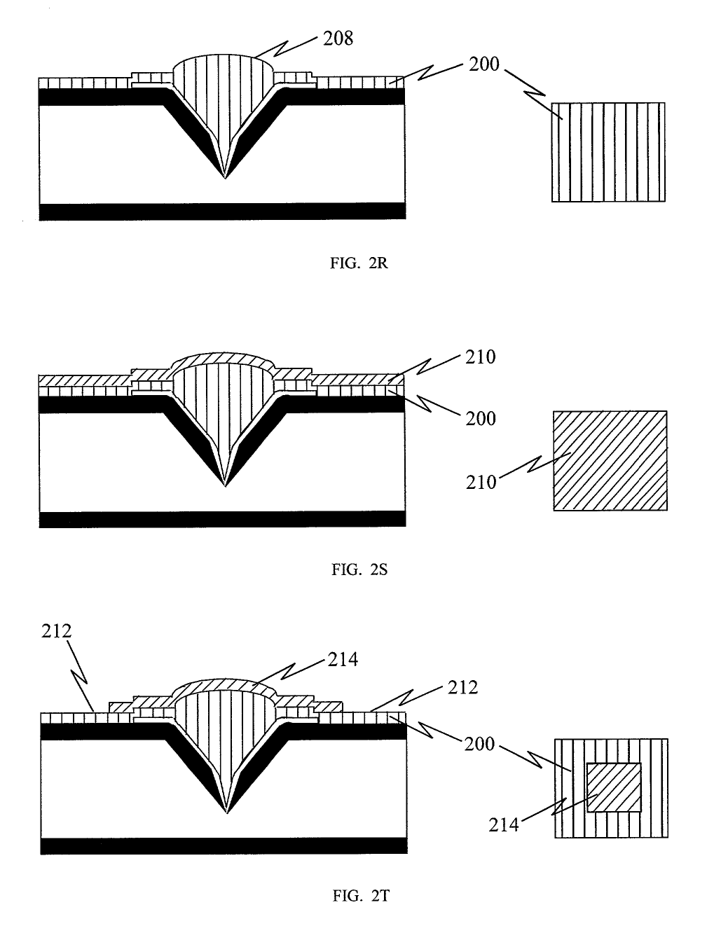

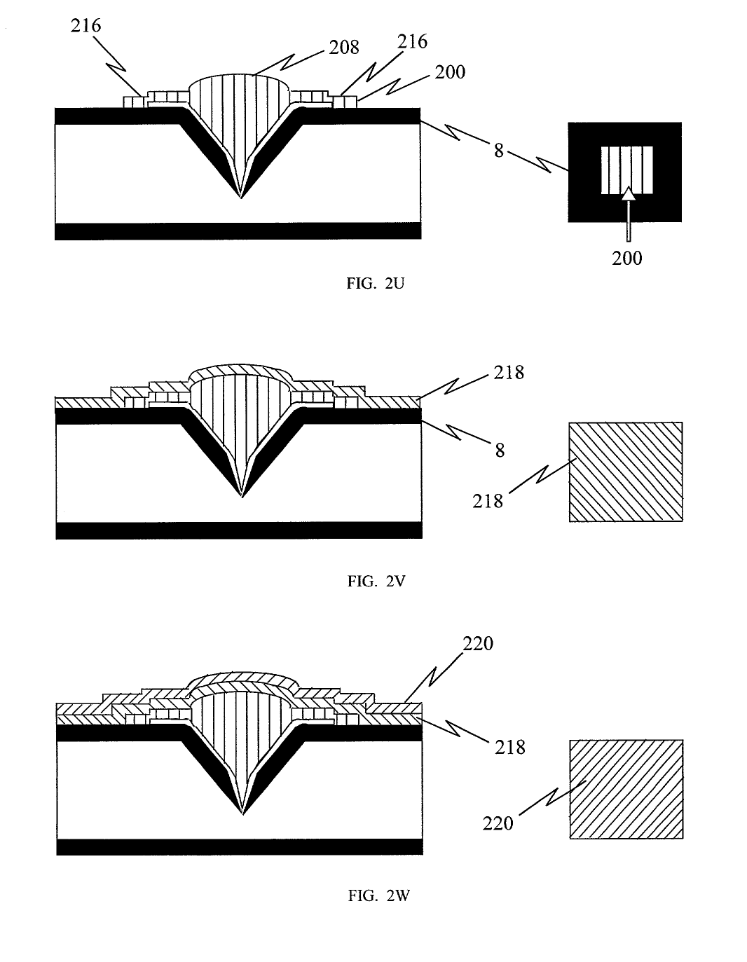

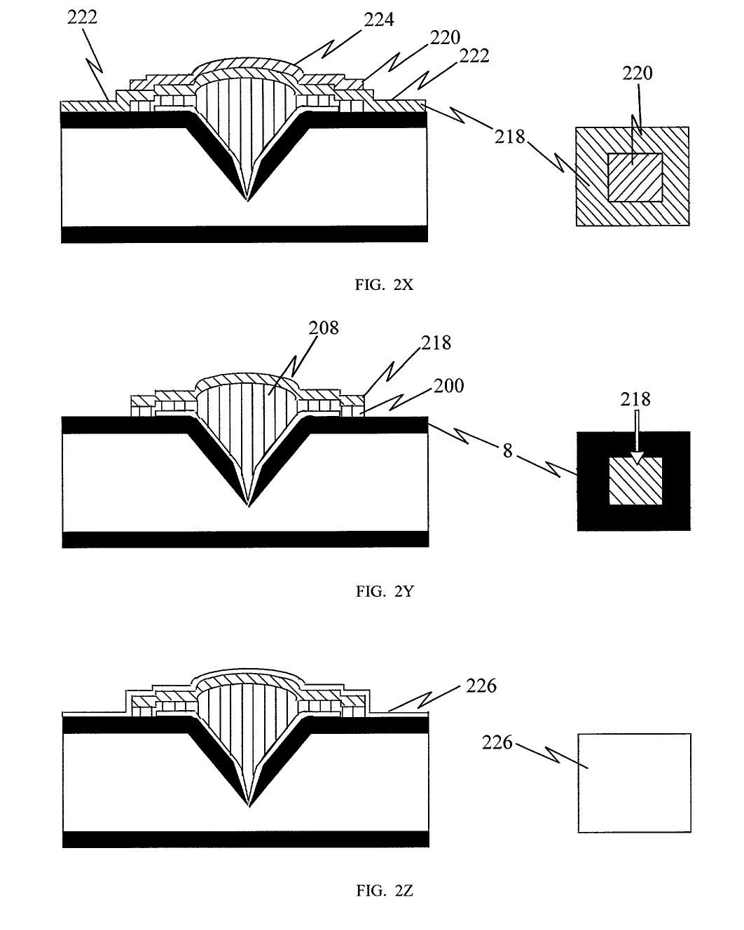

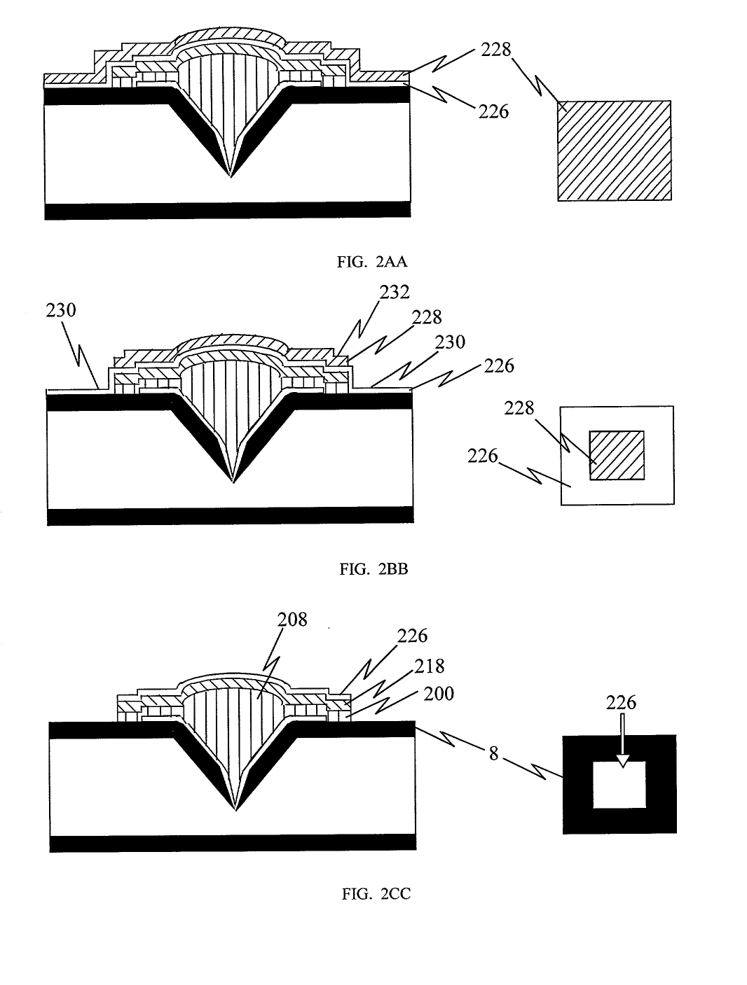

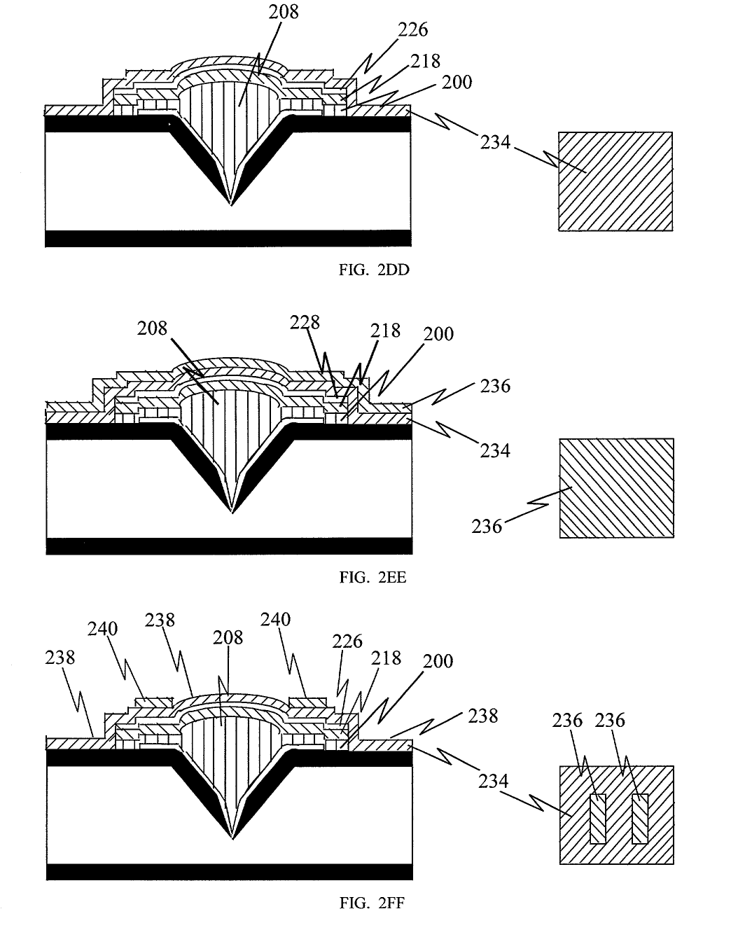

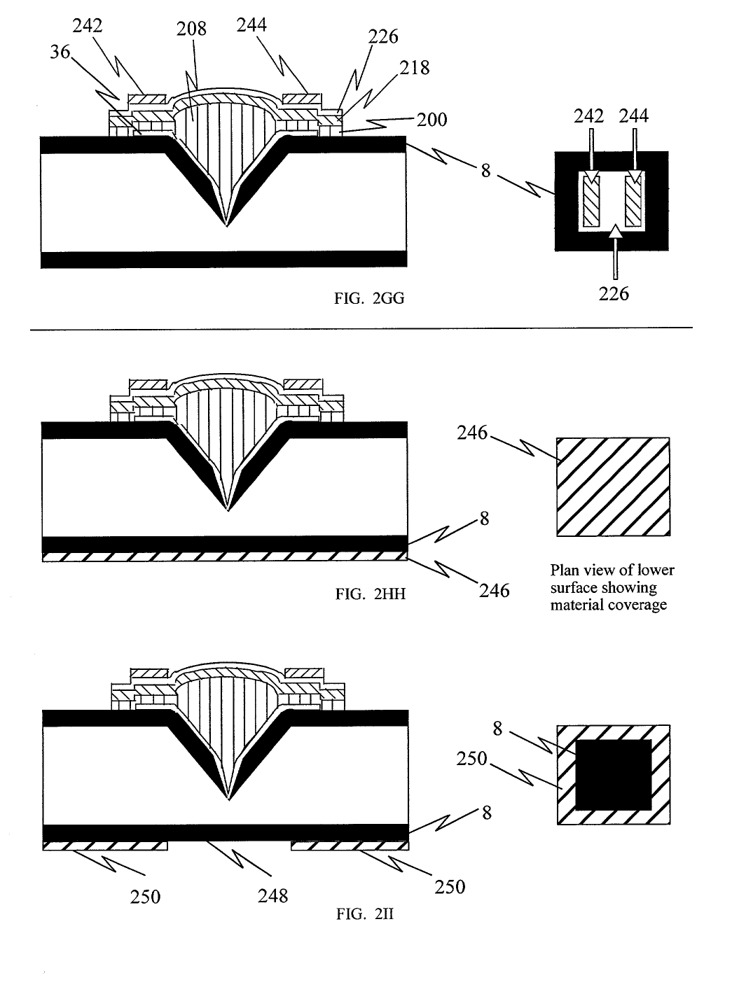

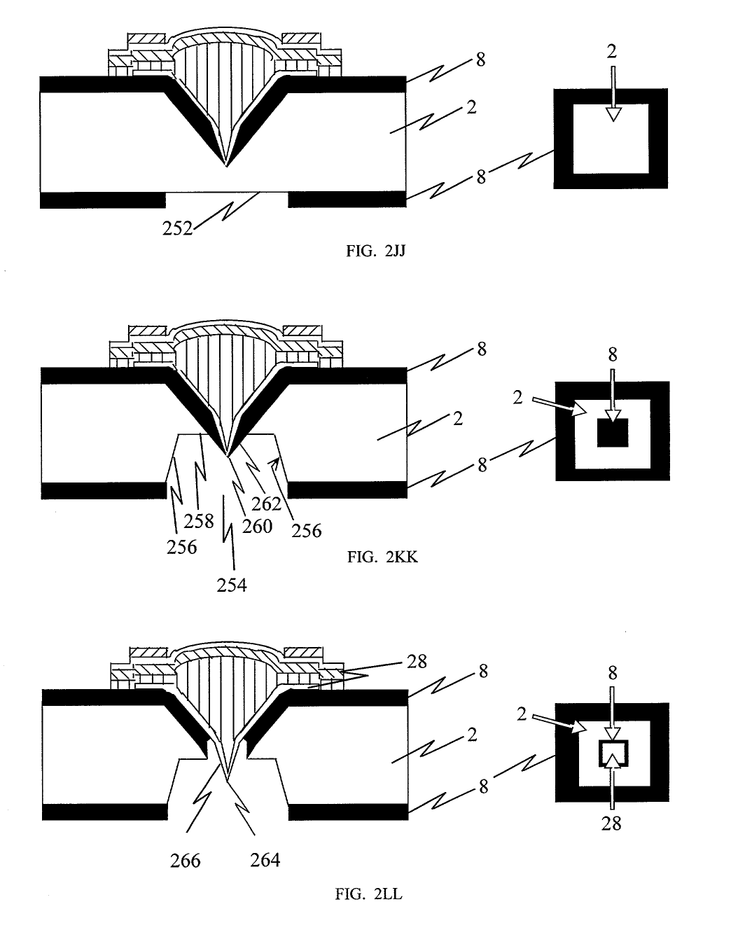

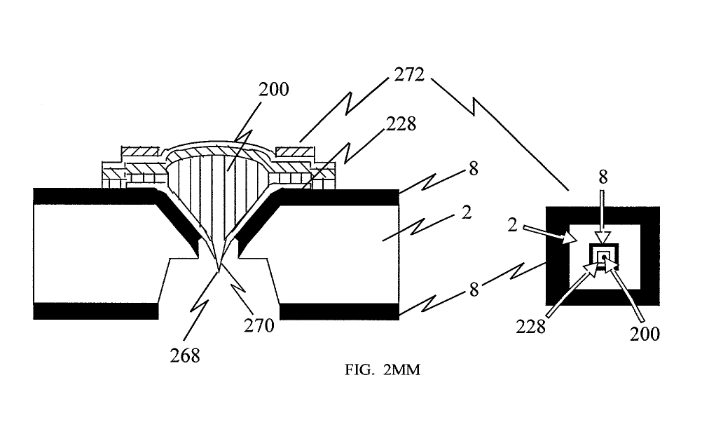

First, all of the steps described in the previous paragraphs regarding the Near Field Optical Detector with a Pyramidal Detecting Layer up to and through the second etching, photoresist removal and wafer cleaning step are incorporated herein and should first be followed. These steps result in the same structures which are shown in FIGS. 1A through 1L. (With the adoption of these steps, references to FIG. 1A will now, for the purposes of describing this second embodiment, be referred to as FIG. 2A instead. Similarly FIG. 1B will be referred to now as FIG. 2B on up through and including FIG. 1L which will now be referred to as FIG. 2L.)

Now to continue. Next, a thick layer 200 of light guiding material is deposited on the first face 4 of the substrate wafer 2 by a suitable light guiding material deposition method leaving the structure as shown in FIG. 2M. An important quality for the light guiding material is the ability to guide light within the resultant near field optical detector with minimum optical losses or attenuation. This light guiding material layer can be between about 1, 3 or 5 μm and about 2 or 4 μm thick.

Next, the first face 4 of the substrate wafer is subjected to a mechanical polishing process which results in the structure as shown in FIG. 2N. Note that the polishing continues until the light guiding material layer is flat and parallel to the original first face 2 of the substrate wafer 2 and the polishing stops when the layer of light guiding material 200 is between about 0.5, 0.7, 0.9, 1, 3, 5, 7, 9 or 10 μm and about 0.6, 0.8, 2, 4, 6, 8 or 20 μm thick or possibly even thicker.

Next, a third photoresist layer 202 is formed thereupon the first face 4 of the substrate wafer 2 by a spin-on procedure leaving the structure shown in FIG. 2O.

Next, a third masking layer masking pattern is formed in the third photoresist layer 202 by a masking procedure and, as shown in FIG. 2P, a third unmasked area 204 on the first face 4 of substrate wafer 2 immediately above the edges of the first void 18 is exposed at the completion of this third masking step. The remaining third masking layer 206 is resistant to etching solutions, and protects the underlying light guiding layer 200.

After the third masking procedure is complete, the wafer is subjected to high temperatures in the range between about 150, 200, 250 or 300° and about 175, 225 or 275° to heat and reflow the third masking layer 206 to create the convex shaped third masking layer 206 shown in FIG. 2Q.

Next, the third unmasked area 206 is next subjected to a plasma etching process which etching process continues until the third masking layer 206 and part of the light guiding layer 200 is removed leaving the convex shaped structure 208 shown in FIG. 2R.

Next, a fourth photoresist layer 210 is formed thereupon the layer of light guiding material 200 by a spin-on procedure resulting in the structure shown in FIG. 2S.

Next, a fourth masking layer masking pattern is formed in the fourth photoresist layer 210 by a masking procedure and, as shown in FIG. 2T, a fourth unmasked area 212 on the first face 4 of substrate wafer 2 starting between about 0.1, 0.3, 0.5, 0.7, 0.9, 1, 3, 5, 7, 9 or 10 μm and about 0.2, 0.4, 0.6, 0.8, 2, 4, 6 or 8 μm beyond the first void 18 is exposed at the completion of this second masking step. The remaining fourth photoresist layer 214 is resistant to etching solutions, and protects the underlying light guiding layer 200.

After the fourth masking procedure is complete, the exposed light guiding layer 200 is next subjected to a plasma etching process which etching process continues until the exposed light guiding layer 38 is removed.

Next, the wafer is subjected to a third cleaning process to remove the remaining fourth masking layer 214 leaving the convex lens 208 surrounded by a lip of light guiding material 216 extending between about 0.1, 0.3, 0.5, 0.7, 0.9, 1, 3, 5, 7, 9 or 10 μm and about 0.2, 0.4, 0.6, 0.8, 2, 4, 6 or 8 μm beyond the edge of the first void 18 as shown in FIG. 2U.

Next, a thin layer 218 of heat absorbent material is deposited on the first face 4 by an appropriate heat absorbent material deposition method leaving the structure as shown in FIG. 2V.

This heat absorbent material layer can be between about 0.001, 0.003, 0.005, 0.007, 0.009, 0.01, 0.03, 0.05, 0.07, 0.09 or 0.1 μm and about 0.002, 0.004, 0.006 0.008, 0.02, 0.04, 0.06 or 0.08 μm.

Next, a fifth photoresist layer 220 is formed thereupon the first face 4 of the substrate wafer 2 by a spin-on procedure leaving the structure shown in FIG. 2W.

Next, a fifth masking layer masking pattern is formed in the fifth photoresist layer 220 by a masking procedure, as shown in FIG. 2X, leaving a fifth unmasked area 222 on the first face 4 of substrate wafer 2 which exposes an area of the heat absorbent layer 218 at the completion of this fifth masking step. This step also leaves behind a fifth masking layer 224 which extends outward between about 1, 3, 5, 7, 9 or 10 μm and about 2, 4, 6 or 8 μm from the edge of the underlying lip 216 of the light guiding layer. The remaining fifth masking layer 214 is resistant to etching solutions, and protects the underlying heat absorbent layer 218.

After the fifth masking procedure is complete, the fifth unmasked area 222 is next subjected to an etching process which etching process continues until the exposed heat absorbent layer 218 is removed.

Next, the wafer is subjected to a fifth cleaning process to remove the remaining fifth masking layer 224 leaving an area of heat absorbent material 218 on the convex lens 208 and surrounding lip of light guiding material 216 extending outward between about 0.1, 0.3, 0.5, 0.7, 0.9, 1, 3, 5, 7, 9 or 10 μm and about 0.2, 0.4, 0.6, 0.8, 2, 4, 6 or 8 μm beyond the edge of the first void 18 as shown to form the structure as shown in FIG. 2Y.

Next, a thin layer 226 of IR sensitive material is deposited on the first face 4 by an appropriate IR sensitive material deposition method leaving the structure as shown in FIG. 2Z. This IR sensitive material layer 226 can be between about 1, 3, 5, 7, 9, 10 or 30 μm and about 2, 4, 6, 8 or 20 μm thick.

Next, a fifth photoresist layer 228 is formed thereupon the first face 4 of the substrate wafer 2 by a spin-on procedure leaving the structure shown in FIG. 2AA.

Next, a fifth masking layer masking pattern is formed in the fifth photoresist layer 228 by a masking procedure leaving, as shown in FIG. 2BB, a fifth unmasked area 230 on the first face 4 which exposes an area of the IR sensitive layer 226 at the completion of this fifth masking step. This step also leaves behind a fifth masking layer 232 which extends to the edge of the underlying lip 216 of the light guiding layer. The remaining fifth masking layer 232 is resistant to etching solutions, and protects the underlying IR sensitive layer 226.

After the fifth masking procedure is complete, the fifth unmasked area 230 is next subjected to an IR sensitive material etching process which etching process continues until the exposed IR sensitive layer 226 is removed.

Next, the wafer is subjected to a fifth cleaning process to remove the remaining fifth masking layer 232 leaving an area of IR sensitive material 226 completely covering the underlying heat absorbent layer 218 to form the structure as shown in FIG. 2CC.

Next, a thin layer of electrically conductive material 234 is deposited on the first face 4 by an appropriate electrically conductive material deposition method leaving the structure as shown in FIG. 2DD. This electrically conductive material layer 234 can be between about 1, 3, 5, 7, 9, 10, 30, 50, 70, 90, 100, 300, or 500 Å and about 2, 4, 6, 8, 20, 40, 60, 80, 200 or 400 Å.

Next, a sixth photoresist layer 236 is formed thereupon the first face 4 of the substrate wafer 2 by a spin-on procedure leaving the structure shown in FIG. 2EE.

Next, a sixth masking layer masking pattern is formed in the sixth photoresist layer 236 by a masking procedure leaving, as shown in FIG. 2FF, a sixth unmasked area 238 on the first face 4 which exposes an area of the electrically conductive material 234 at the completion of this sixth masking step. This step also leaves behind a sixth masking layer 240 which covers two areas of the electrically conductive layer 234 which lie on opposite sides of the first void sides and extend outwards between about 1, 3, 5, 7, 9 or 10 μm and about 2, 4, 6 or 8 μm. The remaining sixth masking layers 240 are resistant to etching solutions, and protect the underlying electrically conductive layer 234.

After the sixth masking procedure is complete, the sixth unmasked area 238 is next subjected to an acid etching process which etching process continues until the exposed electrically conductive layer 234 is removed.

Next, the wafer is subjected to a sixth cleaning process to remove the remaining sixth masking layers 240 leaving two areas of electrically conductive material on the first face 4 above the lip of the light guiding material 36 to form a first electrode 242 and second electrode 244 as shown in FIG. 2GG.

Next, a seventh photoresist layer 246 is formed on the second face 6 by a spin-on procedure leaving the structure as shown in FIG. 2HH.

Next, a seventh masking layer masking pattern is formed in the seventh photoresist layer 246 by a masking procedure and, as shown in FIG. 2II, a seventh unmasked area 248 on the second face 6 of substrate wafer 2 forming a 3 micron by 3 micron square area centered directly below the first void 18 is exposed at the completion of this seventh masking step. The remaining seventh masking layer 250 is resistant to etching solutions, and protects the underlying first passivation layer 8 found on the second face 6.

Next, the seventh unmasked area 248 is subjected to an etching process and the seventh masking layer 250 removed. As shown in FIG. 2JJ there is created at this stage a second area of exposed substrate 252.

After the above masking, etching and photoresist removal procedures are complete, the second area of exposed substrate 252 is next subjected to a silicon anisotropic etching process which etching process continues until the <111> crystal planes of the substrate expose the pyramidally shaped first passivation layer 8 formed on the first face 4 to a height of between about 500, 600, 700, 800, 900 or 1000 Å and about 5500, 650, 750, 850 or 950 Å. The structure of the second void 254 created in the substrate 2 by this anisotropic etching process is shown in FIG. 2KK. This second void 254 has the shape of a truncated pyramidal void which is defined by sloping sides 256 which intersect with a flat roof plane 258 through which an inverted pyramidally shaped point 260 centrally projects.

Next, the exposed passivation layer 262 on the centrally projecting inverted pyramidally shaped point 260 is subjected to an eighth etching process and the exposed first passivation layer removed. At this stage there is exposed a thin tapered point 264 clad with a light confining layer 266 as shown in FIG. 2LL.

Lastly, the exposed light confining layer 266 on the thin tapered point 264 is subjected to a ninth etching process and the light confining layer removed. This series of micromachining steps creates a near field optical detector with a detecting layer arrayed on a convex lens 272 as shown in FIG. 2MM wherein there is exposed an exceedingly slender detector tip 268 comprising in part an area of exposed light guiding material 270 coupled with a detecting layer lying on top of a convex lens. The detector tip 268 has a diameter of approximately 10 to 20 nm at its apex.

### III THE THIRD STRUCTURE—A NEAR FIELD OPTICAL DETECTOR WITH PLANAR DETECTING LAYER

The present invention includes an embodiment in which the detecting layer is planar and substantially perpendicular with the axis of the detector tip.

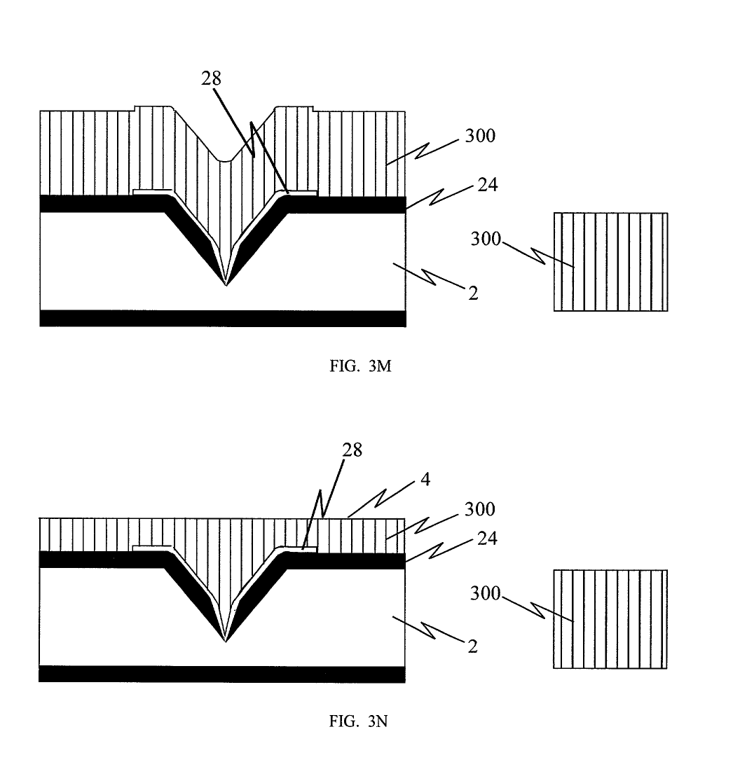

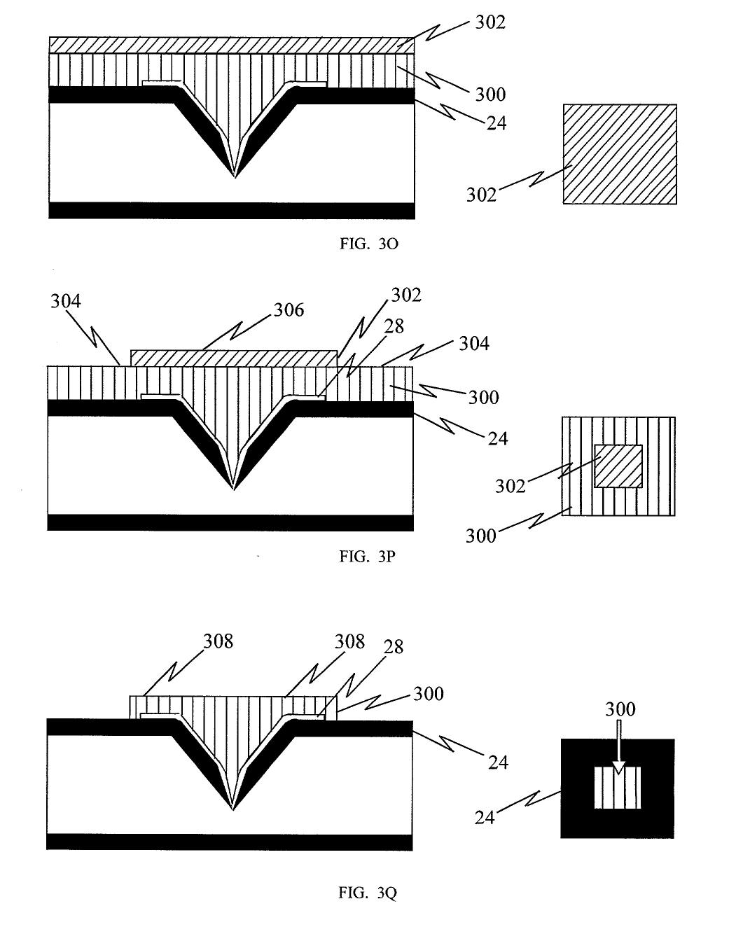

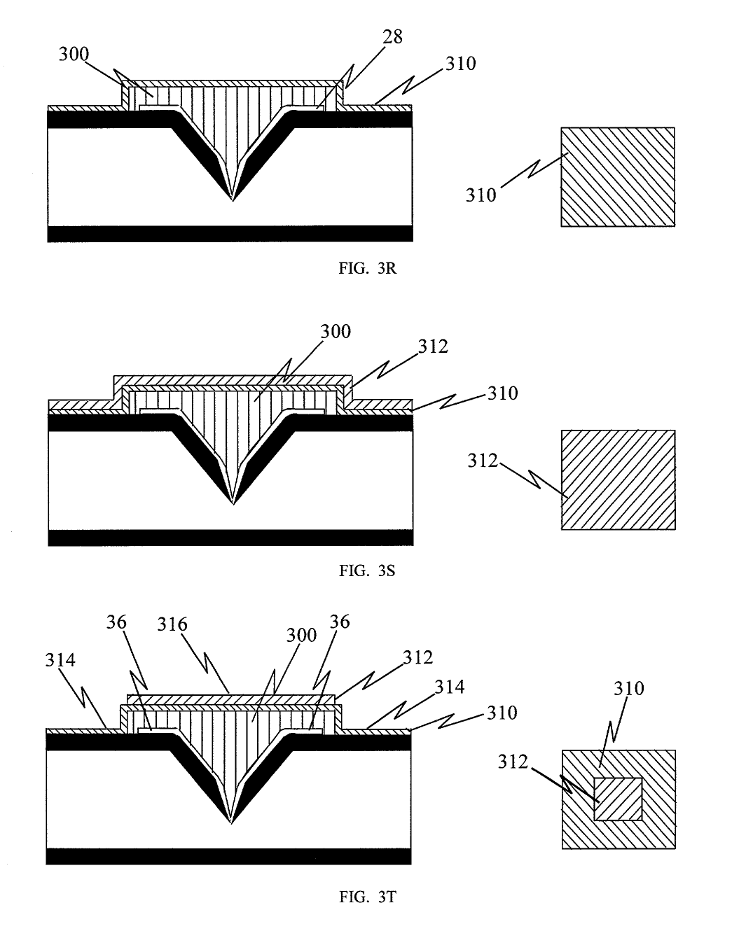

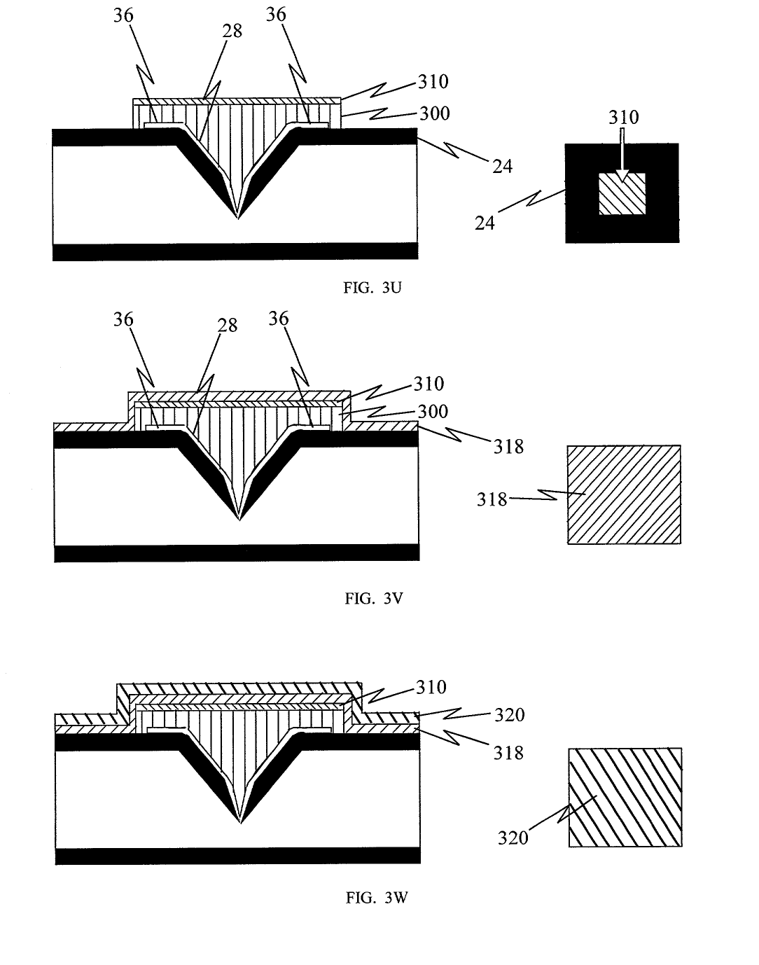

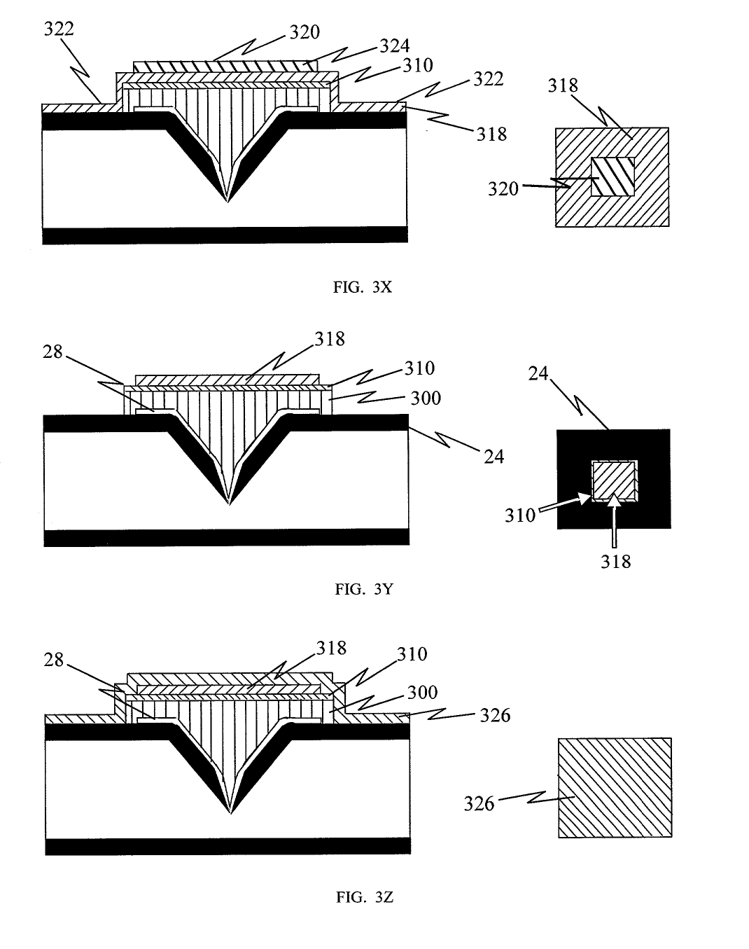

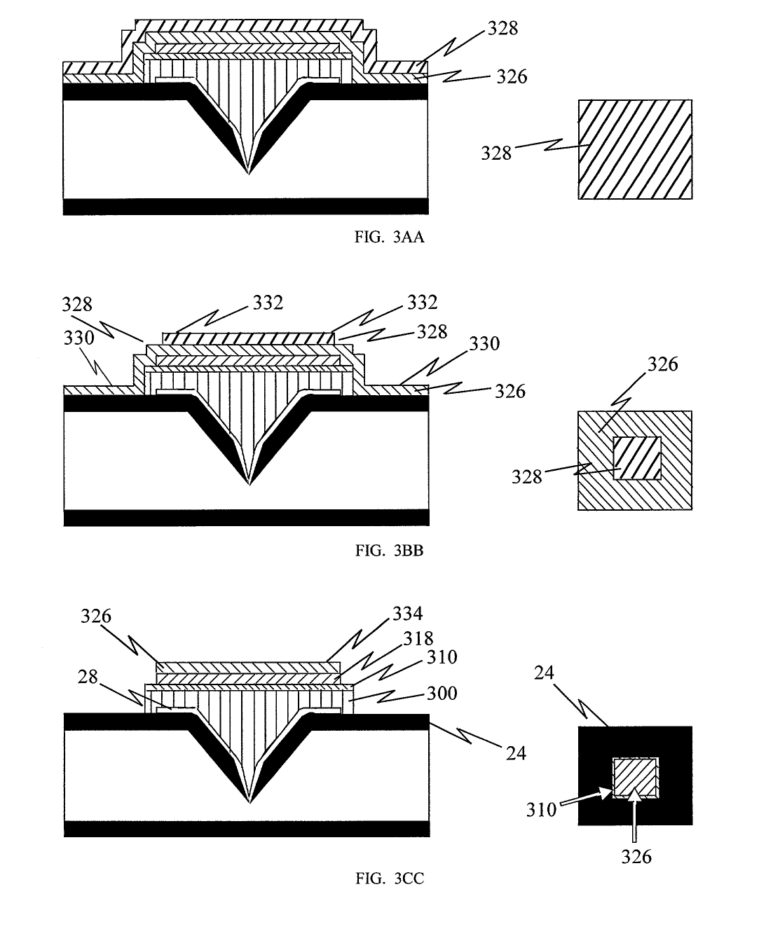

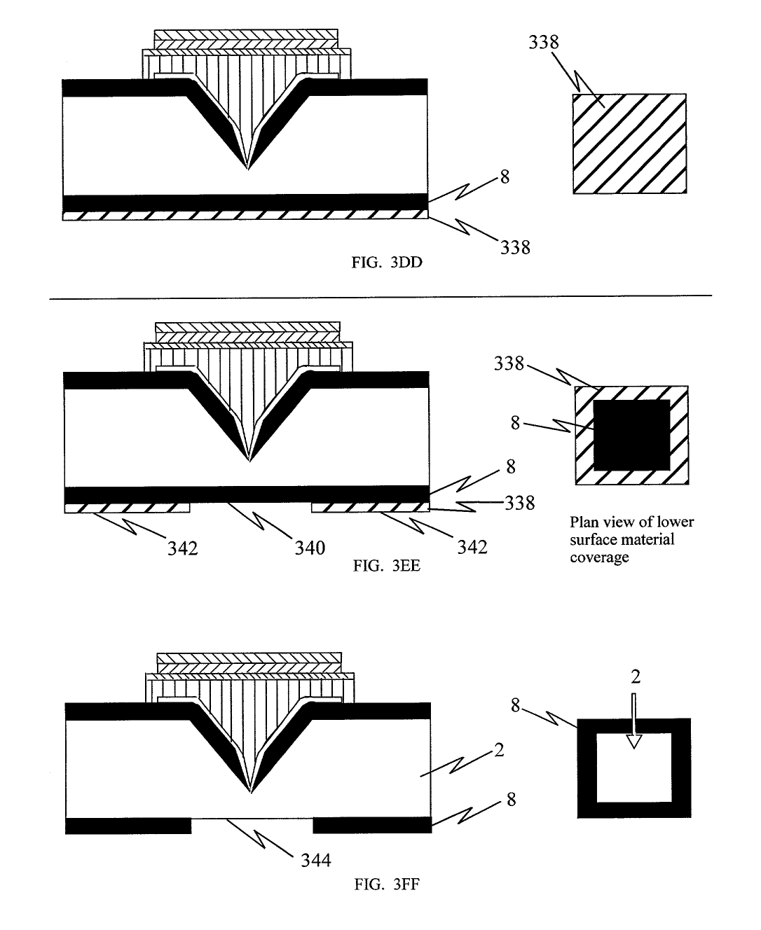

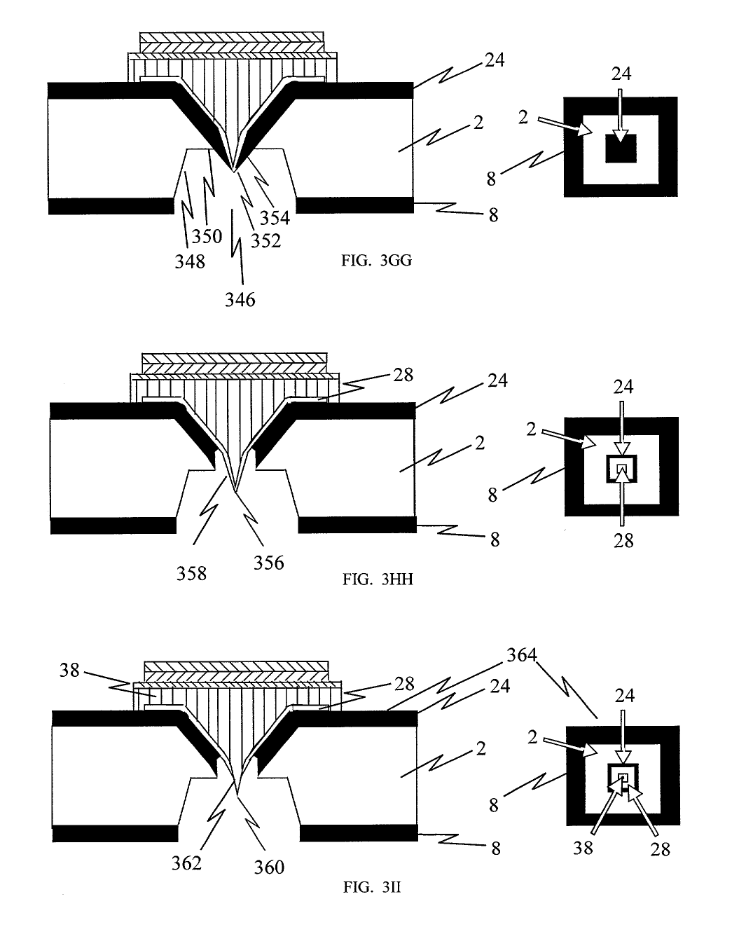

First, all of the steps described previously in the previous paragraphs regarding the Near Field Optical Detector with a Pyramidal Detecting Layer up to and through the second etching, photoresist removal and wafer cleaning step are incorporated herein and should first be followed. These steps result in the same structures which are shown in FIGS. 1A through 1L. (With the adoption of these steps, references to FIG. 1A will now, for the purposes of this second example, referred to FIG. 3A instead. Similarly FIG. 1B will be referred to now as FIG. 3B on up through and including FIG. 1L which will now be referred to as FIG. 3L.)

Now to continue. Next, a thick layer 300 of light guiding material is deposited on the first face 4 of the substrate wafer 2 by a an appropriate light guiding material deposition method leaving the structure as shown in FIG. 3M. An important quality for the light guiding material is the ability to guide light within the resultant near field optical detector with minimum optical losses or attenuation. The light guiding material layer can be between about 1, 3 or 5 μm and about 2 or 4 μm thick.

Next, the first face 4 of the substrate wafer is subjected to a mechanical polishing process which results in the structure as shown in FIG. 3N. Note that the polishing continues until the light guiding material layer is flat and parallel to the original first face 2 of the substrate wafer 2 and the polishing stops when the layer of light guiding material 300 is between about 0.5, 0.7, 0.9, 1, 3, 5, 7, 9 or 10 μm and about 0.6, 0.8, 2, 4, 6, 8 or 20 μm thick or possibly even thicker.

Next, a third photoresist layer 302 is formed thereupon the first face 4 of the substrate wafer 2 by a spin-on procedure leaving the structure shown in FIG. 30.

Next, a third masking layer masking pattern is formed in the third photoresist layer 302 by a masking procedure and, as shown in FIG. 3P, a third unmasked area 304 on the first face 4 of substrate wafer 2 starting between about 0.1, 0.3, 0.5, 0.7, 0.9, 1, 3, 5, 7, 9 or 10 μm and about 0.2, 0.4, 0.6, 0.8, 2, 4, 6 or 8 μm beyond the edge of the first void 18 is exposed at the completion of this third masking step. The remaining third masking layer 306 is resistant to etching solutions, and protects the underlying light guiding layer 300.

After the third masking procedure is complete, the third unmasked area 306 is next subjected to a third etching process which etching process continues until the exposed light guiding layer 300 is removed.

Next, the wafer is subjected to a third cleaning process to remove any remaining third masking layer 306 leaving an area of light guiding material 300 filing the first void 18 and extending between about 0.1, 0.3, 0.5, 0.7, 0.9, 1, 3, 5, 7, 9 or 10 μm and about 0.2, 0.4, 0.6, 0.8, 2, 4, 6 or 8 μm beyond the lip 36 of the light confining material to form a lip 308 of light guiding material as shown in FIG. 3Q.

Next, a thin layer 310 of heat absorbent material is deposited on the first face 4 by an appropriate heat absorbent material deposition method leaving the structure as shown in FIG. 3R. This heat absorbent material layer can be between about 0.001, 0.003, 0.005, 0.007, 0.009, 0.01, 0.03, 0.05, 0.07, 0.09 or 0.1 μm and about 0.002, 0.004, 0.006 0.008, 0.02, 0.04, 0.06 or 0.08 μm.

Next, a fourth photoresist layer 312 is formed thereupon the first face 4 of the substrate wafer 2 by a spin-on procedure leaving the structure shown in FIG. 3S.

Next, a fourth masking layer masking pattern is formed in the fourth photoresist layer 312 by a masking procedure, as shown in FIG. 3T, leaving a fourth unmasked area 314 on the first face 4 of substrate wafer 2 which exposes an area of the heat absorbent layer 310 at the completion of this fourth masking step. This step also leaves behind a fourth masking layer 316 which extends to within between about 0.1, 0.3, 0.5, 0.7, 0.9, 1, 3, 5, 7, 9 or 10 μm and about 0.2, 0.4, 0.6, 0.8, 2, 4, 6 or 8 μm from the edge of the underlying lip 36 of the light confining layer. The remaining fourth masking layer 316 is resistant to etching solutions, and protects the underlying heat absorbent layer 310.

After the fourth masking procedure is complete, the fourth unmasked area 314 is next subjected to an etching process which etching process continues until the exposed heat absorbent layer 310 is removed.

Next, the wafer is subjected to a fourth cleaning process to remove the remaining fourth masking layer 316 leaving an area of heat absorbent material 310 on the area directly above the void 18 and extending outward between about 0.1, 0.3, 0.5, 0.7, 0.9, 1, 3, 5, 7, 9 or 10 μm and about 0.2, 0.4, 0.6, 0.8, 2, 4, 6 or 8 μm beyond the edge of the first void 18 as shown to form the structure as shown in FIG. 3U.

Next, a thin layer 318 of IR sensitive material is deposited on the first face 4 by an appropriate IR sensitive material deposition method leaving the structure as shown in FIG. 3V. This IR sensitive material layer can be between about 1, 3, 5, 7, 9, 10 or 30 μm and about 2, 4, 6, 8 or 20 μm thick.

Next, a fifth photoresist layer 320 is formed thereupon the first face 4 of the substrate wafer 2 by a spin-on procedure leaving the structure shown in FIG. 3W.

Next, a fifth masking layer masking pattern is formed in the fifth photoresist layer 320 by a masking procedure leaving, as shown in FIG. 3X, a fifth unmasked area 322 on the first face 4 which exposes an area of the IR sensitive layer 318 at the completion of this fifth masking step. This step also leaves behind a fifth masking layer 324 which extends to the edge of the underlying lip 36 of the light confining layer. The remaining fifth masking layer 324 is resistant to etching solutions, and protects the underlying IR sensitive layer 318.

After the fifth masking procedure is complete, the fifth unmasked area 322 is next subjected to an IR sensitive material etching process which etching process continues until the exposed IR sensitive layer 318 is removed.

Next, the wafer is subjected to a fifth cleaning process to remove the remaining fifth masking layer 324 leaving an area of IR sensitive material 318 completely covering the underlying light confining layer 28 to form the structure as shown in FIG. 3Y.

Next, a thin layer 326 of electrically conductive material is deposited on the first face 4 by an appropriate electrically conductive material deposition method leaving the structure as shown in FIG. 3Z. This electrically conductive material layer can be between about 1, 3, 5, 7, 9, 10, 30, 50, 70, 90, 100, 300 or 500 Å and about 2, 4, 6, 8, 20, 40, 60, 80, 200 or 400 Å.

Next, a sixth photoresist layer 328 is formed thereupon the first face 4 of the substrate wafer 2 by a spin-on procedure leaving the structure shown in FIG. 3AA.

Next, a sixth masking layer masking pattern is formed in the sixth photoresist layer 328 by a masking procedure leaving, as shown in FIG. 3BB, a sixth unmasked area 330 on the first face 4 which exposes an area of the electrically conductive material 326 at the completion of this sixth masking step. This step also leaves behind a sixth masking layer 332 which covers an area of the electrically conductive layer 326 which lies directly above the underlying heat absorbent layer 310 and extends outwards between about 1, 3, 5, 7, 9 or 10 μm and about 2, 4, 6 or 8 μm. The remaining sixth masking layers 332 are resistant to etching solutions, and protect the underlying electrically conductive layer 326.

After the sixth masking procedure is complete, the sixth unmasked areas 330 are next subjected to an etching process which etching process continues until the exposed electrically conductive layer 326 is removed.

Next, the wafer is subjected to a sixth cleaning process to remove the remaining sixth masking layers 332 leaving an area of electrically conductive material on the first face 4 above the lip of the light guiding material 36 to form an electrode 334 as shown in FIG. 3CC.

Next, a seventh photoresist layer 338 is formed on the second face 6 by a spin-on procedure leaving the structure as shown in FIG. 3DD.

Next, a seventh masking layer masking pattern is formed in the seventh photoresist layer 338 by a masking procedure and, as shown in FIG. 3EE, a seventh unmasked area 340 on the second face 6 of substrate wafer 2 forming a 3 micron by 3 micron square area centered directly below the first void 18 is exposed at the completion of this seventh masking step. The remaining seventh masking layer 342 is resistant to etching solutions, and protects the underlying first passivation layer 8 found on the second face 6.

Next, the seventh unmasked area 340 is subjected to an etching process and the seventh masking layer 342 removed. As shown in FIG. 3FF there is created at this stage a second area of exposed substrate 344.

After the above masking, etching and photoresist removal procedures are complete, the second area of exposed substrate 344 is next subjected to an anisotropic etching process which etching process continues until the <111> crystal planes of the substrate expose the pyramidally shaped first passivation layer 8 formed on the first face 4 to a height of height of between about 500, 600, 700, 800, 900 or 1000 Å and about 5500, 650, 750, 850 or 950 Å. The structure of the second void 346 created in the substrate 2 by this anisotropic etching process is shown in FIG. 3GG. This second void 346 has the shape of a truncated pyramidal void which is defined by sloping sides 348 which intersect with a flat roof plane 350 through which an inverted pyramidally shaped point 352 centrally projects.

Next, the exposed first passivation layer 354 on the centrally projecting inverted pyramidally shaped point 352 is subjected to an eighth etching process and the exposed first passivation layer removed. At this stage there is exposed a thin tapered point 356 clad with a light confining layer 358 as shown in FIG. 3HH.

Lastly, the exposed light confining layer 358 on the thin tapered point 356 is subjected to a ninth etching process and the exposed light confining layer 358 removed. This series of micromachining steps creates a near field optical detector with a planar detecting layer 364 as shown in FIG. 3II wherein there is exposed an exceedingly slender detector tip 360 comprising in part an area of exposed light guiding material 362 coupled with a planar detecting layer reposing substantially in vertical alignment with the axis of the detector tip. The detector tip 360 has a diameter of approximately 10 to 20 nm at its apex.

### IV THE FOURTH STRUCTURE—A CAPILLARY ELECTROPHORESIS DEVICE TO RAPIDLY AND ACCURATELY SEQUENCE LONG DNA FRAGMENTS WITH INTEGRATED NEAR FIELD OPTICAL DETECTOR

The following establishes the micromachining steps necessary for the manufacture and integration of the Near Field Optical Detector (“NFOD”) with a chip capillary electrophoresis (“CE”) 6 device useful for the rapid and accurate sequencing of long DNA fragments. The integrated near field optical detector/chip capillary electrophoresis device is hereinafter referred to as the NFOD/CE chip. This example also establishes the use of the NFOD/CE chip in the detection of individual nucleotides and their relative sequence on a DNA fragment.

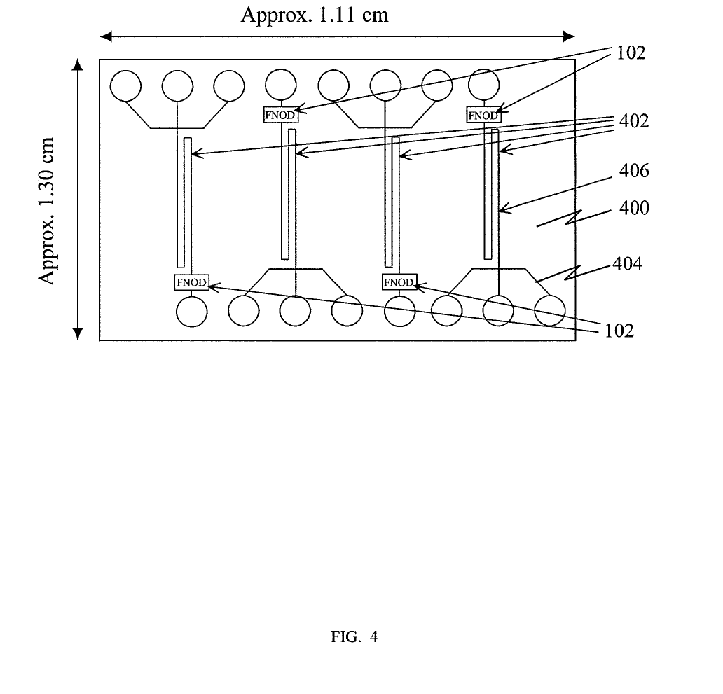

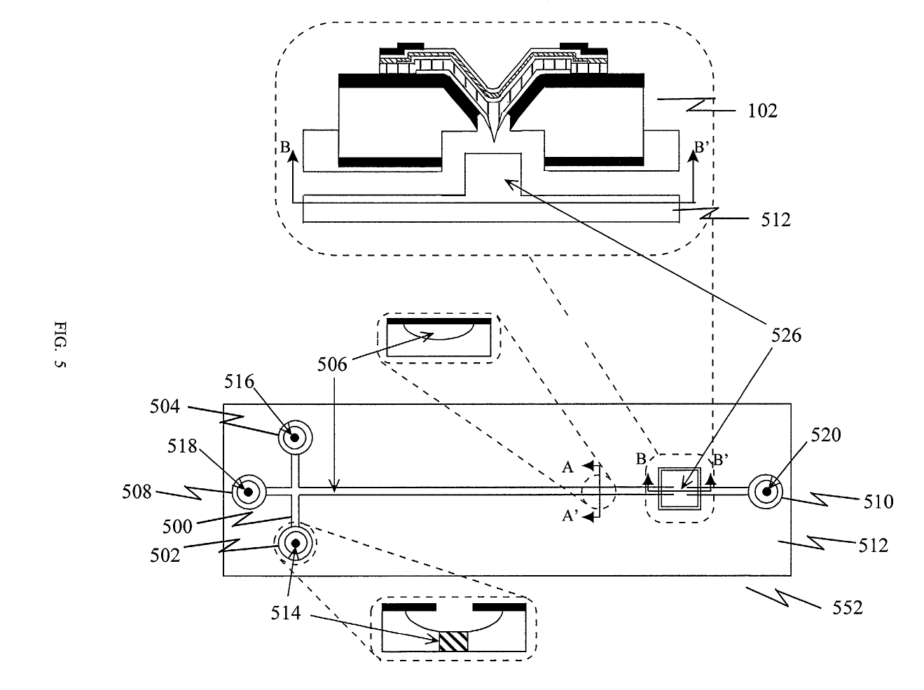

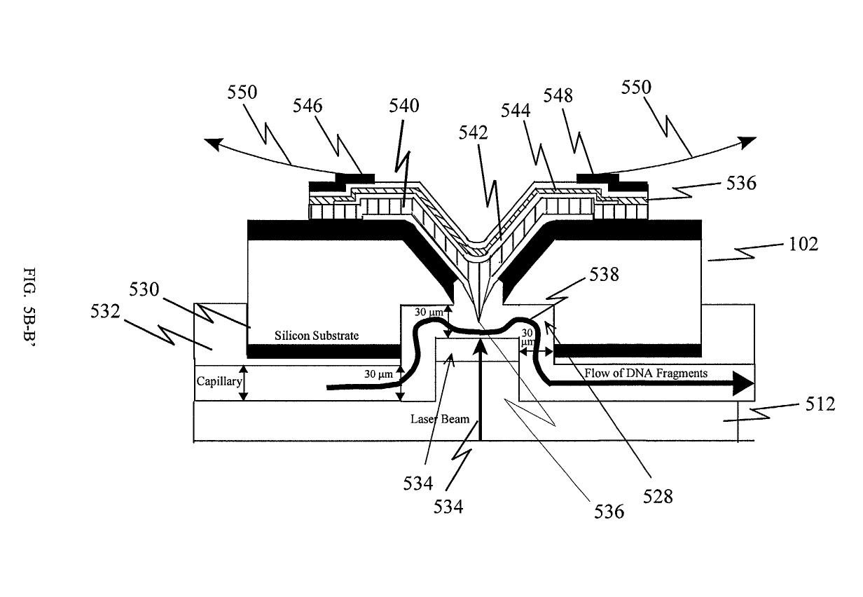

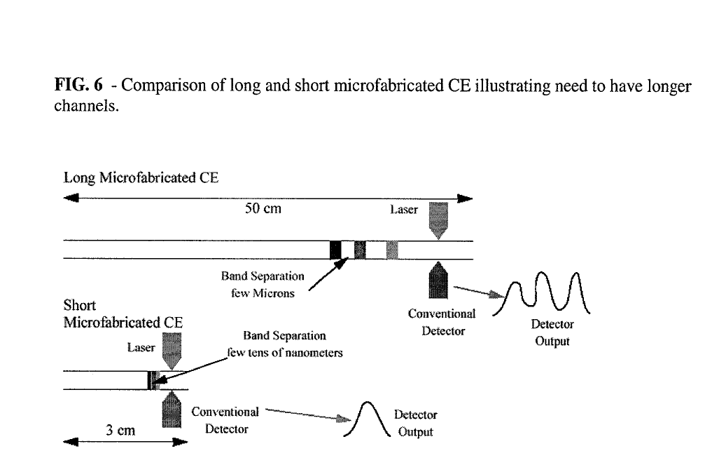

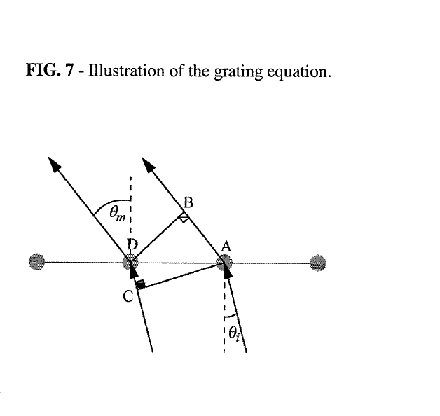

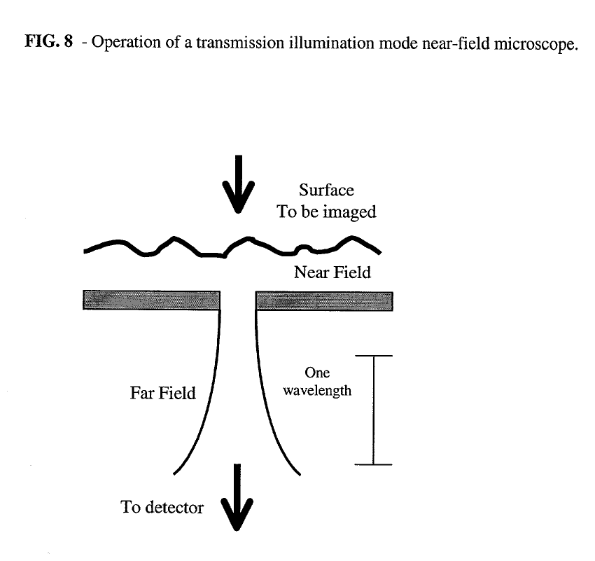

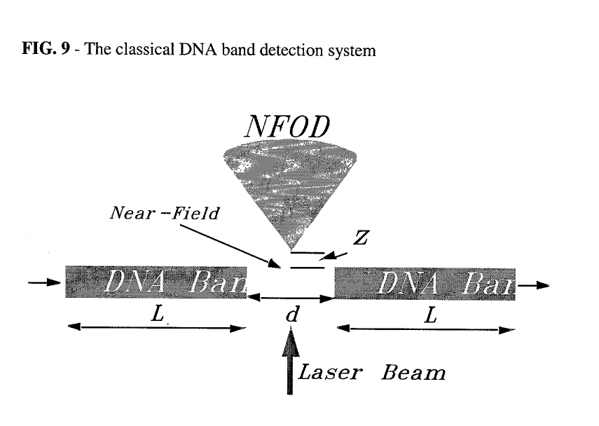

FIGS. 4, 5 and 5B-B′ show various details regarding the integration of the NFOD described in Example 1 with a CE device in a NFOD/CE chip useful for DNA sequence detection. FIG. 4 shows in plan view the integration of a NFOD with a microfabricated CE device on a chip. The other embodiments of the NFOD as described in above and in following Examples 2 and 3 can alternatively be used instead of the NFOD described in above and in Example 1.

The NFOD/CE chip 400 comprises a glass chip with one or more microchannel structures arrayed on the top surface of the glass chip as shown in FIG. 4. Each microchannel structure 402 is comprised of a sample microchannel 404 which can be between about 30, 50, 70, 90, 100 or 150 μm and about 40, 60, 80 or 125 μm in depth by between about 30, 50, 70, 90, 100 or 150 μm and about 40, 60, 80 or 125 μm in width. Each sample microchannel 404 fluidically intersects and crosses a separation microchannel 406 of similar dimensions.

As shown in more detail in FIG. 5 and FIG. 5B-B′ there is arrayed and fluidically connected at one end of the sample microchannel 500 a sample well 502 and a waste well 504 at the other end of the sample microchannel 500. On one end of the separation microchannel 506 there is arrayed and fluidically connected a buffer well 508 and at the other end is a waste/buffer well 510. Each well is micromachined into the glass chip 512 using conventional chip micromachining techniques. At the bottom of the sample well 502 there is a first electrode 514. At the bottom of the waste well 504 there is similarly a second electrode 516. A third electrode 518 is located in the bottom of the buffer well 508 and a fourth electrode 520 is located in the bottom of the waste/buffer well 510. Each of these electrodes can be conductive materials such as metals and polymers which are deposited in holes which were micromachined through the bottom of the wells to the bottom surface of the glass chip 512 to permit electrical connectivity between the bottom surface of the glass chip 512 and the interior of the various wells. The first 514 and second 516 electrodes are connected to a means 522 of applying a regulated electric current sufficient for running a sample containing DNA fragments from the sample well 502 through the sample microchannel 500 to the waste well 504. The third 518 and fourth 520 electrodes are similarly connected to a means 524 of applying a regulated electric current sufficient to separate and run DNA fragments down the length of the separation channel 506 from where the separation channel 506 intersects with the sample microchannel 500 down to the buffer/waste well 510.

Right before the separation microchannel fluidically connects with the waste/buffer well, there is a diverting barrier 526 which would normally stop the flow and migration of DNA fragments were it not for the void 528 presented by the NFOD lying directly above the diverting barrier 526 as shown in FIG. 5B-B′. This void 528 presents a microchannel through which the DNA fragments may continue their journey to ultimately end up in the waste/buffer well 508.

The NFOD rests in a flanged opening 530 micromachined into a glass lid 532 which lies in a sealingly fashion directly on the upper surface of the glass chip 512. This complete arrangement comprises the capillary electrophoresis device with integrated near-field optical detector (“NFOD/CE”) of the present invention 554.

In operation, one first chemically passivates the sample 500 and separation 506 microchannels to prevent electroosmotic flow and sample adsorption to the walls. See, Hjerten, S. J. Chromatogr. 1985, 347, 191-198.

Next, the sample 500 and separation 506 microchannels are then filled with polyacrylamide gel solution.

Next, the ends of the sample 500 and separation 506 microchannels are closed and sealed with the glass lid 532 and the NFOD/CE chip submerged in an ice bath exposed to high-energy UV light source overnight to polymerize the gel. After polymerization, separation microchannel 506 is pre-run prior to sample injection.

Next, samples are prepared as described by Soper. See, Soper, S. A. Flanagan, J. H. Legendre, B. L Williams, D. C. Hammer, R. P., IEEE-QE, 1996, 2, 1129-1139. The samples are not heat-denatured.

Next, a small sample containing DNA fragments is pipetted into the sample well 502 and the sample electrophoresed across the sample microchannel 500.

Next, once the sample reaches the intersection of the sample 500 and separation microchannels 506 the voltage is switched to the third 518 and fourth 520 electrodes to create an electric field across the separation microchannel 506. During their traversal of the separation microchannel 506 the DNA fragments are separated according to their size by means of molecular sieving.

Next, the NFOD/CE chip is placed on a computer-controlled translation stage and the detector tip 536 and the void 528 on the NFOD/CE chip is aligned with the laser light coming from a semiconductor laser. This laser light has wavelengths in approximately the 400 to 600 nm range and a field strength of approximately 5 mW. This laser light 534 is focused from under the NFOD/CE chip up through the diverting barrier 526 to within the separation channel 506.

Next, the individual nucleotides on the DNA fragments are then exposed to and excited by a laser light 534 as the nucleotides pass up and over the diverting barrier 526 and past the detector tip 536 of the NFOD. As a result of this optical excitation, emitted light from the individual nucleotides on a DNA fragment 538 is projected onto and collected by the detector tip 536 from where the emitted light is guided through the light guiding layer 540 to be absorbed by the IR absorbing layer 542. The IR absorbing layer expands and contracts with varying levels of light absorption and thus causes the respective expansion and contraction in the overlying pyroelectric layer 544 which generates an electrical signal which is conducted by the first NFOD electrode 546 and second NFOD electrode 548.

Finally, signal from the electrical leads 550 of the NFOD is sampled and filtered with an electronic low-pass filter prior to digitization with a computer resident board 552.

### EXAMPLES

### Example 1

### Near Field Optical Detector With Pyramidal Detecting Layer

This example establishes the micromachining steps necessary for the manufacture of one embodiment of the present invention, namely, a Near Field Optical Detector with a pyramidal detecting layer which results in the detecting layer lying in close proximity with the detector tip.

FIGS. 1A to 1HH illustrate the method for micromachining the near field optical detector 100 with a conical detecting detector of FIG. 1HH. These series of figures show cross-sectional views of a substrate wafer at various stages or steps during the fabrication of the near-field optical detector. The process first begins by providing a substrate wafer 2 as shown in FIG. 1A. The substrate material is this and subsequent examples is single crystal <100> oriented silicon. Substrate wafer 2 has a first face 4 and a second face 6 and a thickness T. The substrate wafer may have any convenient diameter and thickness but in this instance, a wafer of about 500 μm thick is used.

Next, as shown in FIG. 1B, a first passivation step provides a first passivation layer 8 of silicon dioxide on each of both the first face 4 and the second face 6 of substrate wafer 2.

Next, a first photoresist layer 10 is formed on the first face 4 by a spin-on procedure leaving the structure as shown in FIG. 1C.

Next, a first masking layer masking pattern is formed in the first photoresist layer 10 on by a masking procedure and, as shown in FIG. 1D, a first unmasked area 12 on the first face 4 of substrate wafer 2 with an approximately 2 μm by 2 μm square area is exposed at the completion of this first masking step. The remaining first masking layer 14 is resistant to etching solutions, and protects the underlying first passivation layer 8.

Next, the first unmasked area 12 is subjected to an oxide etching process and the first masking layer 14 removed. As shown in FIG. 1E there is created at this stage a first area of exposed substrate 16.

After the above masking, etching and photoresist removal procedures are complete, the first area of exposed substrate 16 is next subjected to a silicon anisotropic etching process which etching process continues until the <111> crystal planes of the substrate meet at the bottom-of the first void 18 created in the substrate 2 as shown in FIG. 1F. This first void has the shape of an inverted pyramidal first void which is defined by sides 20 which intersect at a sharp point 22.

Next, the is subjected to a first cleaning process, preferably by the RCA or Piranha methods.

Next, the wafer is subjected to a second passivation procedure using a low temperature thermal oxidation of the wafer. This procedure is preferentially carried out at a temperature of between about 800° to 950° C. to introduce a curved surface in the newly formed passivation layers which now form the sides 20 of the first void 18 as shown in FIG. 1G. The thickness of the second passivation layer 24 formed on the first 4 and second faces 6 of the wafer 2 upon completion of this step is about 1000 Å. Upon completion of this second passivation process the sides 20 of the first void 18 define a cusp-shaped tapered void 26.

Next, a thin layer of gold 28 is deposited by an electron beam evaporation process onto the first face 4 of the wafer 2 as shown in FIG. 1H. This layer of gold is about 500 Å thick.

Next, a second photoresist layer 30 is formed thereupon the layer of gold 28 by a spin-on procedure resulting in the structure shown in FIG. 1I.

Next, a second masking layer masking pattern is formed in the second photoresist layer 30 by a masking procedure and, as shown in FIG. 1H, a second unmasked area 32 on the first face 4 of substrate wafer 2 starting about 1 μm beyond the first void 18 is exposed at the completion of this second masking step. The remaining second photoresist layer 34 is resistant to etching solutions, and protects the underlying gold layer 28.

After the second masking procedure is complete, the exposed gold layer 28 is next subjected to an acid etch process which etching process continues until the exposed gold layer 28 is removed and the wafer subjected to a second cleaning process, preferably by the RCA or Piranha methods to remove the remaining second masking layer 34. This process leaves an area of gold 28 on the first void sides 20 and extending about 1 μm beyond the first void 18 to form a lip 36 of gold as shown in FIG. 1L. The previous five processing steps can alternatively be replaced by a lift-off process as described previously and as shown in FIGS. 1H′ though 1L′.

Next, a thin layer 38 of silicon nitride is deposited on the first face 4 of the substrate wafer 2 by a sputtering method leaving the structure as shown in FIG. 1M. This layer of silicon nitride has a thickness of about 1000 Å.

Next, a third photoresist layer 40 is formed thereupon the first face 4 of the substrate wafer 2 by a spin-on procedure leaving the structure shown in FIG. 1N.

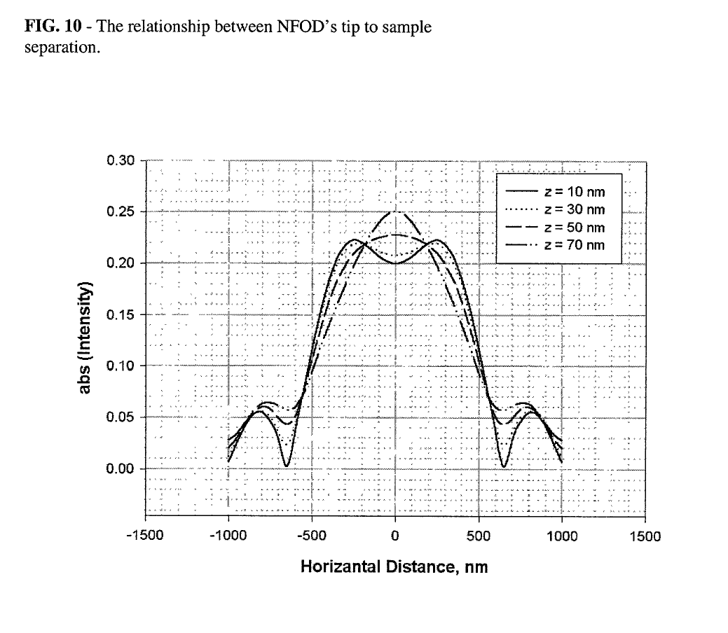

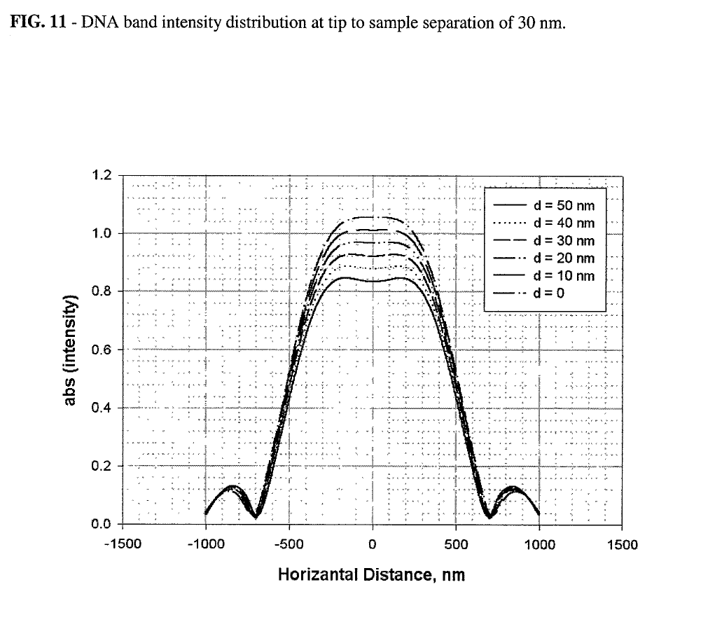

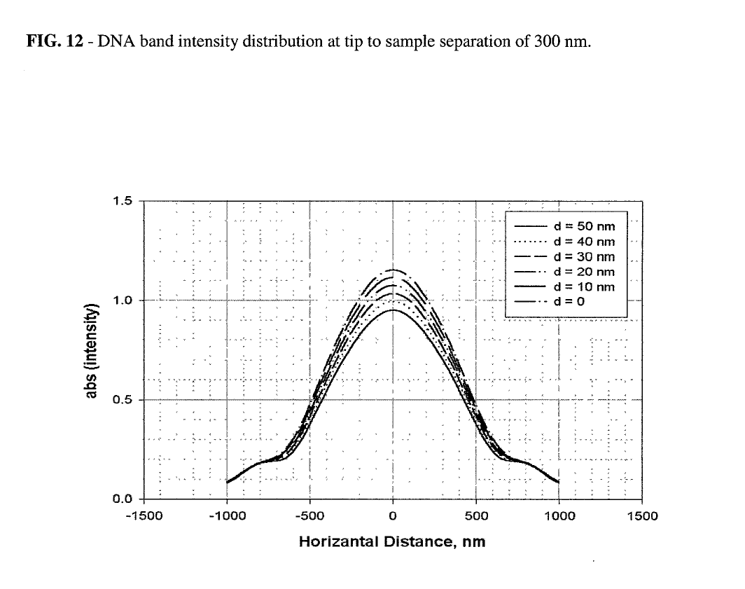

Next, a third masking layer masking pattern is formed in the third photoresist layer 40 by a masking procedure and, as shown in FIG. 10, a third unmasked area 42 on the first face 4 of substrate wafer 2 starting about 2 μm beyond the lip of the gold layer 36 is exposed at the completion of this third masking step. The remaining third masking layer 44 is resistant to etching solutions, and protects the underlying silicon nitride layer 38.

After the third masking procedure is complete, the third unmasked area 42 is next subjected to a plasma etching process which etching process continues until the exposed silicon nitride layer 38 is removed.

Next, the wafer is subjected to a third cleaning process, preferably by the RCA or Piranha methods to remove the remaining third masking layer 44 leaving an area of silicon nitride 38 on the first void sides 20 and extending about 2 μm beyond the lip 36 of the gold layer 36 to form a lip 46 of silicon nitride material as shown in FIG. 1P.

Next, a thin layer 48 of carbon is deposited on the first face 4 by a sputtering method leaving the structure as shown in FIG. 1Q. This layer of carbon 48 is about 0.1 μm thick.

Next, a fourth photoresist layer 50 is formed thereupon the first face 4 of the substrate wafer 2 by a spin-on procedure leaving the structure shown in FIG. 1R.

Next, a fourth masking layer masking pattern is formed in the fourth photoresist layer 50 by a masking procedure, as shown in FIG. 1S, in a fourth unmasked area 52 on the first face 4 of substrate wafer 2 which exposes an area of the carbon layer 48 at the completion of this fourth masking step. This step also leaves behind a fourth masking layer 54 which extends to within about 2 μm from the edge of the underlying lip 46 of the gold layer. The remaining fourth masking layer 54 is resistant to etching solutions, and protects the underlying carbon layer 48.

After the fourth masking procedure is complete, the fourth unmasked area 52 is next subjected to an oxidizing etching process which etching process continues until the exposed carbon layer 48 is removed.

Next, the wafer is subjected to a fourth cleaning process, preferably by the RCA or Piranha methods to remove the remaining fourth masking layer 54 leaving an area of carbon 48 on the first void sides 20 and extending about 2 μm on the first face 4 until just before reaching the lip 46 of the silicon nitride layer 38 to form the structure as shown in FIG. 1T.

Next, a thin layer 56 of PVDF is deposited on the first face 4 by sputtering leaving the structure as shown in FIG. 1U. The PVDF layer is about 9 μm thick.

Next, a fifth photoresist layer 58 is formed thereupon the first face 4 of the substrate wafer 2 by a spin-on procedure leaving the structure shown in FIG. 1V.

Next, a fifth masking layer masking pattern is formed in the fifth photoresist layer 58 by a masking procedure leaving, as shown in FIG. 1W, a fifth unmasked area 60 on the first face 4 which exposes an area of the PVDF layer 56 at the completion of this fifth masking step. This step also leaves behind a fifth masking layer 62 which extends to the edge of the underlying lip 46 of the gold layer. The remaining fifth masking layer 62 is resistant to etching solutions, and protects the underlying PVDF layer 56.

After the fifth masking procedure is complete, the fifth unmasked area 60 is next subjected to a reactive ion etching process which etching process continues until the exposed PVDF layer 56 is removed.

Next, the wafer is subjected to a fifth cleaning process, preferably by the RCA or Piranha methods to remove the remaining fifth masking layer 62 leaving an area of PVDF material 56 on the first void sides 20 and extending about 2 μm on the first face 4 until stopping just above the lip 46 of the silicon nitride layer 38 to form the structure as shown in FIG. 1X.

Next, a thin layer 64 of PEDT/PSS is deposited on the first face 4 by sputtering leaving the structure as shown in FIG. 1Y. This PEDT/PSS layer is about 500 Å thick.

Next, a sixth photoresist layer 66 is formed thereupon the first face 4 of the substrate wafer 2 by a spin-on procedure leaving the structure shown in FIG. 1Z.

Next, a sixth masking layer masking pattern is formed in the sixth photoresist layer 66 by a masking procedure leaving, as shown in FIG. 1AA, a sixth unmasked area 68 on the first face 4 which exposes an area of the PEDT/PSS layer 64 at the completion of this sixth masking step. This step also leaves behind a sixth masking layer 70 which covers an area of the PEDT/PSS layer 64 which lies directly above the PVDF layer 56. The remaining sixth masking layer 70 is resistant to etching solutions, and protects the underlying PEDT/PSS layer 64.

After the sixth masking procedure is complete, the sixth unmasked area 68 is next subjected to an etching process using a PEDT/PSS solvent such as photo developer which etching process continues until the exposed PEDT/PSS layer 64 is removed.

Next, the wafer is subjected to a sixth cleaning process, preferably by the RCA or Piranha methods to remove the remaining sixth masking layer 70 leaving an area of PEDT/PSS on the first face 4 above the PVDF layer 56 to form an electrode 72 as shown in FIG. 1BB.

Next, a seventh photoresist layer 76 is formed on the second face 6 by a spin-on procedure leaving the structure as shown in FIG. 1CC.

Next, a seventh masking layer masking pattern is formed in the seventh photoresist layer 76 by a masking procedure and, as shown in FIG. 1DD, a seventh unmasked area 78 on the second face 6 of substrate wafer 2 with an approximately 3 micron by 3 micron square area centered directly below the first void 18 is exposed at the completion of this seventh masking step. The remaining seventh masking layer 80 is resistant to etching solutions, and protects the underlying first silicon dioxide layer 8 found on the second face 6.

Next, the seventh unmasked area 78 is subjected to an etching process and the seventh masking layer 80 removed. As shown in FIG. 1EE there is created at this stage a second area of exposed substrate 82.

After the above masking, etching and photoresist removal procedures are complete, the second area of exposed substrate 82 is next subjected to a silicon anisotropic etching process which etching process continues until the <111> crystal planes of the substrate expose the pyramidally shaped first silicon dioxide layer 8 formed on the first face 4 to a height of about 500 A. The structure of the second void 84 created in the substrate 2 by this anisotropic etching process is shown in FIG. 1FF. This second void 84 has the shape of a truncated pyramidal void which is defined by sloping sides 86 which intersect with a flat roof plane 88 through which an inverted pyramidally shaped point 90 centrally projects.

Next, the exposed first silicon dioxide layer 92 on the centrally projecting inverted pyramidally shaped point 90 is subjected to an eighth etching process using oxide etchants and the exposed first passivation layer 8 removed. At this stage there is exposed a thin tapered point 94 clad with a gold layer light confining layer 96 as shown in FIG. 1GG.

Lastly, the exposed gold layer 96 on the thin tapered point 94 is subjected to a ninth etching process using a plasma etchant and the exposed gold layer removed. This series of micromachining steps creates a near field optical detector with a pyramidal detecting layer 102 as shown in FIG. 1HH wherein there is exposed an exceedingly slender detector tip 98 comprising in part an area of exposed light guiding material 100 coupled with a detecting layer in close proximity with the detecting tip. The detector tip 98 has a diameter of approximately 10 to 20 nm at its apex.

### Example 2

### Near Field Optical Detector With Detecting Layer Arrayed on a Convex Lens

This example establishes the micromachining steps necessary for the manufacture of one embodiment of the present invention, namely, a Near Field Optical Detector with a detecting layer which a convex lens on which the detecting layer lies.

First, all of the steps described previously in Example 1 up to and through the second etching, photoresist removal and wafer cleaning are incorporated herein and should first be followed. These steps result in the same structures which are shown in FIGS. 1A through 1L. (With the adoption of these steps, references to FIG. 1A will now, for the purposes of this second example, referred to FIG. 2A instead. Similarly FIG. 1B will be referred to now as FIG. 2B on up through and including FIG. 1L which will now be referred to as FIG. 2L.)

Now to continue. Next, a thick layer 200 of silicon nitride is deposited on the first face 4 of the substrate wafer 2 by a sputtering technique leaving the structure as shown in FIG. 2M. An important quality for the light guiding material is the ability to guide light within the resultant near field optical detector with minimum optical losses or attenuation. This silicon nitride layer is about 5 μm thick.

Next, the first face 4 of the substrate wafer is subjected to a mechanical polishing process which results in the structure as shown in FIG. 2N. Note that the polishing continues until the silicon nitride layer is flat and parallel to the original first face 2 of the substrate wafer 2. Polishing stops when the layer of silicon nitride layer 200 is about 0.5 μm thick.

Next, a third photoresist layer 202 is formed thereupon the first face 4 of the substrate wafer 2 by a spin-on procedure leaving the structure shown in FIG. 20.

Next, a third masking layer masking pattern is formed in the third photoresist layer 202 by a masking procedure and, as shown in FIG. 2P, a third unmasked area 204 on the first face 4 of substrate wafer 2 immediately above the edges of the first void 18 is exposed at the completion of this third masking step. The remaining third masking layer 206 is resistant to etching solutions, and protects the underlying silicon nitride layer 200.

After the third masking procedure is complete, the wafer is subjected to high temperatures of about 150° C. for a short time to heat and reflow the third masking layer 206 to create the convex shaped third masking layer 206 shown in FIG. 2Q.

Next, the third unmasked area 206 is next subjected to a plasma etching process which etching process continues until the third masking layer 206 and part of the silicon nitride layer 200 is removed leaving the convex shaped structure 208 shown in FIG. 2R.

Next, a fourth photoresist layer 210 is formed thereupon the layer of light guiding material 200 by a spin-on procedure resulting in the structure shown in FIG. 2S.

Next, a fourth masking layer masking pattern is formed in the fourth photoresist layer 210 by a masking procedure and, as shown in FIG. 2T, a fourth unmasked area 212 on the first face 4 of substrate wafer 2 starting about 2 μm beyond the first void 18 is exposed at the completion of this second masking step. The remaining fourth photoresist layer 214 is resistant to etching solutions, and protects the underlying silicon nitride layer 200.

After the fourth masking procedure is complete, the exposed silicon nitride layer 200 is next subjected to a plasma etching process which etching process continues until the exposed silicon nitride layer 38 is removed.

Next, the wafer is subjected to a third cleaning process, preferably by the RCA or Piranha methods to remove the remaining fourth masking layer 214 leaving the convex lens 208 surrounded by a lip of silicon nitride 216 extending about 2 μm beyond the edge of the first void 18 as shown in FIG. 2U.

Next, a thin layer 218 of gold is deposited on the first face 4 by a metalization technique leaving the structure as shown in FIG. 2V. This gold layer is about 0.1 μm thick.

Next, a fifth photoresist layer 220 is formed thereupon the first face 4 of the substrate wafer 2 by a spin-on procedure leaving the structure shown in FIG. 2W.

Next, a fifth masking layer masking pattern is formed in the fifth photoresist layer 220 by a masking procedure, as shown in FIG. 2X, leaving a fifth unmasked area 222 on the first face 4 of substrate wafer 2 which exposes an area of the gold layer 218 at the completion of this fifth masking step. This step also leaves behind a fifth masking layer 224 which extends outward about 2 μm from the edge of the underlying lip 216 of the silicon nitride layer. The remaining fifth masking layer 214 is resistant to etching solutions, and protects the underlying gold layer 218.

After the fifth masking procedure is complete, the fifth unmasked area 222 is next subjected to a HF acid etching process which etching process continues until the exposed gold layer 218 is removed.

Next, the wafer is subjected to a fifth cleaning process, preferably by the RCA or Piranha methods to remove the remaining fifth masking layer 224 leaving an area of gold 218 on the convex lens 208 and surrounding lip of silicon nitride 216 extending about 2 μm beyond the edge of the first void 18 as shown to form the structure as shown in FIG. 2Y.

Next, a thin layer 226 of PVDF is deposited on the first face 4 by sputtering leaving the structure as shown in FIG. 2Z. This layer of PVDF is about 9 μm thick.

Next, a fifth photoresist layer 228 is formed thereupon the first face 4 of the substrate wafer 2 by a spin-on procedure leaving the structure shown in FIG. 2AA.

Next, a fifth masking layer masking pattern is formed in the fifth photoresist layer 228 by a masking procedure leaving, as shown in FIG. 2BB, a fifth unmasked area 230 on the first face 4 which exposes an area of the PVDF layer 226 at the completion of this fifth masking step. This step also leaves behind a fifth masking layer 232 which extends to the edge of the underlying lip 216 of the silicon nitride layer. The remaining fifth masking layer 232 is resistant to etching solutions, and protects the underlying PVDF layer 226.

After the fifth masking procedure is complete, the fifth unmasked area 230 is next subjected to a PVDF etching process using a PVDF solvent which etching process continues until the exposed PVDF layer 226 is removed.

Next, the wafer is subjected to a fifth cleaning process, preferably by the RCA or Piranha methods to remove the remaining fifth masking layer 232 leaving an area of PVDF 226 completely covering the underlying gold layer 218 to form the structure as shown in FIG. 2CC.

Next, a thin layer of gold 234 is deposited on the first face 4 by sputtering leaving the structure as shown in FIG. 2DD. This gold layer is about 500 Å thick.

Next, a sixth photoresist layer 236 is formed thereupon the first face 4 of the substrate wafer 2 by a spin-on procedure leaving the structure shown in FIG. 2EE.

Next, a sixth masking layer masking pattern is formed in the sixth photoresist layer 236 by a masking procedure leaving, as shown in FIG. 2FF, a sixth unmasked area 238 on the first face 4 which exposes an area of the gold layer 234 at the completion of this sixth masking step. This step also leaves behind a sixth masking layer 240 which covers two areas of the gold layer 234 which lie on opposite sides of the first void sides and extend outwards about 2 μm. The remaining sixth masking layers 240 are resistant to etching solutions, and protect the underlying gold layer 234.

After the sixth masking procedure is complete, the sixth unmasked area 238 is next subjected to a HF acid etching process which etching process continues until the exposed gold layer 234 is removed.

Next, the wafer is subjected to a sixth cleaning process, preferably by the RCA or Piranha methods to remove the remaining sixth masking layers 240 leaving two areas of gold on the first face 4 above the lip of the light guiding material 36 to form a first NFOD electrode 242 and second NFOD electrode 244 as shown in FIG. 2GG.

Next, a seventh photoresist layer 246 is formed on the second face 6 by a spin-on procedure leaving the structure as shown in FIG. 2HH.

Next, a seventh masking layer masking pattern is formed in the seventh photoresist layer 246 by a masking procedure and, as shown in FIG. 2II, a seventh unmasked area 248 on the second face 6 of substrate wafer 2 forming an approximately 3 micron by 3 micron square area centered directly below the first void 18 is exposed at the completion of this seventh masking step. The remaining seventh masking layer 250 is resistant to etching solutions, and protects the underlying first silicon dioxide layer 8 found on the second face 6.

Next, the seventh unmasked area 248 is subjected to an oxide etching process and the seventh masking layer 250 removed. As shown in FIG. 2JJ there is created at this stage a second area of exposed substrate 252.

After the above masking, etching and photoresist removal procedures are complete, the second area of exposed substrate 252 is next subjected to a silicon anisotropic etching process which etching process continues until the <111> crystal planes of the substrate expose the pyramidally shaped first silicon dioxide layer 8 formed on the first face 4 to a height of about 500 Å. The structure of the second void 254 created in the substrate 2 by this anisotropic etching process is shown in FIG. 2KK. This second void 254 has the shape of a truncated pyramidal void which is defined by sloping sides 256 which intersect with a flat roof plane 258 through which an inverted pyramidally shaped point 260 centrally projects.

Next, the exposed silicon dioxide layer 262 on the centrally projecting inverted pyramidally shaped point 260 is subjected to an eighth etching process using oxide etchants and the exposed first silicon dioxide layer removed. At this stage there is exposed a thin tapered point 264 clad with a gold layer 266 as shown in FIG. 2LL.

Lastly, the exposed gold layer 266 on the thin tapered point 264 is subjected to a ninth etching process using a plasma etchant and the exposed gold layer removed. This series of micromachining steps creates a near field optical detector with a detecting layer arrayed on a convex lens 272 as shown in FIG. 2MM wherein there is exposed an exceedingly slender detector tip 268 comprising in part an area of exposed silicon nitride 270. This detector tip 268 has a diameter of approximately 10 to 20 nm at its apex.

### Example 3

### Near Field Optical Detector With Planar Detecting Layer

This example establishes the micromachining steps necessary for the manufacture of one embodiment of the present invention, namely, a Near Field Optical Detector with a planar detecting layer which lies substantially vertical with respect to the axis of the detector tip.

First, all of the steps described previously in Example 1 up to and through the second etching, photoresist removal and wafer cleaning are incorporated herein and should first be followed. These steps result in the same structures which are shown in FIGS. 1A through 1L. (With the adoption of these steps, references to FIG. 1A will now, for the purposes of this second example, referred to FIG. 3A instead. Similarly FIG. 1B will be referred to now as FIG. 3B on up through and including FIG. 1L which will now be referred to as FIG. 3L.) Now to continue. Next, a thick layer 300 of silicon nitride is deposited on the first face 4 of the substrate wafer 2 by sputtering leaving the structure as shown in FIG. 3M. This silicon nitride layer is about 5 μm thick.

Next, the first face 4 of the substrate wafer is subjected to a mechanical polishing process which results in the structure as shown in FIG. 3N. Note that the polishing continues until the silicon nitride layer is flat and parallel to the original first face 2 of the substrate wafer 2 and the polishing stops when the layer of silicon nitride 300 is about 0.5 μm thick.

Next, a third photoresist layer 302 is formed thereupon the first face 4 of the substrate wafer 2 by a spin-on procedure leaving the structure shown in FIG. 3O.

Next, a third masking layer masking pattern is formed in the third photoresist layer 302 by a masking procedure and, as shown in FIG. 3P, a third unmasked area 304 on the first face 4 of substrate wafer 2 starting about 2 μm beyond the edge of the first void 18 is exposed at the completion of this third masking step. The remaining third masking layer 306 is resistant to etching solutions, and protects the underlying silicon nitride layer 300.

After the third masking procedure is complete, the third unmasked area 306 is next subjected to a third etching process by plasma which etching process continues until the exposed silicon nitride layer 300 is removed.

Next, the wafer is subjected to a third cleaning process, preferably by the RCA or Piranha methods to remove any remaining third masking layer 306 leaving an area of silicon nitride 300 filing the first void 18 and extending about 2 μm beyond the lip 36 of the gold layer to form a lip 308 of silicon nitride as shown in FIG. 3Q.

Next, a thin layer of PEDT/PSS polymer 310 is deposited on the first face 4 by a spin-on technique leaving the structure as shown in FIG. 3R. This PEDT/PSS polymer layer is about 0.1 μm thick.

Next, a fourth photoresist layer 312 is formed thereupon the first face 4 of the substrate wafer 2 by a spin-on procedure leaving the structure shown in FIG. 3S.

Next, a fourth masking layer masking pattern is formed in the fourth photoresist layer 312 by a masking procedure, as shown in FIG. 3T, leaving a fourth unmasked area 314 on the first face 4 of substrate wafer 2 which exposes an area of the PEDT/PSS polymer layer 310 at the completion of this fourth masking step. This step also leaves behind a fourth masking layer 316 which extends to within 2 μm from the edge of the underlying lip 36 of the PEDT/PSS polymer layer. The remaining fourth masking layer 316 is resistant to etching solutions, and protects the underlying PEDT/PSS polymer layer 310.

After the fourth masking procedure is complete, the fourth unmasked area 314 is next subjected to a PEDT/PSS polymer etching process using a PEDT/PSS solvent which etching process continues until the exposed PEDT/PSS polymer layer 310 is removed.

Next, the wafer is subjected to a fourth cleaning process, preferably by the RCA or Piranha methods to remove the remaining fourth masking layer 316 leaving an area of PEDT/PSS material 310 on the area directly above the void 18 and extending about 2 μm beyond the edge of the first void 18 as shown to form the structure as shown in FIG. 3U.

Next, a thin layer 318 of PVDF is deposited on the first face 4 by sputtering leaving the structure as shown in FIG. 3V. This PVDF layer is about 9 μm thick.

Next, a fifth photoresist layer 320 is formed thereupon the first face 4 of the substrate wafer 2 by a spin-on procedure leaving the structure shown in FIG. 3W.

Next, a fifth masking layer masking pattern is formed in the fifth photoresist layer 320 by a masking procedure leaving, as shown in FIG. 3X, a fifth unmasked area 322 on the first face 4 which exposes an area of the PVDF layer 318 at the completion of this fifth masking step. This step also leaves behind a fifth masking layer 324 which extends to the edge of the underlying lip 36 of the gold layer. The remaining fifth masking layer 324 is resistant to etching solutions, and protects the underlying PVDF layer 318.

After the fifth masking procedure is complete, the fifth unmasked area 322 is next subjected to a PVDF etching process using a PVDF solvent which etching process continues until the exposed PVDF layer 318 is removed.

Next, the wafer is subjected to a fifth cleaning process, preferably by the RCA or Piranha methods to remove the remaining fifth masking layer 324 leaving an area of PVDF material 318 completely substantially covering the underlying PEDT/PSS layer 310 to form the structure as shown in FIG. 3Y.

Next, a thin layer 326 of gold is deposited on the first face 4 by sputtering leaving the structure as shown in FIG. 3Z. This gold layer is about 500 Å thick.

Next, a sixth photoresist layer 328 is formed thereupon the first face 4 of the substrate wafer 2 by a spin-on procedure leaving the structure shown in FIG. 3AA.

Next, a sixth masking layer masking pattern is formed in the sixth photoresist layer 328 by a masking procedure leaving, as shown in FIG. 3BB, a sixth unmasked area 330 on the first face 4 which exposes an area of the gold layer 326 at the completion of this sixth masking step. This step also leaves behind a sixth masking layer 332 which covers an area of the gold layer 326 which lies directly above the underlying PEDT/PSS layer 310. The remaining sixth masking layers 332 are resistant to etching solutions, and protect the underlying gold layer 326.

After the sixth masking procedure is complete, the sixth unmasked areas 330 are next subjected to a HF acid etching process which etching process continues until the exposed gold layer 326 is removed.

Next, the wafer is subjected to a sixth cleaning process, preferably by the RCA or Piranha methods to remove the remaining sixth masking layer 332 leaving an area of gold on the first face 4 above the lip of the silicon nitride layer 36 to form an electrode 334 as shown in FIG. 3CC.

Next, a seventh photoresist layer 338 is formed on the second face 6 by a spin-on procedure leaving the structure as shown in FIG. 3DD.

Next, a seventh masking layer masking pattern is formed in the seventh photoresist layer 338 by a masking procedure and, as shown in FIG. 3EE, a seventh unmasked area 340 on the second face 6 of substrate wafer 2 forming an approximately 3 micron by 3 micron square area centered directly below the first void 18 is exposed at the completion of this seventh masking step. The remaining seventh masking layer 342 is resistant to etching solutions, and protects the underlying first silicon dioxide layer 8 found on the second face 6.

Next, the seventh unmasked area 340 is subjected to an oxide etching process and the seventh masking layer 342 removed. As shown in FIG. 3FF there is created at this stage a second area of exposed substrate 344. 1 After the above masking, etching and photoresist removal procedures are complete, the second area of exposed substrate 344 is next subjected to a silicon anisotropic etching process which etching process continues until the <111> crystal planes of the substrate expose the pyramidally shaped first passivation layer 8 formed on the first face 4 to a height of about 500 A. The structure of the second void 346 created in the substrate 2 by this anisotropic etching process is shown in FIG. 3GG. This second void 346 has the shape of a truncated pyramidal void which is defined by sloping sides 348 which intersect with a flat roof plane 350 through which an inverted pyramidally shaped point 352 centrally projects.

Next, the exposed first silicon dioxide layer 354 on the centrally projecting inverted pyramidally shaped point 352 is subjected to an eighth etching process using the oxide etchants and the exposed first silicon dioxide layer removed. At this stage there is exposed a thin tapered point 356 clad with a gold layer 358 as shown in FIG. 3HH.

Lastly, the exposed gold layer 358 on the thin tapered point 356 is subjected to a ninth etching process using a plasma etchant and the exposed gold layer 358 removed. This series of micromachining steps creates a near field optical detector with a planar detecting layer 364 as shown in FIG. 3II wherein there is exposed an exceedingly slender detector tip 360 comprising in part an area of exposed silicon nitride 362 coupled with a planar detector lying substantially vertical with respect to the axis of the detector tip. This detector tip 360 has a diameter of approximately 10 to 20 nm at its apex.

### Example 4

### Near Field Optical Detector Integrated With Chip Capillary Electrophesis Device

This example establishes the micromachining steps necessary for the manufacture and integration of the Near Field Optical Detector (“NFOD”) with a chip capillary electrophoresis (“CE”) device. The integrated near field optical detector/chip capillary electrophoresis device is hereinafter referred to as the NFOD/CE chip. It is this device which is capable of the rapid and accurate sequencing of long DNA fragments. This example also establishes the use of the NFOD/CE chip in the detection of individual nucleotides and their relative sequence on a DNA fragment.

FIGS. 4 and 5 show various details regarding the integration of the NFOD described in Example 1 with a CE device in a NFOD/CE chip useful for DNA sequence detection. FIG. 4 shows in plan view the integration of a NFOD with a microfabricated CE device on a chip. The other embodiments of the NFOD as described in Examples 2 and 3 can alternatively be used instead of the NFOD described in Example 1.

The NFOD/CE chip 400 comprises an approximately 1.3 cm by 1.11 cm glass chip with four microchannel structures arrayed on the top surface of the glass chip as shown in FIG. 4. Each microchannel structure 402 is comprised of a sample microchannel 404 about 30 μm deep by about 30 μm wide which fluidically intersects and crosses a separation microchannel 406 of similar dimensions.

As shown in more detail in FIG. 5 and FIG. 5B-B′ there is arrayed and fluidically connected at one end of the sample microchannel 500 a sample well 502′ and a waste well 504 at the other end of the sample microchannel 500. On one end of the separation microchannel 506 there is arrayed and fluidically connected a buffer well 508 and at the other end is a waste/buffer well 510. Each well is micromachined into the glass chip 512 using conventional chip micromachining techniques. At the bottom of the sample well 502 there is a first electrode 514. At the bottom of the waste well 504 there is similarly a second electrode 516. A third electrode 518 is located in the bottom of the buffer well 508 and a fourth electrode 520 is located in the bottom of the waste/buffer well 510. Each of these electrodes are comprised of gold deposited in holes which were micromachined through the bottom of the wells to the bottom surface of the glass chip 512 to provide electrical connectivity between the bottom surface of the glass chip 512 and the interior of the various wells. The first 514 and second 516 electrodes are connected to a means 522 of applying a regulated electric current sufficient for running a sample containing DNA fragments from the sample well 502 through the sample microchannel 500 to the waste well 504. The third 518 and fourth 520 electrodes are similarly connected to a means 524 of applying a regulated electric current sufficient to separate and run DNA fragments down the length of the separation channel 506 from where the separation channel 506 intersects with the sample microchannel 500 down to the buffer/waste well 510.

Right before the separation microchannel fluidically connects with the waste/buffer well, there is a diverting barrier 526 which would normally stop the flow and migration of DNA fragments were it not for the void 528 presented by the NFOD lying directly above the diverting barrier 526. This void 528 presents a microchannel about 30 μm deep by about 30 μm wide through which the DNA fragments may continue their journey to ultimately end up in the waste/buffer well 508.

The NFOD rests in a sealingly fashion in a depression 530 approximately 1.12 cm long by approximately 1.31 cm wide micromachined into a glass lid 532 which lid lies in a sealingly fashion directly on the upper surface of the glass chip 512. The above described structure comprises the capillary electrophoresis device with integral near-field optical detector (“NFOD/CE”) of the present invention 554.

In operation, one first chemically passivates the sample 500 and separation 506 microchannels to prevent electroosmotic flow and sample adsorption to the walls. See, Hjerten, S. J. Chromatogr. 1985, 347, 191-198.

Next, the sample 500 and separation 506 microchannels are then filled with polyacrylamide gel solution.

Next, the ends of the sample 500 and separation 506 microchannels are closed the glass lid 532 and the NFOD/CE chip submerged in an ice bath exposed to high-energy UV light source overnight to polymerize the gel. After polymerization, separation microchannel 506 is pre-run for approximately 30 min at 6 KV prior to sample injection.

Next, samples are prepared as described by Soper. See, Soper, S. A. Flanagan, J. H. legendre, B. L Williams, D.C. Hammer, R. P., IEEE-QE, 1996, 2, 1129-1139. The samples are not heat-denatured.

Next, a small 10 nl sample containing DNA fragments is pipetted into the sample well 502 and the sample electrophoresed for 3 min at 300 V/cm across the sample microchannel 500.

Next, once the sample reaches the intersection of the sample 500 and separation microchannels 506 the voltage is switched to the third 518 and fourth 520 electrodes to create a field strength of 150V/cm in the separation microchannel 506. During their traversal of the separation microchannel 506 the DNA fragments are separated according to their size by means of molecular sieving.

Next, the NFOD/CE chip is placed on a computer-controlled translation stage and the detector tip 536 and the void 528 on the NFOD/CE chip is aligned with the 780 nm wavelengths laser light coming from a semiconductor laser. This laser light 534 is focused from under the NFOD/CE chip up through the diverting barrier 526 to within the separation channel 506.

Next, the individual nucleotides on the DNA fragments are then exposed to and excited by a laser light 534 is between about 400, 450, 500, 550 and 600 nm and about 425, 475, 525 and 575 nm in wavelength and between about 1, 3, 4, 5 and 5 mW and about 1.5, 2.5, 3.5 and 4.5 mW in field strength as the nucleotides pass up and over the diverting barrier 526 and past the detector tip 536 of the NFOD. As a result of this optical excitation, emitted light from the individual nucleotides on a DNA fragment 538 is projected onto and collected by the detector tip 536 from where the emitted light is guided through the light guiding layer 540 to be absorbed by the IR absorbing layer 542. The IR absorbing layer expands and contracts with varying levels of light absorption and thus causes the respective expansion and contraction in the overlying pyroelectric layer 544 which generates an electrical signal which is conducted by the NFOD electrode 546. This signal is then conducted into an electrical lead 550 which is soldered to the first NFOD electrode 546 and the second NFOD electrode 548.

Finally, signal from the electrical lead 550 of the NFOD is sampled at 1000 Hz and filtered with a 500 Hz electronic low-pass filter prior to digitization with a 16-bit ADC board resident in a computer 552.

All publications, including patent documents and scientific articles, referred to in this application and the bibliography and attachments are incorporated by reference in their entirety for all purposes to the same extent as if each individual publication were individually incorporated by reference.

All headings are for the convenience of the reader and should not be used to limit the meaning of the text that follows the heading, unless so specified.

What is claimed is:

1. A process of manufacturing a near-field optical device with a pyramidal detecting layer, comprising, the following steps:
(a) providing a wafer comprised of a substrate having a first face and a second face;
(b) providing a layer of first passivation material on at least the first face of the wafer;
(c) forming a first photoresist layer on the first face of the wafer;
(d) forming a first masking layer masking pattern in the first photoresist layer resulting in a first unmasked area of passivation material and a first masking layer on the first face of the wafer;
(e) etching and removing the first unmasked area of passivation material;
(f) removing the first masking layer creating a first area of exposed substrate;
(g) subjecting the first area of exposed substrate to an anisotropic etching process to create an inverted pyramidal first void with sides which intersect at a sharp point;
(h) subjecting the wafer to a first cleaning process to remove the remaining first masking layer;
(i) subjecting the wafer to a second passivation procedure to create a cusp-shaped tapered void on the first void;
(j) depositing a thin layer of light confining material onto the first face of the wafer;
(k) forming a second photoresist layer on the first face of the wafer;
(l) forming a second masking layer masking pattern in the second photoresist layer resulting in a second unmasked area of light confining material and a second masking area on the first face of the wafer;
(m) etching and removing the second unmasked area of exposed light confining material;
(n) subjecting the wafer to a second cleaning process to remove the remaining second masking layer and to leave an area of light confining material on the first void sides and a lip of light confining material extending beyond the first void;
(o) depositing a thin layer of light guiding material on the first face of the wafer;
(p) forming a third photoresist layer on the first face of the wafer;
(q) forming a third masking layer masking pattern in the third photoresist layer resulting in a third unmasked area of light guiding material and a third masking layer on the first face of the wafer;
(r) etching and removing the third unmasked area of light guiding material;
(s) subjecting the wafer to a third cleaning process to remove the remaining third masking layer and to leave an area of light guiding material on the first void sides and a lip of light guiding material extending beyond the first void;
(t) depositing a thin layer of heat absorbent material on the first face of the wafer;
(u) forming a fourth photoresist layer on the first face of the wafer;
(v) forming a fourth masking layer masking pattern in the fourth photoresist layer resulting in a fourth unmasked area of heat absorbent material and a fourth masking layer on the first face of the wafer;
(w) etching and removing the fourth unmasked area of heat absorbent material;
(x) subjecting the wafer to a fourth cleaning process to remove the remaining fourth masking layer;
(y) depositing a thin layer of infra-red sensitive material on the first face of the wafer;
(z) forming a fifth photoresist layer on the first face of the wafer;
(aa) forming a fifth masking layer masking pattern in the fifth photoresist layer resulting in a fifth unmasked area of infra-red sensitive material and a fifth masking layer on the first face of the wafer;
(bb) etching and removing the fifth unmasked area of infra-red sensitive material;
(cc) subjecting the wafer to a fifth cleaning process to remove the remaining fifth masking layer and to leave an area of infra-red sensitive material on the first void sides and extending on the first face until stopping just above the lip of the light guiding material;
(dd) depositing a thin layer of electrically conductive material on the first face of the wafer;
(ee) forming a sixth photoresist layer on the first face of the wafer
(ff) forming a sixth masking layer masking pattern in the sixth photoresist layer resulting in a sixth unmasked area of electrically conductive material and a sixth masking layer on the first face of the wafer;
(gg) etching and removing the sixth unmasked area of electrically conductive material;
(hh) subjecting the wafer to a sixth cleaning process to remove the remaining sixth masking layer and to leave an area of electrically conductive material to form an electrode on the first face of the wafer directly above the infra-red sensitive material layer;
(ii) forming a seventh photoresist layer on the second face of the wafer;
(jj) forming a seventh masking layer masking pattern in the seventh photoresist layer resulting in a seventh unmasked area of first passiviation material and a seventh masking layer on the second face of the wafer;
(kk) etching and removing the seventh unmasked area of first passivation material resulting in a second area of exposed substrate;
(ll) subjecting the second area of exposed substrate to an anisotropic etching process to create a second void which has a flat roof plane through which centrally projects an exposed first passivation layer in the shape of a inverted pyramidal point;
(mm) etching and removing the exposed first passivation layer in the shape of a inverted pyramidal point resulting in an exposed thin tapered point clad with a light confining layer; and
(nn) etching and removing the exposed light confining layer cladding on the thin tapered point.

2. The process in claim 1 in which steps (j) through (n) are replaced by the following steps:
(a) forming a second photoresist layer on the first face of the wafer;
(b) forming a second masking layer masking pattern in the second photoresist layer resulting in a second masking layer and a second unmasked area exposing the cusp-shaped tapered void and a surrounding lip of second passivation material;
(c) depositing a thin layer of light confining material onto the first face of the wafer; and
(d) subjecting the wafer to a second cleaning process to lift-off and remove the second masking layer and overlying light confining layer and to leave an area of light confining material on the cusp-shaped tapered void and the surrounding lip of second passivation material.

3. A process of manufacturing a near-field optical device with a detecting layer arrayed on a convex lens, comprising, the following steps:
(a) providing a wafer comprised of a substrate having a first face and a second face;
(b) providing a layer of first passivation material on at least the first face of the wafer;
(c) forming a first photoresist layer on the first face of the wafer;
(d) forming a first masking layer masking pattern in the first photoresist layer resulting in a first unmasked area of passivation material and a first masking layer on the first face of the wafer;
(e) etching and removing the first unmasked area of passivation material;
(f) removing the first masking layer creating a first area of exposed substrate;
(g) subjecting the first area of exposed substrate to an anisotropic etching process to create an inverted pyramidal first void with sides which intersect at a sharp point;
(h) subjecting the wafer to a first cleaning process to remove the remaining first masking layer;
(i) subjecting the wafer to a second passivation procedure to create a cusp-shaped tapered void on the first void;
(j) depositing a thin layer of light confining material onto the first face of the wafer;
(k) forming a second photoresist layer on the first face of the wafer;
(l) forming a second masking layer masking pattern in the second photoresist layer resulting in a second unmasked area of light confining material and a second masking area on the first face of the wafer;
(m) etching and removing the second unmasked area of exposed light confining material;
(n) subjecting the wafer to a second cleaning process to remove the remaining second masking layer and to leave an area of light confining material on the first void sides and a lip of light confining material extending beyond the first void;
(o) depositing a thick layer of light guiding material on the first face wafer;
(p) polishing flat the thick layer of light guiding material on the first face of the wafer;
(q) forming a third photoresist layer on the first face of the wafer;
(r) forming a third masking layer masking pattern in the third photoresist layer resulting in a third unmasked area of light guiding material and a third masking layer;
(s) heating the wafer to heat and reflow the third masking layer to create a convex shaped third masking layer;
(t) etching and removing the third masking layer and part of the light guiding layer resulting in a convex shaped lens structure;
(u) forming a fourth photoresist layer on the first surface of the wafer;
(v) forming a fourth masking layer masking pattern in the fourth photoresist layer resulting in a fourth unmasked area of the light guiding material and a fourth masking layer;
(w) etching and removing the unmasked area of light guiding material
(x) subjecting the wafer to a third cleaning process to remove the remaining fourth masking layer and to leave the convex lens surrounded by a lip of light guiding material extending beyond the edge of the first void;
(y) depositing a thin layer of material on the first face of the wafer;
(z) forming a fifth photoresist layer on the first face of the wafer;
(aa) forming a fifth masking layer masking pattern in the fifth photoresist layer resulting in a fifth unmasked area of material and a fifth masking layer on the first face of the wafer;
(bb) etching and removing the fifth unmasked area of material;
(cc) subjecting the wafer to a fifth cleaning process to remove the remaining fifth masking layer and to leave exposed an area of material on the convex lens and to leave exposed a surrounding lip of light guiding material extending outwards from the edge of the first void;
(dd) depositing a thin layer of infra-red sensitive material is deposited on the first face of the wafer;
(ee) forming a fifth photoresist layer on the first face of the wafer
(ff) forming a fifth masking layer masking pattern in the fifth photoresist layer resulting in a fifth unmasked area of infra-red sensitive material and a fifth masking layer;
(gg) etching and removing the fifth unmasked area of infra-red sensitive material;
(hh) subjecting the wafer a fifth cleaning process to remove the remaining fifth masking layer;
(ii) depositing a thin layer of electrically conductive material on the first face of the wafer;
(jj) forming a sixth photoresist layer on the first face of the wafer;
(kk) forming a sixth masking layer masking pattern in the sixth photoresist layer resulting in a sixth unmasked area of electrically conductive material and a sixth masking layer;
(ll) etching and removing the sixth unmasked area of electrically conductive material;
(mm) subjecting the wafer to a sixth cleaning process to remove the remaining sixth masking layers and resulting in the exposure of a first and second electrode;
(nn) forming a seventh photoresist layer on the second face
(oo) forming a seventh masking layer masking pattern in the seventh photoresist layer resulting in a seventh unmasked area of first passiviation material and a seventh masking layer on the second face of the wafer;
(pp) etching and removing the seventh unmasked area of first passivation material resulting in a second area of exposed substrate;
(qq) subjecting the second area of exposed substrate to an anisotropic etching process to create a second void which has a flat roof plane through which centrally projects an exposed first passivation layer in the shape of a inverted pyramidal point;
(rr) etching and removing the exposed first passivation layer in the shape of a inverted pyramidal point resulting in an exposed thin tapered point clad with a light confining layer; and
(ss) etching and removing the exposed light confining layer cladding on the thin tapered point.

4. A process of manufacturing a near-field optical device with a planar detecting layer, comprising, the following steps:
(a) providing a wafer comprised of a substrate having a first face and a second face;
(b) providing a layer of first passivation material on at least the first face of the wafer;
(c) forming a first photoresist layer on the first face of the wafer;
(d) forming a first masking layer masking pattern in the first photoresist layer resulting in a first unmasked area of passivation material and a first masking layer on the first face of the wafer;
(e) etching and removing the first unmasked area of passivation material;
(f) removing the first masking layer creating a first area of exposed substrate;
(g) subjecting the first area of exposed substrate to an anisotropic etching process to create an inverted pyramidal first void with sides which intersect at a sharp point;
(h) subjecting the wafer to a first cleaning process to remove the remaining first masking layer;
(i) subjecting the wafer to a second passivation procedure to create a cusp-shaped tapered void on the first void;
(j) depositing a thin layer of light confining material onto the first face of the wafer;
(k) forming a second photoresist layer on the first face of the wafer;
(l) forming a second masking layer masking pattern in the second photoresist layer resulting in a second unmasked area of light confining material and a second masking area on the first face of the wafer;
(m) etching and removing the second unmasked area of exposed light confining material;
(n) subjecting the wafer to a second cleaning process to remove the remaining second masking layer and to leave an area of light confining material on the first void sides and a lip of light confining material extending beyond the first void;
(o) depositing a thick layer of light guiding material on the first face of the wafer;
(p) polishing flat the thick layer of light guiding material on the first face of the wafer;
(q) forming a third photoresist layer on the first face of the wafer;
(r) forming a third masking layer masking pattern in the third photoresist layer resulting in a third unmasked area of light guiding material and a third masking layer;
(s) etching and removing the unmasked area of light guiding material;
(t) subjecting the wafer to a third cleaning process to remove any remaining third masking layer and to leave an area of light guiding material on the first void sides and a lip of light guiding material extending beyond the first void;
(u) depositing a thin layer of material on the first face of the wafer;
(v) forming a fourth photoresist layer on the first face of the wafer;
(w) forming a fourth masking layer masking pattern in the fourth photoresist layer resulting in a fourth unmasked area of heat absorbent material and a fourth masking layer on the first face of the wafer;
(x) etching and removing the fourth unmasked area of heat absorbent material;
(y) subjecting the wafer to a fourth cleaning process to remove the remaining fourth masking layer;
(z) depositing a thin layer of infra-red sensitive material on the first face of the wafer;
(aa) forming a fifth photoresist layer on the first face of the wafer;
(bb) forming a fifth masking layer masking pattern in the fifth photoresist layer resulting in a fifth unmasked area of infra-red sensitive material and a fifth masking layer on the first face of the wafer;
(cc) etching and removing the fifth unmasked area of infra-red sensitive material;
(dd) subjecting the wafer to a fifth cleaning process to remove the remaining fifth masking layer and to leave an area of infra-red sensitive material substantially covering the underlying heat absorbing layer;
(ee) forming a thin layer of electrically conductive material on the first face of the wafer;
(ff) forming a sixth photoresist layer on the first face of the wafer;
(gg) forming a sixth masking layer masking pattern in the sixth photoresist layer resulting in a sixth unmasked area of electrically conductive material and a sixth masking layer covering two areas of the electrically conductive layer which lie on opposite sides of the first void sides and extending outwards on the first face of the wafer;
(hh) etching and removing the sixth unmasked area of electrically conductive material;
(ii) subjecting the wafer to a sixth cleaning process to remove the remaining sixth masking layer and to leave an area of electrically conductive material to form an electrode on the first face of the wafer substantially directly above the infra-red sensitive material;
(jj) forming a seventh photoresist layer on the second face of the wafer;
(kk) forming a seventh masking layer masking pattern in the seventh photoresist layer resulting in a seventh unmasked area of first passiviation material and a seventh masking layer on the second face of the wafer;
(ll) etching and removing the seventh unmasked area of first passivation material resulting in a second area of exposed substrate;
(mm) subjecting the second area of exposed substrate to an anisotropic etching process to create a second void which has a flat roof plane through which centrally projects an exposed first passivation layer in the shape of a inverted pyramidal point;
(nn) etching and removing the exposed first passivation layer in the shape of a inverted pyramidal point resulting in an exposed thin tapered point clad with a light confining layer; and
(oo) etching and removing the exposed light confining layer cladding on the thin tapered point.

5. A near field optical detector manufactured according to the process described in claim 1.

6. A near field optical detector manufactured according to the process described in claim 2.

7. A near field optical detector manufactured according to the process described in claim 3.

8. A near field optical detector manufactured according to the process described in claim 4.

9. A detecting device with integrated near field optical detector comprising, the following elements:
(a) a chip with a top and bottom surface;
(b) one or more microchannel structures micromachined into the chip; and
(c) a near-field optical detector manufactured according to the process described in claim 1 detectably integrated with one or more of the microchannel structures.

10. A detecting device with integrated near field optical detector comprising, the following elements:
(a) a chip with a top and bottom surface;
(b) one or more microchannel structures micromachined into the chip; and
(c) a near-field optical detector manufactured according to the process described in claim 2 detectably integrated with one or more of the microchannel structures.

11. A detecting device with integrated near field optical detector comprising, the following elements:
(a) a chip with a top and bottom surface;
(b) one or more microchannel structures micromachined into the chip; and
(c) a near-field optical detector manufactured according to the process described in claim 3 detectably integrated with one or more of the microchannel structures.

12. A detecting device with integrated near field optical detector comprising, the following elements:
(a) a chip with a top and bottom surface;
(b) one or more microchannel structures micromachined into the chip; and
(c) a near-field optical detector manufactured according to the process described in claim 4 detectably integrated with one or more of the microchannel structures.

13. A capillary electrophoresis device with integrated near field optical detector comprising, the following elements:
(a) a chip with a top and bottom surface;
(b) one or more microchannel structures arrayed on the top surface of the chip with each structure comprising a sample microchannel and a separation microchannel in fluidic communication;
(c) a sample well fluidically connected to an end of the sample microchannel;
(d) a waste well fluidically connected to an opposite end of the sample microchannel;
(e) a buffer well fluidically connected to an end of the separation microchannel;
(f) a waste/buffer well fluidically connected to the opposite end of the separation microchannel;
(g) a first electrode conductively arrayed in the sample well;
(h) a second electrode conductively arrayed in the waste well;
(i) a third electrode conductively arrayed in the buffer well;
(j) a fourth electrode conductively arrayed in the waste buffer well;
(k) a means of applying regulated current sufficient through the first and second electrode and for running a sample containing DNA fragments from the first electrode through the sample microchannel to the second electrode;
(l) a means of applying regulated current through the third and fourth electrodes sufficient to separate and run DNA fragments down the length of the separation channel from where the separation channel intersects with the sample microchannel to the buffer/waste well;
(m) a diverting barrier in the separation microchannel;
(n) a lid which lies in a sealingly fashion on the upper surface of the chip;
(o) a flanged opening in the lid into which fits the near-field optical detector in a detectingly fashion;
(p) a near field optical detector fitted into the flanged opening in the lid and detectably oriented with the separation microchannel; and
(q) a laser light source.

14. The process in claim 1 in which the substrate material is selected from the group consisting of single crystal <100> oriented silicon, germanium, gallium arsenide, borosilicate glass and soda glass.

15. The process in claim 3 in which the substrate material is selected from the group consisting of single crystal <100> oriented silicon, germanium, gallium arsenide, borosilicate glass and soda glass.

16. The process in claims 4 in which the substrate material is selected from the group consisting of single crystal <100> oriented silicon, germanium, gallium arsenide, borosilicate glass and soda glass.

17. The process in claim 1 in which the step of subjecting the first area of exposed substrate to an anisotropic etching process to create an inverted pyramidal first void with sides which intersect at a sharp point results instead in the creation of an inverted bullet shaped void with sloping sides which intersect at a sharp point.

18. The process in claim 3 in which the step of subjecting the first area of exposed substrate to an anisotropic etching process to create an inverted pyramidal first void with sides which intersect at a sharp point results instead in the creation of an inverted bullet shaped void with sloping sides which intersect at a sharp point.

19. The process in claim 4 in which the step of subjecting the first area of exposed substrate to an anisotropic etching process to create an inverted pyramidal first void with sides which intersect at a sharp point results instead in the creation of an inverted bullet shaped void with sloping sides which intersect at a sharp point.

20. The process in claim 1 in which the first unmasked area is between about 1 μm and about 500 μm in length and width.

21. The process in claim 3 in which the first unmasked area is between about 1 μm and about 500 μm in length and width.

22. The process in claim 4 in which the first unmasked area is between about 1 μm and about 500 μm in length and width.

23. The process in claim 1 in which the first passivation layer is selected from the following group consisting of silicon oxide, phosphorous doped silicon oxide, silicon nitride, spun-on glass, spun-on polymer, gold, chromium, wolfram and tungsten.

24. The process in claim 3 in which the first passivation layer is selected from the following group consisting of silicon oxide, phosphorous doped silicon oxide, silicon nitride, spun-on glass, spun-on polymer, gold, chromium, wolfram and tungsten.

25. The process in claim 4 in which the first passivation layer is selected from the following group consisting of silicon oxide, phosphorous doped silicon oxide, silicon nitride, spun-on glass, spun-on polymer, gold, chromium, wolfram and tungsten.

26. The process in claim 1 in which the second passivation layer formed on the first face of the 6 wafer upon completion of the second passivation step is formed to a thickness which transitions between about 1 Å to about 900 Å at the narrowest point and between about 2 Å to about 1000 Å at the thickest point.

27. The process in claim 1 in which the light confining material is selected from the following group consisting of gold, chromium, wolfram, tungsten, organic polymers and inorganic polymers.

28. The process in claim 3 in which the light confining material is selected from the following group consisting of gold, chromium, wolfram, tungsten, organic polymers and inorganic polymers.

29. The process in claim 4 in which the light confining material is selected from the following group consisting of gold, chromium, wolfram, tungsten, organic polymers and inorganic polymers.

30. The process in claim 1 in which the light confining material layer is deposited to a thickness between about 1 Å and 500 Å.

31. The process in claim 2 in which the light confining material layer is deposited to a thickness between about 1 Å and 500 Å.

32. The process in claim 3 in which the light confining material layer is deposited to a thickness between about 1 Å and 500 Å.

33. The process in claim 4 in which the light confining material layer is deposited to a thickness between about 1 Å and 500 Å.

34. The process in claim 1 in which the light guiding material is selected from the following group consisting of silicon, silicon oxide, silicon nitride, organic polymers and inorganic polymers.

35. The process in claim 3 in which the light guiding material is selected from the following group consisting of silicon, silicon oxide, silicon nitride, organic polymers and inorganic polymers.

36. The process in claim 4 in which the light guiding material is selected from the following group consisting of silicon, silicon oxide, silicon nitride, organic polymers and inorganic polymers.

37. The process in claim 1 in which the light guiding material is deposited to a thickness between about 1 Å and about 1000 Å.

38. The process in claim 3 in which the light guiding material is deposited to a thickness between about 0.1 μm and about 8 Åm.

39. The process in claim 4 in which the light guiding material is deposited to a thickness between about 1 Åm and about 5 Åm.

40. The process in claim 2 in which the step of subjecting the wafer to a second cleaning process to lift-off and remove the second masking layer is accomplished using chlorobenzene.

41. The process in claim 1 in which the etching and removing the third unmasked area of light guiding material is accomplished by a plasma etching process.

42. The process in claim 1 in which the heat absorbent material is selected from the following group consisting of gold, carbon and poly-3,4-ethylenedioxythiophene polystyrenesulphonate polymer.

43. The process in claim 3 in which the heat absorbent material is selected from the following group consisting of gold, carbon and poly-3,4-ethylenedioxythiophene polystyrenesulphonate polymer.

44. The process in claim 4 in which the heat absorbent material is selected from the following group consisting of gold, carbon and poly-3,4-ethylenedioxythiophene polystyrenesulphonate polymer.

45. The process in claim 1 in which the heat absorbent material layer is deposited to a thickness between about 0.001 μm and about 0.1 μm.

46. The process in claim 3 in which the heat absorbent material layer is deposited to a thickness between about 0.001 μm and about 0.1 μm.

47. The process in claim 4 in which the heat absorbent material layer is deposited to a thickness between about 0.001 μm and about 0.1 μm.

48. The process in claim 1 in which the infra-red sensitive material is selected from the following group consisting of polyvinylidene fluoride (“PVDF”), polyvinylidene fluoride/trifluoroethylene copolymer (“PVDF/TrFE”), lanthanum-doped lead zirconate tantalate (“PZT”), ZnO, TiW, lithium tantalate, barium titanate, triglycine sulfate, polyvinyl fluoride and quartz.

49. The process in claim 3 in which the infra-red sensitive material is selected from the following group consisting of polyvinylidene fluoride (“PVDF”), polyvinylidene fluoride/trifluoroethylene copolymer (“PVDF/TrFE”), lanthanum-doped lead zirconate tantalate (“PZT”), ZnO, TiW, lithium tantalate, barium titanate, triglycine sulfate, polyvinyl fluoride and quartz.

50. The process in claim 4 in which the infra-red sensitive material is selected from the following group consisting of polyvinylidene fluoride (“PVDF”), polyvinylidene fluoride/trifluoroethylene copolymer (“PVDF/TrFE”), lanthanum-doped lead zirconate tantalate (“PZT”), ZnO, TiW, lithium tantalate, barium titanate, triglycine sulfate, polyvinyl fluoride and quartz.

51. The process in claim 1 in which the infra-red sensitive material is deposited to a thickness between about 1 μm and about 20 μm thick.

52. The process in claim 3 in which the infra-red sensitive material is deposited to a thickness between about 1 μm and about 20 μm thick.

53. The process in claim 4 in which the infra-red sensitive material is deposited to a thickness between about 1 μm and about 20 μm thick.

54. The process in claim 1 in which the electrically conductive material is selected from the following group consisting of metals, semiconductors, conductive organic polymers and conductive inorganic polymers.

55. The process in claim 3 in which the electrically conductive material is selected from the following group consisting of metals, semiconductors, conductive organic polymers and conductive inorganic polymers.

56. The process in claim 4 in which the electrically conductive material is selected from the following group consisting of metals, semiconductors, conductive organic polymers and conductive inorganic polymers.

57. The process in claim 1 in which the electrically conductive material is deposited to a thickness between about 1 Å and 500 Å.

58. The process in claim 3 in which the electrically conductive material is deposited to a thickness between about 1 Å and 500 Å.

59. The process in claim 4 in which the electrically conductive material is deposited to a thickness between about 1 Å and 500 Å.

60. The capillary electrophoresis device of claim 7 in which the chip is comprise d of a material selected from the group consisting of glass, silicon dioxide, ceramics, organic polymers and inorganic polymers.

61. The capillary electrophoresis device of claim 7 in which the lid is comprised of a material selected from the group consisting of glass, silicon dioxide, ceramics, organic polymers and inorganic polymers.

62. The capillary electrophoresis device of claim 7 in which the microchannel structure is between about 30 μm and about 150 μm in depth by between about 30 μm and about 150 μm in width.

63. The capillary electrophoresis device of claim 7 in which the near field optical detector is manufactured according to the process described in claim 1.

64. The capillary electrophoresis device of claim 7 in which the near field optical detector is manufactured according to the process described in claim 2.

65. The capillary electrophoresis device of claim 7 in which the near field optical detector is manufactured according to the process described in claim 3.

66. The capillary electrophoresis device of claim 7 in which the near field optical detector is manufactured according to the process described in claim 4.

67. The capillary electrophoresis device of claim 7 in which the laser light is between about 400 nm and 600 nm in wavelength.

68. The capillary electrophoresis device of claim 7 in which the laser light is between about 1 mW and 5 mW in field strength.
